(19) United States
(12) Patent Application Publication
(10) Pub. No.: US 2002/0011852 A1
(43) Pub. Date: Jan. 31, 2002

(54) Non-contact photothermal radiometric metrologies and instrumentation for characterization of semiconductor wafers, devices and non electronic materials

(76) Inventors: Andreas Mandelis, Scarborough (CA); Jose Agustin Garcia-Hercules, Toronto (CA); Lena Nicolaides, Toronto (CA); Mario Enrique Rodriguze-Garcia, Queretaro, NM (US); Stefano Pauloni, Roma (IT)

Correspondence Address: DOWELL & DOWELL PC, SUITE 309, 1215 JEFFERSON DAVIS HIGHWAY, ARLINGTON, VA, 22202

(21) Appl. No.: 09/813,357

(22) Filed: Mar. 21, 2001

Related U.S. Application Data
(60) Provisional application No. 60/191,294, filed on Mar. 21, 2000.

(51) Int. Cl. G01R 31/302

(52) U.S. Cl. 324/752

(57) ABSTRACT

There is provided a metrologic methodology, useful for in-situ, non-destructive monitoring, comprising a combination of novel signal generation and analysis techniques, computational techniques, and laser infrared radiometric instrumental configurations for measuring thermal and electronic properties of industrial semiconductor wafers and non-electronic materials. This methodology includes: the combination of the frequency sweep (Chirp) and conventional frequency scan techniques for rapid measurement of electronic and thermal transport properties of semiconductor and engineering materials/devices. The common-mode rejection demodulation (bi-modal pulse) method for detection of very weak inhomogeneities in materials, based on generating a real time periodic waveform consisting of two incident square-wave pulses. The foregoing common-mode rejection demodulation method is a very general signal generation and detection methodology and is not limited to photothermal or photoacoustic phenomena, but rather encompasses any and all methodologies that utilize signal modulation. The multiparameter computational method for determining a unique set of thermal and electronic parameters of semiconductor (e.g. Si) wafers, from frequency domain measurements, based on the specifics of signal sensitivity dependence on a given transport parameter across particular regions of the waveform repetition frequency spectrum. And the depth profilometry and roughness elimination method for determining thermal diffusivity profiles of rough samples by processing the experimental data with an approach to roughness based on the concept of the equivalence of random size-parameter distribution of rough layers to white noise.

### CROSS REFERENCE TO RELATED PATENT APPLICATION

This patent application relates to U.S. Provisional Patent Application Serial No. 60/191,294 filed on Mar. 21, 2000 entitled NON-CONTACT PHOTOTHERMAL RADIOMETRIC METROLOGIES AND INSTRUMENTATION FOR CHARACTERIZATION OF SEMICONDUCTOR WAFERS, DEVICES AND NON ELECTRONIC MATERIALS, which is incorporated herein by reference in its entirety.

### FIELD OF INVENTION

The present invention relates to metrologic methodologies and instrumentation, in particular to laser-frequency domain infrared photothermal radiometry (PTR), for measuring electronic properties in industrial Si wafers, devices and other semiconductor materials; and metrologic methodologies for performing thermal-parameter depth profilometry of intrinsic or process-induced inhomogeneities in engineering materials. In particular, the metrologic application to measuring thermal diffusivity of layered solids, αⱼ, inhomogeneous thermal diffusivity depth profiles, α(x), and electronic transport properties in semiconductor wafers such as: minority-carrier lifetime (τ), surface recombination velocities (S), diffusion coefficient (D) and diffusion length (L).

### BACKGROUND OF THE INVENTION

There are essentially two dynamic or time-dependent methods for measuring thermal and electronic properties of solids. Regarding thermal (or thermophysical) properties, the first is the periodic heat flow method (see for example L. Qian and P. Li, Appl. Opt. 29, 4241, 1990) and the second one is the transient method (see W. P. Leung and C. A. Tam, J. Appl. Phys. 56, 153, 1984), including the spectral analysis and cross-correlation (multi-frequency) method (S. Peralta, S. C. Ellis, C. Christofides and A. Mandelis, J. Res. Non-Destructive Eval., 3, 69, 1991).

In the periodic heat flow case, a solid sample is irradiated with a harmonically modulated laser beam thereby launching a thermal wave through the sample. The resulting periodic temperature profile at the front or back of the surface of the sample is monitored at several modulation frequencies f, also known as the frequency scan method. The frequency dependent thermal diffusion length μ is given by:

μ=\sqrt{α/πf}

and is related to the phase-lag of the detected temperature wave with respect to the heating source and may be monitored using a lock-in amplifier.

In transient measurement techniques such as pulsed or multi-frequency spectral excitation, a sample is irradiated on one side with a laser pulse and the time evolution of the temperature is monitored and the rate of decay of the temperature is related to thermal diffusivity of the solid. Among the most common non-contact, non-destructive techniques used for characterizing electronic materials and semiconductor substrates are: Photothermal radiometry (PTR) [E. A. Ulmer and D. R. Frankl, Proc. IX-th Int. Conf. Physics Semiconductors, Nauka, 1959, pp. 99-101; H. Nakamura, K. Tsubouchi, N. Mikoshiba and T. Fukuda, Jpn. J. Appl. Phys. 24, L876 (1985); S. J. Sheard M. G. Somekh and T. Hiller, Mater. Sci. Eng. B5, 101, (1990); A. Mandelis, R. Bleiss and F. Shimura, J. Appl. Phys. 74, 3431 (1993)]; laser/microwave absorption/reflection (LMR) [T. Warabisako, T. Saitoh, T. Motooka and T. Tokuyama, Jpn. J. Appl. Phys. Suppl. 22-1, 557 (1982); J. Waldemeyer, J. Appl. Phys. 63, 1977 (1988); Z. G. Ling and P. K. Ajmera, J. Appl. Phys. 69, 519 (1991)]; infrared absorption (IA) [Y. Mada, Jpn. J. Appl. Phys. 18, 2171 (1979); F. Shimura, T. Okui and T. Kusama, J. Appl. Phys. 61, 7168 (1990); A. Buckzkowski, G. A. Rozgonyi and F. Shimura, Proc. MRS Spring Conf. (1992)]; microwave photoconductance decay (μ-PCD) [T. Tiegje, J. I. Haberman, R. W. Francis and A. K. Ghosh, J. Appl. Phys. 54, 2499 (1983)], or open circuit decay (OCVD [U. Lehmann and H. Foll, J. Electrochem. Soc. 135, 2831 (1988)]; surface photovoltage, SPV, [J. Lagowski, P. Edelman, M. Dexter, and W. B. Henley, Semicond. Sci. Thechnol. 7A, 185 (1992); J. Lagowski, V. Faifer, and P. Edelman, Electrocehm. Soc. Proc. 96-13, 512 (1995)]; laser photomodulated thermoreflectance, PMOR [A. Rocencwaig, in Photoacoustic and Thermal-Wave Phenomena in Semiconductors, edited by A. Mandelis (Elsevier, New York, 1987), Chap. 5]. In all of these methods laser illumination is used to generate excess electron-hole pairs. The resulting signal is detected in the frequency-domain as a function of modulation frequency (in PTR and PMOR) or in the time domain as a transient signal (IA, LMR, μ-PCD, and OCVD).

### SUMMARY OF THE INVENTION

The present invention consists of the development of a complete photothermal radiometric instrumentation hardware and software metrologic system comprising novel combinations of signal generation and analysis techniques, computational software, as well as novel instrumental hardware configurations based on (but not confined to) the physical principles of laser infrared photothermal radiometry.

### Frequency-Sweep (Chirp) Photothermal Radiometry

The present invention provides a method of noncontact measurement of electronic and thermal transport properties in semiconductors such as thermal diffusivity (α), minority carrier lifetime (τ), front and back surface recombination velocities (S), and electronic carrier diffusion length (L). In one aspect the present radiometric method comprises (a) providing a sample of a semiconductor wafer, including a scribeline between adjacent circuit devices; (b) irradiating the sample with an excitation source (laser); (c) generating a square-wave chirp from a dual-channel fast Fourier transform (FFT) analyzer to drive an acousto-optic modulator and produce periodic frequency sweeps (chirps) of the laser beam in the range including (but not confined to) dc to 100 kHz; (d) generating an instrumental transfer function, H(f), by fitting the frequency-scan data from a Si wafer with well-known electronic and thermal parameters to a theoretical model which uses these parameters, computing the necessary corrections to the captured radiometric amplitude and phase signal, and storing them in the FFT analyzer and in a personal computer; (e) fitting the obtained signal from arbitrary semiconductor samples to the same theoretical model of the photothermal radioemtric response, corrected for the instrumental transfer function, by using the multiparameter computational method (presented in this invention) to obtain the thermal and/or electronic parameters of these samples.

The present invention further provides for using the same chirp methodology as described above, for generating fast radiometric (or otherwise) frequency scans from multi-layered and inhomogeneous materials, such as thermal barrier coatings and hardened steels, in order to measure the thermophysical properties (thermal diffusivity, α, and conductivity, k) of multi-layer structures, and to reconstruct thermal diffusivity depth profiles, α(x), of inherently or process-related inhomogeneous structures.

### Common Rejection Mode (Dual Pulse)

The present invention also provides a general instrumental method for detection of very weak inhomogeneities among materials that are not possible to detect with conventional signal generation techniques. In one aspect the present method comprises (a) providing a sample of the material; (b) irradiating the sample with an optical or otherwise excitation source of thermal waves; (c) generating a real time periodic waveform consisting of two incident pulses; (d) detecting the signal (photothermal or otherwise) and feeding it to a lock-in amplifier.

The present invention is by no means confined to thermal-wave signal generation, but encompasses all manner of modulated signals, such as acoustic, optical, ultrasonic, X-rays and any other signal generation method accessible to those skilled in the art.

### Multiparameter Computational Radiometric Methodology

In another aspect of the present invention a computational method for determining a unique set of thermal and electronic parameters of industrial semiconductor (e.g. Si) wafers, from frequency domain radiometric measurements, is also provided. This method comprises the steps of (a) providing a sample of the semiconductor; (b) irradiating the sample with a periodic optical (laser) or other free-carrier raising energy source generating a blackbody radiation signal; (c) detecting said radiometric signal and inputting said radiometric signal to a lock-in amplifier and storing the frequency scans in a personal computer; (d) applying the multiparameter fitting procedure using the electronic spread sheet coupled to a numerical function-program.

### Depth Profilometry and Roughness Elimination Algorithm

The present invention provides a method for reconstructing the thermal diffusivity profile of rough engineering materials by means of first eliminating roughness effects from the experimental data. In one aspect the method comprises of (a) providing a sample of process-related inhomogeneous material or multi-layer structures; (b) irradiating the sample with a periodically excited source (laser); (c) detecting the photothermal (radiometric or otherwise) frequency sweep signal with a lock-in amplifier and storing the experimental data in a personal computer; (d) processing the experimental data with a heuristic approach to roughness so as to eliminate the effects of roughness; (e) applying to the processed data the theoretical/computational model to reconstruct the thermal diffusivity profile.

### BRIEF DESCRIPTION OF THE DRAWINGS

The methods of the present invention will now be described by way of example only, reference being had to the accompanying drawings in which:

FIG. 1 Illustrates a schematic diagram of one embodiment of an apparatus used for measuring thermal and electronic properties according to the methods of the present inventions.

Lock-In Common Rejection Mode Figures

FIG. 2. Shows the (a) Optical excitation pulse train i(t); (b) radiometric repetitive transient signal s(t) due to i(t); and (c)lock-in weighting function w(t).

FIG. 3. Shows the amplitude of the in-phase (IP) and quadrature (Q) component of the lock-in analyzer (LIA) radiometric response, as function of the separation between two pulses for the τ₁/T values reported in the inset. The sample has been assumed homogeneous, i.e. Re[S(f)]=−Im[S(f)] and τ₂/T=25%, where S(f) is the system frequency response; T is the period; τ₁ is the duration of pulse 1; and τ₂ is the duration of pulse 2.

FIG. 4. Shows the IP and Q components of the LIA response, as functions of the pulse separation, Δ, for various arguments of S(f) reported in the inset. τ₁/T and τ₂/T have been assumed equal to 5 and 25%, respectively.

FIG. 5. Shows the dependence of the zero crossing values Δ_{0,IP} and Δ_{0,Q} on the duration of the first pulse for the arg[S(f)] values reported in the inset. τ₂/T has been assumed equal to 25%.

FIG. 6. Illustrates the block diagram of the infrared laser photothermal radiometric system, (a subset of the apparatus shown in FIG. 1), used as a first embodiment of the pulse-separation scan invention.

FIG. 7. Displays the experimental IP- and Q-component data obtained on a Zr alloy sample for the τ₁/T values reported in the inset. The modulation frequency was f=10 kHz and τ₂/T=25%. The solid lines represent the theoretical fits calculated according to the theory (see section with detailed description of method below) assuming Re[S(f)]=−Im[S(f)].

FIG. 8. Displays the experimental Q-component zero crossing values obtained on the Zr alloy sample with τ₁/T=2, 5, 7 and 10%. The modulation frequency is 5 kHz while τ₂/T=25%. The shown continuous line is theoretical (see section with detailed description of method below).

FIG. 9. Displays the Q-magnitude pulse-separation scans obtained for τ₁/T=5%, τ₂/T=25%, f=500 Hz and for the pump laser power values shown in the inset. Continuous lines are theoretical fits (see setion with detailed description of the method below) with Im[(S(f)]/Re[S(f)] as the only adjustable parameter.

FIG. 10. Displays the conventional 50%-duty-cycle frequency-scan phase signals obtained for the pump power values reported in FIG. 9.

FIG. 11. Shows a zoom of the data reported in FIG. 9 in the vicinity of the zero crossing region. The solid lines are fits calculated according to the theory described in detailed in section below. The dotted curves represent the theoretical data obtained for P=150 mW, calculated for arg[(S(f)] values reported in the inset.

FIG. 12. Shows microhardness depth profiles for two shot peened Zr-2.5Nb alloy samples. The inset shows Almen intensities. The data corresponding to the N7 sample have been smoothed.

FIG. 13. Displays (a) Experimental Q-component data obtained from the N7 Zr-2.5Nb alloy sample in FIG. 12 for the τ₁/T values reported in the inset, and τ₂/T=25%: (a) f=500 Hz; (b) f=5 kHz. (b) The near-zero crossing region for the Q-components of the two shot peened Zr-2.5Nb samples in FIG. 12 and a Zr sample used as a reference. τ₁/T=5%, τ₂/T=25% and f=500 Hz.

FIG. 14. Displays the near-zero crossing region for the Q-components of the two shot peened Zr-2.5Nb samples and the Zr reference. τ₁/T=5%, τ₂/T=25% and f=500 Hz.

FIG. 15. Displays the experimental Q-component zero-crossing data obtained on the (a) C5, and (b) N7 shot peened Zr-2.5Nb alloy samples for the modulation frequencies reported in the inset. The τ₁/T and τ₂/T values are the same as in FIG. 13.

FIG. 16. Displays the measured photothermal radiometric amplitude ratio, (a), and phase difference, (b), for the two shot peened Zr-2.5Nb alloy samples. To aid the eye, the C5 ratio has been shifted upward by +0.5. The relative amplitudes are consistent with the slopes of the N7 and C5 curves in FIG. 13, which reveal a low photothermal amplitude response for the C5 sample.

Frequency-Sweep (“Chirp”) Figures

FIG. 17. Illustrates an schematic representation of photothermal radiometric apparatus embodiment used for simultaneous measurements of transient and frequency swept scans. M: mirror; AOM: Acousto-optic modulator; MCT: Mercury Cadmium Telluride detector; L: lens; LIA: lock-in amplifier; MC: mechanical chopper; FFT: fast Fourier transform. X(t) is the chirp periodic waveform launched by the FFT analyzer. Y(t) is the sample response to X(t). H(f) is the output spectral transfer function.

FIG. 18. Shows a comparison of two radiometric signal transients of an unirradiated (a) and irradiated (b) spot of an n-type unoxidized Si wafer, and an unirradiated spot of a p-type Si wafer with a 5000Σ oxide film (c). The parameters used for the fittings (solid lines) are shown in this figure. The horizontal bar on curve (a) indicates the duration of each set of frequency swept measurements (chirps). Arrows indicate the onset of each set of chirps

FIG. 19. Displays the experimental PTR amplitude (a) and phase (b) responses of an n-Si wafer. Curve (1) corresponds to lock-in amplifier data obtained at steady state. Curve (2) is the normalized frequency-sweep (100 Hz-100 kHz) transfer function, H(f), corresponding to the first chirp measurement (300 s) on the same wafer. Solid lines show the simultaneous best fit using a finite-thickness model⁸. Parameters derived from the best fits are i) at steady state: τ=110 μs, D_{P}=10 cm²/s, S₁=320 cm/s; ii) after 300 s of exposure: τ=110 μs, Dₚ=10 cm²/s, S₁=830 cm/s and L=570 μm. Inset: calculated surface recombination velocities of the n-Si wafer at different times for transients (a) and (b) of FIG. 2. The extremes of the solid line denote the radiation turn-off and turn-on times.

Computational Method Figures

FIG. 20 Displays the PTR signal amplitude (a) and phase (b) for lifetime simulations in some Si samples. Values uses for these simulations were: Dₙ=5 cm²/s, S₁=130 cm/s, S₂=1×10⁴ cm/s, α=0.116 cm²/s, Cₚ=3×10⁻²⁰ a.u, Cₜ=1 a.u.

FIG. 21 Shows the Linear relation between lifetime measurements and PTR signal amplitude for a high-resistivity p-Si wafer, evaluated at four different positions along the radial direction.

FIG. 22 displays the amplitude (a) and phase (b) PTR images of a long-lifetime Si wafer, probed from the front (intact) surface and scanned over the coordinates of the back surface mechanical defect site.

FIG. 23 Illustrates an schematic representation of the horizontal furnace used for dry isochronal oxidation process.

FIG. 24 Displays the PTR signal amplitude (a) and phase (b) for front surface recombination velocity simulations in Si samples with long lifetime (τ=1500 μs). Values for the remaining simulation parameters were: Dₙ=5 cm²/s, S₂=1×10⁴ cm/s, α=0.116 cm²/s, Cₚ=3×10⁻²⁰ a.u and Cₜ=1 a.u.

FIG. 25 Displays the PTR signal amplitude (a) and phase (b) for back surface recombination velocity in Si samples with long lifetime (τ=1500 μs). Values for the remaining simulations parameter were: Dₙ=5 cm²/s, S₁=130 cm/s, α=0.116 cm²/s, Cₚ=3×10⁻²⁰ a.u. and Cₜ=1 a.u.

FIG. 26 Displays the PTR signal amplitude (a) and phase for a Si sample with long-lifetime wafer, before (front 1 and back 1) and after (front 2 and back 2) back-surface damage, respectively.

FIG. 27 Shows a histogram for best-fit results for wafer 1 (door), 2 (source), 25 (door) and 26 (source) processed in tube 15 (a) front surface recombination velocity (b) lifetime.

FIG. 28 Displays the μ-PCD iron concentration (a, c) and lifetime measurement (b, d) for p-silicon wafers: sample 1 (BK101) and 2 (BK1003).

FIG. 29 Shows the PTR signal for the six radial positions in sample 2 (BK1003).

FIG. 30 Shows a typical configuration of thermal annealing of industrial p-Si wafers under an applied electric field

FIG. 31 Displays the PTR amplitude (a) and phase (b) frequency scans for p-Si wafer. Annealed under no electric field condition. The solid lines represent the best fits using the multiparameter computational methodology presented in this invention.

FIG. 32 Dispalys the Experimental PTR amplitude (a) and phase (b) frequency responses obtained from a nonimplanted reference wafer and Si wafers implanted with P⁺ ions of 50 keV energy to various doses (ions/cm²): (1) 5×10¹⁰; (2) 1×10¹¹; (3) 5×10¹¹; (4) 1×10¹²; (5) 5×10¹²; (6) 1×10¹³; (7) 5×10¹³; (8) 1×10¹⁴; (9) 5×10¹⁴; (10) 1×10¹⁵; (11) 5×10¹⁵; (12) 1×10¹⁶.

FIG. 33 Displays the (a) Values of the minority carrier lifetime evaluate from the PTR amplitude and phase frequency responses as a function of implantation dose for implantation energies of 50, 100, and 150 keV. (b) Experimental dependencies of PTR amplitude on implantation dose for 50, 100 and 150 keV implantation energies taken at 10 kHz modulation frequency.

FIG. 34 Displays the (a) Microscope photograph showing two different sizes of scribelines in a patterned wafer. b) Schematic representation of the cross-sectional geometry of the wafers.

FIG. 35 Displays a Microscope photograph of a characteristic region located 2 cm away from the wafer flat, showing the topology of PTR line scans.

FIG. 36 Displays the PTR signal amplitude (a) and phase for six positions (three SiO₂ and three poly-Si pads) shown in FIG. 35.

FIG. 37 Displays the PTR signal amplitude (a) and phase (b) thermolectronic images for region A shown in FIG. 34(a).

Depth Profilometry/Roughness Elimination Algorithm Figures

FIG. 38 Illustrates the depth profilometric region under investigation.

FIG. 39 Illustrates the frequency-domain photothermal radiometric instrumentation.

FIG. 40 Displays the experimental data and forward theoretical fit of untreated AISI 8620 steels samples.

FIG. 41 Displays the thermal diffusivity reconstruction of untreated AISI 8620 steels samples.

FIG. 42 Displays a simulation of roughness elimination method with 1.6 μm roughness thickness.

FIG. 43 Displays a simulation of roughness elimination method with 7 μm roughness thickness.

FIG. 44 Displays simulation of roughness elimination method with 13 μm roughness thickness.

FIG. 45 Shows an experimental elimination of roughness with 1.6 μm roughness thickness.

FIG. 46 Shows an experimental elimination of roughness with 5.6 μm roughness thickness.

FIG. 47 Shows an experimental data of carburized samples at depths 0.02″, 0.04″ and 0.06″ with two levels of roughness.

FIG. 48 Shows an elimination of roughness of carburized samples of FIG. 45.

FIG. 49 Shows the thermal diffusivity reconstruction of carburized samples of FIG. 46. Hardness profile for each respective depth also shown.

FIG. 50 Displays the PTR amplitude (a) and phase (b) frequency response from a stainless steel thermal spray coating on a carbon steel substrate. The solid line is the Gaussian fit to the high frequency experimental data.

FIG. 51 Displays the PTR amplitude (a) and phase (b) frequency response from the stainless steel thermal spray coating on a carbon steel substrate of FIG. 48. The high frequency data has been corrected by the roughness elimination methodology.

Micro-Weld Application Figures

FIG. 52 Displays a CCD camera image of pins 1-to-4 of sample 8f2 (90 gf) examined using PTR

FIG. 53 Displays the PTR phase (a) and amplitude (b) image at 10 kHz for pin 1 of sample 8f2 (bonding force was 90 gf)

FIG. 54 Displays the PTR amplitude (a) and phase (b) frequency scans for pin 1-to-3 of sample 8f2 (bonding force was 90 gf)

### PRIOR ART

i) Conventional Photothermal Frequency Scan Method

The differences between the conventional frequency scan method and the common-rejection mode method, and the frequency-sweep (“chirp”) method are best understood by comparison of the various methods. The conventional frequency scan method will be first described followed by a description of the sweep frequency (Chirp), and the common rejection mode.

In a conventional photothermal radiometric embodiment, one dimensional analysis of the diffusion of the thermal wave generated inside a solid strip of thickness L by a laser beam modulated at angular frequency ω, yields the following expression for the a.c. temperature at the irradiated surface:

$$T ( ω ) = \frac{{I}_{o} {η}_{s}}{{k}_{s} {σ}_{s} ( 1 + {b}_{gs} )} \cdot \frac{1 + {R}_{gs} exp ( - 2 {σ}_{s} L )}{1 - {R}_{gs}^{2} exp ( - 2 {σ}_{s} L )} \qquad ( 1 )$$

[see G. Busse and H. G. Walther, in Progress in Photoacoustic and Photothermal Science and Technology, edited by A. Mandelis, Vol. I, Chapter 5, p. 205, (Elsevier, New York, 19991)], where kₛ is the thermal conductivity of the sample; Iₒ is the laser irradiance; ηₛ is the optical-to-thermal energy conversion efficiency at the sample surface; and b_{gs} is the thermal coupling coefficient to the surrounding gas (air) given by:

$${b}_{gs} = \frac{{k}_{g} / \sqrt{{α}_{g}}}{{k}_{s} / \sqrt{{α}_{s}}} \qquad ( 2 )$$

Here kⱼ is the thermal conductivity and αⱼ is the thermal diffusivity of medium j with the subscripts s and g referring to the sample and the gas, respectively. The quantity R_{gs} given by:

$${R}_{gs} = \frac{1 - {b}_{gs}}{1 + {b}_{gs}} \qquad ( 3 )$$

is the thermal-wave reflection coefficient at the solid-gas interface and σₛ is a complex diffusion coefficient given by:

$${σ}_{s} = ( 1 + i ) \sqrt{\frac{2 {α}_{s}}{ω}} \qquad ( 4 )$$

It is assumed that the solid and air are in perfect thermal contact. Expressions for the measured quantities, phase and amplitude, can be derived from the real and imaginary parts of Equation 1. The measurements are made with respect to a thermally thick (L>>μ) reference sample where the signal is given by:

$${T}_{ref} ( ω ) = \frac{I o {η}_{r}}{{k}_{r} {σ}_{r} ( 1 + {b}_{g r} )} \qquad ( 5 )$$

The signal from the semi-infinite reference sample is used to compensate for the instrumental transfer function. For radiometric detection both T(ω) and T_{ref}(ω) expressions must be multiplied by terms including surface emissivity, detector parameters, ambient temperature, etc. This constant multiplicative term, except for the sample dependent terms, is cancelled out from the normalized amplitude signal, Equation 1, divided by Equation 5; and from the normalized phase signal in Equation (1), subtracted from the phase in Eq. (5).

By fitting the normalized experimental data (phase and amplitude) frequency dependence to the corresponding expressions derived from Equation 1, the parameters R_{gs} and L/(α)^{½} can be calculated. Since the coupling medium is usually air [k_{g}=0.026 Wm⁻¹K⁻¹, α_{g}=3.1×10−5 m²s²; A. Rocencwaig, Photoacoustics and Photoacoustic Spectroscopy, Chem. Anal. Vol. 57 (J. Wiley & Sons, New York, 1980), p. 96], the value of b_{gs}<<1. Therefore, R_{gs} is almost unity and its sensitivity to kₛ is extremely small. That simplification renders L/(α)^{½} the only fitting parameter for normalized phase data. In addition to L/(α)^{½} the normalized amplitude data contain a multiplicative factor due to any differences in the bulk thermal properties and the surface finish (e.g. roughness) and its possible differences between the sample and the reference. This factor may be cancelled out by setting the amplitude ratio to be unity at the high frequency (thermally thick) end, where the phase difference is expected to be zero. Setting the amplitude ratio equal to unity is possible because we are only interested in the shape of the normalized curve, not in the absolute magnitude. However there is a very real possibility that the surface “finishes” will overlap the lower frequency regions in either or both sampleand reference, in which case the “setting-to-unity” method will not work. For such cases a roughness elimination algorithm from the high-f “humps” developed by L. Nicolaides and A. Mandelis can be used (see section below). Since there exist extrema in the frequency curve of both amplitude and phase (thermal-wave interference), which are very sensitive to L/(α)^{½}, it is not necessary to fit an entire frequency range. These extrema could be used as a fast on-line measurement of small variations in L or αₛ in an industrial environment.

ii) Conventional Photothermal Electronic Lifetime Measurement Methods.

For sometime now several laser-based photothermal techniques have been developed to monitor photoexited carrier kinetics and transport properties in semiconductors, the advantage over other, mainly electrical, methods being that electronic effects can thus be monitored in a non-contacting and non-destructive manner, therefore eliminating the need for electrode attachment [A. Rocencwaig, in Photoacoustic and Thermal-Wave Phenomena in Semiconductors, edited by A. Mandelis (Elsevier, New York, 1987); M. Wagner, N. Winkler and H. D. Geiler, Appl. Surf. Sci. 50, 373 (1991); A. Skumanich, D. Fournier, A. C. Boccara and N. M. Amer, Appl. Phys. Lett. 47, 402 (1985); A. Mandelis, A. A. Ward and K. T. Lee, J. Appl. Phys. 66, 5584 (1989)]. A distinct disadvantage of those photothermal techniques, however, is the fact that with either frequency-scanned detection [A. Rocencwaig, in Photoacoustic and Thermal-Wave Phenomena in Semiconductors, edited by A. Mandelis (Elsevier, New York, 1987); ); A. Mandelis, A. A. Ward and K. T. Lee, J. Appl. Phys. 66, 5584 (1989)], both free carrier (plasma)-wave and thermal wave responses from semiconductors are strongly coupled together [A. Mandelis and R. E. Wagner, Jpn. J. Appl. Phys. 35, 1786 (1996)]. As a result the interpretation of the convoluted experimental data is usually complicated. The task of deconvoluting the two types of responses becomes cumbersome, and this renders much of the analysis qualitative. As an example, the photomodulated thermoreflectance (PMOR) technique [A. Rocencwaig, in Photoacoustic and Thermal-Wave Phenomena in Semiconductors, edited by A. Mandelis (Elsevier, New York, 1987), Chap. 5] produces signals ΔR which depend on both the a.c. temperature of the laser-excited semiconductor surface ΔT(ω), and on the photogenerated electron-hole plasma wave ωN(ω),

$$Δ R ( ω ) = ( \frac{\partial R}{\partial T} ) Δ T ( ω ) + ( \frac{\partial R}{\partial N} ) Δ N ( ω ) \qquad ( 6 )$$

Very tightly focused (˜1 μm²) pump beams can, in principle, lead to the domination of PMOR by the plasma response, yet this constraint almost invariably gives rise to unwanted non-linear phenomena, such as Auger recombination, which further complicate the quantitative aspects of the technique [R. E. Wagner and A. Mandelis, Semicond. Sci. Technol. 11, 289 (1996); and 300 (1996)]. Therefore, very tight laser focusing can be detrimental to the study of electronic defects, since the exceedingly high fluence may greatly perturb the experimental behavior of an electronic material.

Regarding laser infrared photothermal radiometry (PTR) of semiconductors, the pulsed (including spectral cross-correlation and impulse response) time-domain mode may exhibit severe overlap of free-carrier density and thermal effects [K. Cho and C. Davis, IEEE J. Quantum Electron. QE-25, 1112 (1989)] and non-optimized signal-to-noise ratio, SNR [A. Mandelis, Rev. Sci. Instrum. 65, 3309 (1994)]. Unlike the PMOR technique, it has been shown that the electronic (plasma-wave) component of the infrared emissivity PTR signal fully dominates the thermal-wave component in typical industrial Si wafers [A. Mandelis, R. Bleiss and F. Shimura, J. Appl. Phys. 74, 3431 (1993); A. Salnick, A. Mandelis, H. Ruda and C. Jean, J. Appl. Phys. 82, 1853 (1997)], thus making PTR the preferred method for industrial semiconductor metrologic technology development. In terms of physical interpretation of signals, the time-domain technique is considered preferable to the frequency-domain counterpart [S. J. Sheard M. G. Somekh and T. Hiller, Mater. Sci. Eng. B5, 101, (1990); Z. H. Chen, R. Bleiss, A. Mandelis and F. Shimura, J. Appl. Phys. 73, 5043 (1993)] due to the inherent ability of transient-response techniques to be interpretable in terms of simple system time-delay constants. The same information can be obtained, in principle, from the frequency-scanned data; however, this method requires the de-multiplexing of data over broad frequency ranges, typical of the existing relationship between Fourier tra-nsform pairs (i.e. time and frequency domains). Nevertheless, the superior frequency-domain SNR, which is achievable via lock-in filtering and demodulation, coupled with further improvements regarding either the substantial acceleration of the measurement process, or the SNR of the signal generation and processing techniques introduced in the present invention, renders the frequency-domain (FD) PTR mode the measurement method of choice for the development of novel industrial-level semiconductor metrologic technologies.

iii) Frequency-Swept Time-Delay-Domain (Chirp) Modulation in PTR Signal Generation and Processing

In the frequency swept optical excitation mode, the temporal equivalent of a single ultrashort excitation pulse is generated over the duration of e.g. a 100-kHz chirp and the sample impulse-response (or cross-correlation) information contained in the output signal spectral response is recovered using (but not only confined to) the photothermal correlation and spectral analysis techniques described by A. Mandelis, IEEE Trans. Ultrasonics, Ferroelectrics, Freq. Control, UFFC-33, 590 (1986). With regard to photothermal (including PTR) detection, the main advantages of this technique for industrial instrumentation and measurement system development over other techniques such as the pulsed laser method, the wideband random noise correlation method and the point-by-point lock-in FD photothermal method are: a) the much accelerated speed of signal data acquisition to less than one minute over the entire frequency span dc-100 kHz for 1024 co-added and averaged frequency sweeps; and b) the flexible signal acquisition nature, capable of yielding the impulse response and/or the transfer function of a sample from the same set of data via instrumental, real-time, fast-Fourier transformations, thus potentially facilitating interpretation and parameter extraction in terms of simple Green function formalisms. The major disadvantage of the chirp method is the less-than-optimal SNR owing to the broadband nature of the data acquisition and noise content, compared to the conventional point-by-point lock-in filtering and demodulation technique.

iv) PTR Depth Profilometry for Rough Samples

Depth profilometry is an important inverse problem where the thermal diffusivity profile is inverted from experimental surface information. Thermal diffusivity is a property that depends on the microstructural properties of a material and thus can be used to identify changes that take place in a material as a result of surface modification processes, such as laser processing, case hardening and coating deposition. The benefits of this methodology for processes such in the heat treating and thermal spray industries are immense since it implies the development of an on-line non-destructive method for rapidly determining the metallurgical properties of case treated material and thermal spray coatings.

In inhomogeneous materials, the amplitude and phase signal channels carry information about any heat transport disruption or change below the surface, which must be interpreted with appropriate models, in order to yield reliable reconstructions of the spatially variant thermal diffusivity of the sample. One of the first theories of this kind of inversions was described by Vidberg et. al. [H. J. Vidberg, J. Jarrinen and D. O. Riska, Can. J. Phys. 64, 1178 (1986)]. This model pertains to the thermal-wave surface signal obtained by measuring the radial variation of the surface temperature of a continuously inhomogeneous solid about a heated point at a single modulation frequency. Both thermal conductivity and heat capacity profiles were reconstructed using Pade approximants for the inversion of spatial Laplace transforms. There are a number of constraints which limit the applicability of this model. The most significant ones are: (1) it is only valid for a nonconventional experimental geometry; (2) the reconstructed profiles are not always numerically reliable; (3) the accuracy is limited to a depth reconstruction on the order of one thermal diffusion length; and (4) the reconstruction algorithm is relatively complex and is sensitive to the presence of small amounts of error. In an earlier publication Jaarinen and Luukkala [J. Jaarinen and M. Luukkala, J. Phys. (Paris) 44, C6-503 (1983)] discussed a numerical analysis of the same experimental geometry based on the solution of the thermal-wave equation at a single modulation frequency. The analysis uses a two-dimensional finite difference grid.

More recently, another major attempt [A. Mandelis, S. B. Peralta and J. Thoen, J. Appl. Phys. 70, 1761 (1991)] was made to approach the thermal-wave inverse problem more rigorously and for more general geometries than the foregoing papers. In this approach the well-known Hamilton-Jacobi formalism from Classical Mechanics was introduced into the thermal-wave problem by treating the a.c. temperature field as a Thermal Harmonic Oscillator (THO) [A. Mandelis, J. Math. Phys. 26, 2676 (1985)] and inverting the amplitude and phase of the experimental data through matching to explicit theoretical expressions for a semi-infinite solid (or liquid). The first experimental inversions were obtained from the liquid crystal octylcyanobiphenyl (8CB) [A. Mandelis, E. Schoubs, S. B. Peralta and J. Thoen, J. Appl. Phys. 70, 1771 (1991)] using this method. Further inversions with semi-infinite laser-processed solids were reported later [T-C. Ma, M. Munidasa and A. Mandelis, J. Appl. Phys. 71, 6029 (1992), M. Munidasa, T. C. Ma, A. Mandelis, S. K. Brown and L. Mannik, Mater. Sci. Eng. A159, 111 (1992)]. An inversion procedure for a finite thickness problem has also been reported based on the same THO approach [A. Mandelis, J. Math. Phys. 26, 2676 (1985)]. More recently, a newer model [C. Glorieux, J. Fivez and J. Thoen, J. Appl. Phys. 73, 684 (1993)] motivated by the approach described by Mandelis and co-workers [A. Mandelis, S. B. Peralta and J. Thoen, J. Appl. Phys. 70, 1761 (1991); A. Mandelis, J. Math. Phys. 26, 2676 (1985); A. Mandelis, E. Schoubs, S. B. Peralta and J. Thoen, J. Appl. Phys. 70, 1771 (1991); T-C. Ma, M. Munidasa and A. Mandelis, J. Appl. Phys. 71, 6029 (1992); M. Munidasa, T. C. Ma, A. Mandelis, S. K. Brown and L. Mannik, Mater. Sci. Eng. A159, 111 (1992); F. Funak, A. Mandelis and M. Munidasa, J. Phys. (Paris) IV, Colloque C7, 95 (1994)] was proposed, that assumed locally constant or linearly-dependent thermal conductivity on depth. In that work the solid was divided up into a virtual incremental discrete-layer system and in each layer forward and reverse thermal-wave equations were set up for constant conductivity and solved using computer-based matrix routines. The resulting equations were inverted for the depth-dependent increments of the value of the thermal conductivity using a commercially available nonlinear least-squares fit routine. It is well established that only true material discontinuities such as surfaces and not virtual incremental slices can generate reflected thermal waves. This raises questions about the validity and/or uniqueness of the inversions. Even if it is accurate for semi-infinite solids, the theory presents problems with the treatment of finite-thickness materials, as it ignores the multiple inter-reflections of the thermal wave between the two boundaries (surfaces) of the material. Fivez and Thoen reported yet another version [J. Fivez and J. Thoen, J. Appl. Phys. 75, 7696 (1994)] of the foregoing inversion problem with a linear dependence of the local (incremental) thermal conductivity with depth. Explicit expressions were derived and matched with experimental data and the results of the inversions were in good agreement with those obtained by the approach by Ma et al. [T-C. Ma, M. Munidasa and A. Mandelis, J. Appl. Phys. 71, 6029 (1992)]. The major shortcoming of this new approach is in its inability to treat semi-infinite solids, as the explicit formulas depend on the boundedness of the derived Bessel and Neumann functions. Instead, it requires flat profiles in the bulk of the material under investigation. This is so because many of the combinations of these functions utilized in this approach become infinite in value as the depth increases without bound. A recent theoretical approach by Lan et. al. [T. T. N. Lan, U. Seidel and H. G. Walther, J. Appl. Phys. 77, 4739 (1995)] combines the approaches of both prior papers [C. Glorieux, J. Fivez and J. Thoen, J. Appl. Phys. 73, 684 (1993), J. Fivez and J. Thoen, J. Appl. Phys. 75, 7696 (1994)]. Therefore, it has improved strengths, yet, it is subject to some combinations of their shortcomings: a flat profile of the thermal conductivity at large distances [T. T. N. Lan, U. Seidel, H. G. Walther, G. Goch and B. Schmitz J. Appl. Phys. 78, 4108 (1995)] (i.e. at “infinity”), to induce boundedness, along with the lack of a theoretical basis to treat multiple thermal-wave reflections from the opposite surfaces of finitely-thick samples. In a more recent theoretical paper [J. Fivez and J. Thoen, J. Appl. Phys. 79, 2225 (1996)] Fivez and Thoen presented a new analytical approach to the inverse problem which is valid for semi-infinite solids at sufficiently high frequencies, but shows significant deviations of reconstructed thermophysical profiles from the expected values at low frequencies (equivalent to large depths in a sample). Kolarov and Velinov [R. Kolarov and T. Velinov, J. Appl. Phys. 83 (4) (1998)] developed a method based on the Riccati first-order differential equation. The numerical method presented solved the general Riccati equation in real time. Recently, Walther and Akeshin [H. G. Walther and V. Aleshin, J. Appl. Phys. 86 (11) (1999)] developed a method which combines laterally scanned and frequency resolved measurements for the inspection of inhomogeneous samples. A lateral scan increases the ill-poseness of the problem since more degrees of freedom are introduced.

Mandelis et al. [A. Mandelis, F. Funak and M. Munidasa, J. Appl. Phys. 80 (10), 5570 (1996)] further formulated a complete generalized expression for the thermal-wave field in an inhomogeneous bounded solid. The method improved on the previously derived formulas [A. Mandelis, S. B. Peralta and J. Thoen, J. Appl. Phys. 70, 1761 (1991); T-C. Ma, M. Munidasa and A. Mandelis, J. Appl. Phys. 71, 6029 (1992); F. Funak, A. Mandelis and M. Munidasa, J. Phys. (Paris) IV, Colloque C7, 95 (1994)] based on the THO approach by ensuring proper convergence to limiting cases. A successful application of the method was further presented in [M. Munidasa, F. Funak and A. Mandelis, J. Appl. Phys. 83 (5) 3495(1998)]. The results were promising but the material roughness response on the experimental data was neglected.

In this invention a methodology based on the THO approach [A. Mandelis, J. Math. Phys. 26, 2676 (1985)], for the thermal-wave field in a semi-infinite inhomogeneous solid with a rough layer is disclosed.

### DETAILED DESCRIPTION OF THE INVENTION

A) Apparatus for Non-Destructively Measuring Electronic Parameters of Semiconductors and Thermal Parameters and Depth Profiles of Non-Electronic Materials

The novel complete instrumentation system (apparatus) using laser PTR as the preferred (but not sole) embodiment of the present invention for measuring the thermal and electronic transport parameters by means of the frequency scan, the frequency sweep (“chirp”), the common-rejection-mode signal generation and processing method, as well as by scanning wafer imaging at a fixed frequency, will now be described.

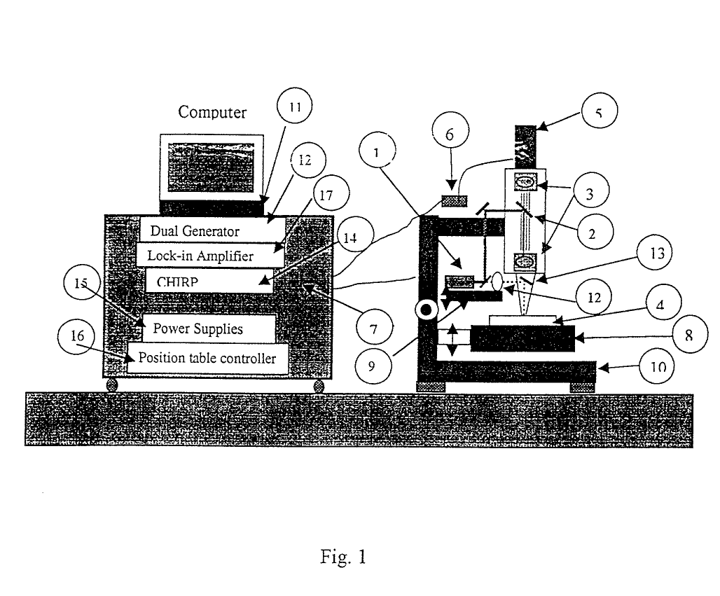

A schematic diagram of the apparatus for measuring thermal and electronic transport properties of substrate or processed semiconductor wafers or chips is shown in FIG. 1. A heating laser 1 with modulated power up to a few watts and super-bandgap wavelength (<1000 nm for Si or <600 nm for very-near-surface probing) is directed onto the surface of a sample 4 using focusing optics 3. The radiation emitted by the surface of the sample 4 is collected and focused onto a detector 5 using a pair of reflecting objectives 3 (two off-axis parabolloidal mirrors or one elliptical mirror can also be used). Detector 5 is a liquid-N2 cooled HgCdTe (EG & G Judson model J15D16-M204) with an active area of 1 mm² or less and a spectrally sensitive range of 2-10 μm. Other non-cryogenic IR detectors such as pyroelectric sensors or Golay cells can be substituted for the LN2 detector, as required. An anti-reflection (AR)-coated Ge window with a transmission bandwidth of 2-13 μm is mounted in front of detector 5 to block any visible radiation from the pump laser 5. The pump spot diameter on sample 4 is typically ca. 1 -to-5 microns. The photothermal signal, which is proportional to the change of the IR radiation emitted from an area viewed by detector 5, is amplified by a preamplifier 6 (EG & G Judson model PA-101) before being sent to a digital lock-in amplifier 13 (e.g. Stanford Research Systems, Model SR 850). Lock-in amplifier 13 is interfaced with a computer 11 so that the frequency scan and data acquisition and storage are automated. The laser can also be modulated by the FFT dynamic signal analyzer 14 or the dual pulse generator 12. The sample is mounted on an automated sample holder 8 with X-Y scaning capability for sample mapping applications through fast point-by-point image construction.

It will be appreciated by those skilled in the art that numerous other configurations for repetitively heating samples and measuring the resulting photothermal radiometric signal may be used. For example IR detectors cooled by other means than liquid nitrogen or modulated infrared sensor arrays (CCD) for imaging purposes. The above example is meant to be non limiting and illustrative only.

B) Methods of the Present Invention

i) Lock-in Common-Mode Rejection Method

a) Description of the Method

Thermophysical properties are, in general, an indicator of the degree of homogeneity of a given sample because they are strongly affected by variations occurring in the sample microstructure. An introduction to thermal-wave non-destructive detection can be found under “Background of the Invention”. Briefly, the common working principle of conventional photothermal techniques is based on the study of the periodic temperature distribution, i.e. the thermal wave, produced in a given sample as a result of heating due to an intensity modulated pump laser source impinging on the surface. Thermal waves inside a homogeneous sample diffuse over a characteristic distance, which is given by the thermal diffusion length μ(f)=(α/πf)^{½}, where α is the thermal diffusivity and f the modulation frequency. By changing the modulation frequency, the thermal wave propagates over different distances and probes the presence of thermal inhomogeneities located at various depths beneath the surface. In fact, thermal features inside the sample alter the heat transfer rate, thus affecting the resulting surface temperature distribution which is detected by various photothermal techniques. Finally, by analyzing the dependence of the photothermal signal from non-electronic materials on the modulation frequency, it is possible to derive some material parameters (thermal diffusivity, conductivity) and/or obtain information on inhomogeneities, such as position, size, depth profile, etc. This is the basic principle of all thermal wave inspection methods. Conventional frequency domain photothermal methods are basically single-ended techniques using an intensity-modulated heating beam intensity (either a 50% duty-cycle square wave, or a sinusoidal wave), and a lock-in amplifier (LIA) for signal processing. The limitations of single-ended detection are that, if the signal contributions from sample inhomogeneities are much smaller than that from the homogeneous bulk of the material (background signal), then they cannot be easily detected. In a single-ended technique the sensitivity of the experiment is determined by the magnitude of the background signal. Without further conditioning, the signal level is simply too high to probe variations of amplitude much smaller than this background. For the purposes of this invention, these very small variations will be called “contrast signals”.

As discussed under “Prior Art”, in order to obtain quantitative information about the sample properties, the photothermal signal must be normalized, i.e. compared to that obtained from a homogenous reference sample in order to account for the instrumental transfer function. Properly normalized signal amplitude ratios and phase differences must be collected as a function of the modulation frequency. This procedure introduces several problems especially when one intends to probe slightly inhomogeneous samples with theoretical contrast signals approaching the noise level of the experiment. In fact, the effect of normalization is, in general, to add some more noise to the measurement, thus resulting in poor SNR, which usually masks contrast signals. A strong noise reduction is required for these kinds of applications and conventional photothermal techniques do not compensate against slowly varying drift phenomena, which can occur during a measurement, because of their single-ended nature [C. -H. Wang and A. Mandelis, Rev. Sci. Instrum., (1999)]. All this despite the advantage of the narrow-bandwidth filtering action of the demodulating lock-in amplifier, since the noise frequency components within the filter bandwidth are not rejected and are still present and become enhanced during the normalization procedure.

The new lock-in common-mode-rejection demodulation scheme, introduced in this invention, seems to be very promising for high-resolution thermal-wave non-destructive material evaluation (NDE) applications. If the sample is irradiated with a periodic optical waveform consisting of two pulses, then the LIA output is basically given by the difference of the physical response waveforms produced by each of the two pulses. This fact is of fundamental importance toward the improvement of low-dynamic range techniques, such as thermal-wave NDE, in their ability to detect relatively small signal variations from slightly different materials. In practice, the differential action has the effect of suppressing the signal baseline, which leads to an enhanced detectivity when compared to conventional single-ended techniques. Thus, the instrumental sensitivity is not compromised by the high-level signal baseline and can easily match the level of small signal variations introduced by slightly different materials or by very weak inhomogeinities in a given material. The principle of the invention can be broadly applied to any technique utilizing a lock-in analyzer demodulation scheme of periodic signal waveforms.

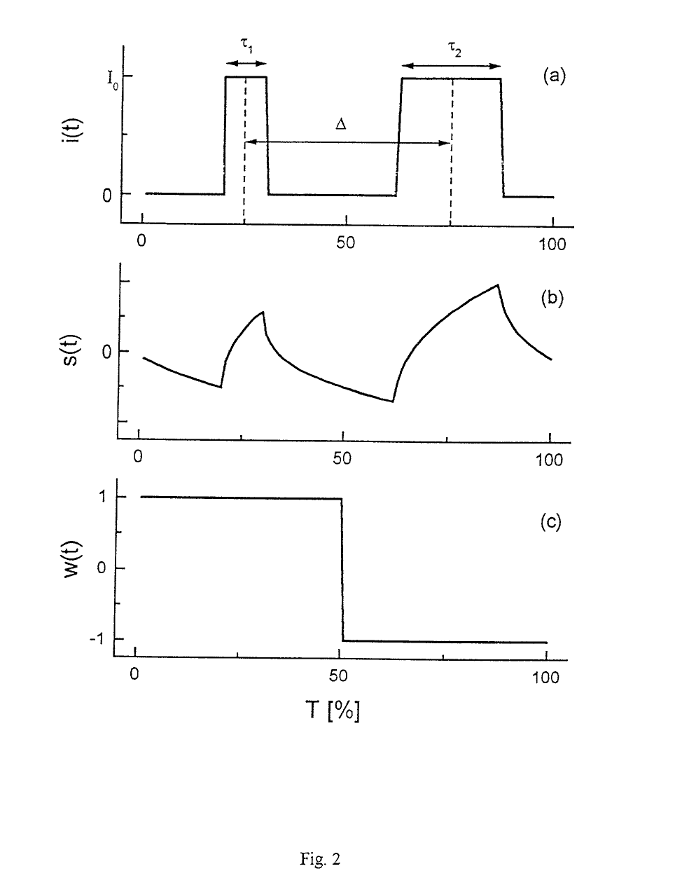

In order to achieve a differential input with a single excitation source and demodulation instrument, a new periodic optical excitation waveform, FIG. 2(a), has been designed, which exploits advantages due to the built-in weighing-function waveform of the LIA [G. L. Miller, J. V. Ramirez and H. A. Robinson, J. Appl. Phys. 46, 2638 (1975); A. Mandelis, Rev. Sci. Instrum. 65, 3309 (1994)]. As shown in FIG. 2(a), in a given period T the sample is excited by two square-wave pulses with center-to-center separation by a time interval Δ. As a consequence of the asymmetric periodic excitation, the transient (photothermal) response s(t) of the sample, FIG. 2(b), rises and decays twice during a period, also with a certain degree of asymmetry. The in-phase or quadrature component of the LIA response to the incoming signal s(t) with a long integration time constant may be written as [A. Mandelis, Rev. Sci. Instrum. 65, 3309 (1994)]

$$y ( t ) = {\int }_{0}^{T} s ( t ) w ( t ) ⅆ t = {\int }_{0}^{T / 2} ( + ) s ( t ) ⅆ t + {\int }_{T / 2}^{T} ( - ) s ( t ) ⅆ t \qquad ( 7 )$$

where w(t) is the square weighing function shown in FIG. 2(c) and assumed to have a zero-delay rising edge. Owing to the opposite signs of w(t) across the mid-period point T/2 for zero phase delay at t=0, the LIA acts like a real-time differential comparator whose output level is a measure of the degree of asymmetry of the two s(t) lineshapes in the two half periods. Therefore, with this waveform design, a differential input configuration is achieved, which suppresses the signal baseline and takes full advantage of the highly efficient noise suppression by the LIA due to its extremely narrow filtering.

The difference between analog and digital LIAs, which use square-wave and synthesized sine-wave reference signals, respectively, has been extensively treated elsewhere [A. Mandelis, Rev. Sci. Instrum. 65, 3309 (1994)]. The output is quantitatively the same for the two types of LIA, provided that a tracking filter is inserted into the input of the analog version, in order to reject the odd harmonics of the input signal.

b) Theory of Output Signal

In this section a theoretical description of the signal generation due to the new waveform of FIG. 2 will be given, providing analytical expressions for both the in-phase (IP) and quadrature (Q) components of the lock-in response. In particular, we are interested in pointing out how the signal output is influenced by the parameters of the composite optical waveform (τ₁, τ₂ and Δ). We will also demonstrate signal sensitivity to the response of the system under investigation. In the analysis, we assume that the system is excited with a repetitive waveform consisting of two square pulses within one period T having the same amplitude I₀, durations τ₁ and τ₂, and separation Δ. For periodic waveforms it is convenient to consider the Fourier series representation of i(t)

$$i ( t ) = {\sum }_{k = - ∞}^{+ ∞} {c}_{k} exp ( \frac{j 2 π kt}{T} ) \qquad ( 8 )$$

in complex form, or,

$$\begin{matrix}i ( t ) = \frac{{a}_{0}}{2} + {\sum }_{k = 1}^{+ ∞} [ {a}_{k} cos ( \frac{2 π kt}{T} ) + {b}_{k} sin ( \frac{2 π kt}{T} ) ] \\ with & ( 9 ) \\ {{c}_{k} = \frac{{a}_{k} - {jb}_{k}}{2} = \frac{1}{T}}_{- \frac{T}{2}}^{\frac{T}{2}} i ( t ) exp ( - \frac{j 2 π kt}{T} ) dt = \frac{1}{T} I ( \frac{k}{T} ) & ( 10 )\end{matrix}$$

where I(f) is the Fourier transform of i(t) calculated over one period. By applying the time shift property to the two-square-pulse Fourier transform, it is easy to show that

$$\begin{matrix}{c}_{k} = \{ \frac{{I}_{0}}{T} {τ}_{1} \frac{sin ( \frac{π k {τ}_{1}}{T} )}{\frac{π k {τ}_{1}}{T}} exp [ - j 2 π \frac{k}{T} ( \frac{T}{2} - \frac{Δ}{2} ) ] \} + \\ \{ \frac{{I}_{0}}{T} {τ}_{2} \frac{sin ( \frac{π k {τ}_{2}}{T} )}{\frac{π k {τ}_{2}}{T}} exp [ - j 2 π \frac{k}{T} ( \frac{T}{2} + \frac{Δ}{2} ) ] \}\end{matrix} \qquad ( 11 )$$

and, after some manipulation,

$$\begin{matrix}{c}_{k} = \frac{{( - 1 )}^{k} {I}_{0}}{π k} \{ cos ( \frac{π k Δ}{T} ) [ sin ( \frac{π k {τ}_{1}}{T} ) + sin ( \frac{π k {τ}_{2}}{T} ) ] + \\ j sin ( \frac{π k Δ}{T} ) [ sin ( \frac{π k {τ}_{1}}{T} ) - sin ( \frac{π k {τ}_{2}}{T} ) ] \}\end{matrix} \qquad ( 12 )$$

The LIA monitors only the fundamental component of the harmonic signal, so we can limit our attention to the first term of the Fourier series, the coefficients of which are given by

$$\begin{matrix}\begin{matrix}{c}_{1} = - \frac{{I}_{0}}{π} \{ cos ( \frac{π Δ}{T} ) [ sin ( \frac{π {τ}_{1}}{T} ) + sin ( \frac{π {τ}_{2}}{T} ) ] + \\ j sin ( \frac{π Δ}{T} ) [ sin ( \frac{π {τ}_{1}}{T} ) - sin ( \frac{π {τ}_{2}}{T} ) ] \}\end{matrix} & ( 13 ) \\ {a}_{1} = 2 Re ( {c}_{1} ) = - \frac{2 {I}_{0}}{π} cos ( \frac{πΔ}{T} ) [ sin ( \frac{{πτ}_{1}}{T} ) + sin ( \frac{{πτ}_{2}}{T} ) ] & ( 14 ) \\ {b}_{1} = - 2 Im ( {c}_{1} ) = \frac{2 {I}_{0}}{π} sin ( \frac{πΔ}{T} ) [ sin ( \frac{{πτ}_{1}}{T} ) - sin ( \frac{{πτ}_{2}}{T} ) ] & ( 15 )\end{matrix}$$

In order to calculate the LIA response to the excitation pulse train, we introduce the system frequency response S(f)=Re[S(f)]+jIm[S(f)] which can be unambiguously defined for each sample as the Fourier transform of the transient impulse response. In so doing, the LIA output may be written as:

Y(f)={[Re[S(f)]+jIm[S(f)]}(a₁+jb₁), (16)

which can be eventually decomposed into in-phase (IP) and quadrature (Q) components given by:

$$\begin{matrix}\begin{matrix}{Y}_{IP} = Re [ Y ( f ) ] \\ = - \frac{2 {I}_{0}}{π} \{ cos ( \frac{πΔ}{T} ) [ sin ( \frac{{πτ}_{1}}{T} ) + sin ( \frac{{πτ}_{2}}{T} ) ] Re [ S ( f ) ] + \\ sin ( \frac{πΔ}{T} ) [ sin ( \frac{{πτ}_{1}}{T} ) - sin ( \frac{{πτ}_{2}}{T} ) ] Im [ S ( f ) ] \}\end{matrix} \\ and & ( 17 ) \\ \begin{matrix}{Y}_{Q} = Im [ Y ( f ) ] \\ = \frac{2 {I}_{0}}{π} \{ sin ( \frac{πΔ}{T} ) [ sin ( \frac{{πτ}_{1}}{T} ) - sin ( \frac{{πτ}_{2}}{T} ) ] Re [ S ( f ) ] - \\ cos ( \frac{πΔ}{T} ) [ sin ( \frac{{πτ}_{1}}{T} ) + sin ( \frac{{πτ}_{2}}{T} ) ] Im [ S ( f ) ] \}\end{matrix} & ( 18 )\end{matrix}$$

It can be seen that, in order to obtain a true differential output, the pulse widths must be different. Otherwise, the effect of the new optical waveform is only to generate a signal equivalent to that obtained from the conventional frequency scan method, from which it differs only by a multiplicative (amplitude) factor. This is physically reasonable, because the effect of two equal-width pulses is the same in the two half periods, FIG. 2, and as a result it does not reveal the asymmetric behavior of the response s(t). If τ₁ is different from τ₂, then the mixer—low-pass filter action of the LIA mixes the IP- and Q-channel signals created by the single-ended or by the equal-width two-pulse waveform. It is most interesting that the demodulated signal output multiplication factors are the real and the imaginary part of the response S(f). In fact, by choosing suitable values of τ₁,τ₂, Δ, it is possible to balance the two terms of the IP and Q components so as to obtain zero magnitude for either the IP or the Q signal channel.

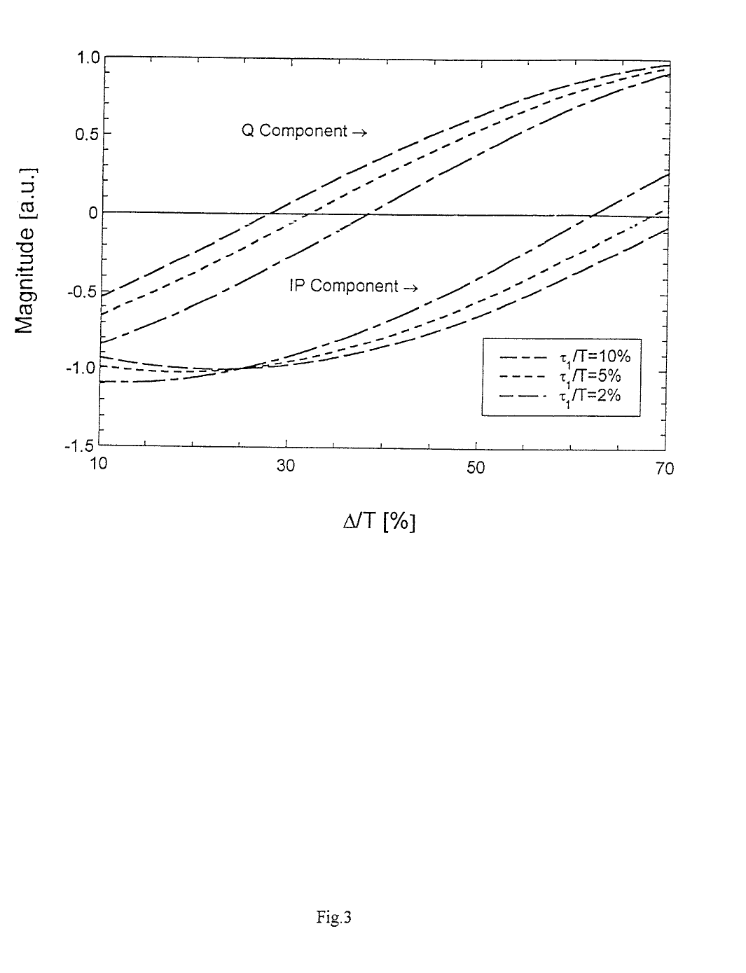

FIG. 3 shows the theoretical behavior of the IP and Q channel outputs obtained for Re[S(f)]/Im[S(f)]=−1 (as we are going to show in the next paragraph, in the photothermal case this condition corresponds to having a thermally homogeneous sample) as a function of the pulse separation Δ for different τ₁/T values. The plots clearly show the existence of particular pulse separation values Δ_{0,IP} and Δ_{0,Q} for which the IP or the Q component is equal to zero. Modifying the properties of the system leads to different values of the ratio Re[S(f)]/Im[S(f)], thus shifting the output zero to a new position along the Δ axis provided that τ₁ and τ₂ are fixed. The IP and Q loci of the zero crossing points can be derived from Eqs. (17) and (18), and are given by the following expressions:

$$\begin{matrix}tan ( \frac{{πΔ}_{0 , IP}}{T} ) = \{ \frac{Re [ S ( f ) ]}{Im [ S ( f ) ]} \frac{sin ( \frac{{πτ}_{1}}{T} ) + sin ( \frac{{πτ}_{2}}{T} )}{sin ( \frac{{πτ}_{2}}{T} ) - sin ( \frac{{πτ}_{1}}{T} )} \} \\ and & ( 19 ) \\ tan ( \frac{{πΔ}_{0 , Q}}{T} ) = \{ \frac{Im [ S ( f ) ]}{Re [ S ( f ) ]} \frac{sin ( \frac{{πτ}_{1}}{T} ) + sin ( \frac{{πτ}_{2}}{T} )}{sin ( \frac{{πτ}_{2}}{T} ) - sin ( \frac{{πτ}_{1}}{T} )} \} & ( 20 )\end{matrix}$$

The existence of zeros in the outputs appears promising, because relatively small variations in the response of a physical system can be readily obtained from the position of the zero on the Δ axis for different values of τ₁ or τ₂. Moreover random fluctuations of the signal amplitude, which normally are not suppressed by LIA filtering [C. -H. Wang and A. Mandelis, Rev. Sci. Instrum., (1999)], affect less the response of the experiment. Of course, an additional noise suppression factor in this technique is the constant, single-frequency bandwidth used for the entire measurement [J. Shen, A. Mandelis, and B. D. Aloysius, Int. J. Thermophys. 17, 1241 (1996)]. This substantially limits the noise output compared to the variable bandwidth of a conventional frequency- or time-scan [M. Munidasa and A. Mandelis, Rev. Sci. Instrum. 65, 2344 (1994)] and is an instrumental feature commonly shared with the single pulsewidth-scan LIA method [A. Mandelis and M. Munidasa, U.S. Pat. No. 5,667,300 (Sep. 16, 1997)]

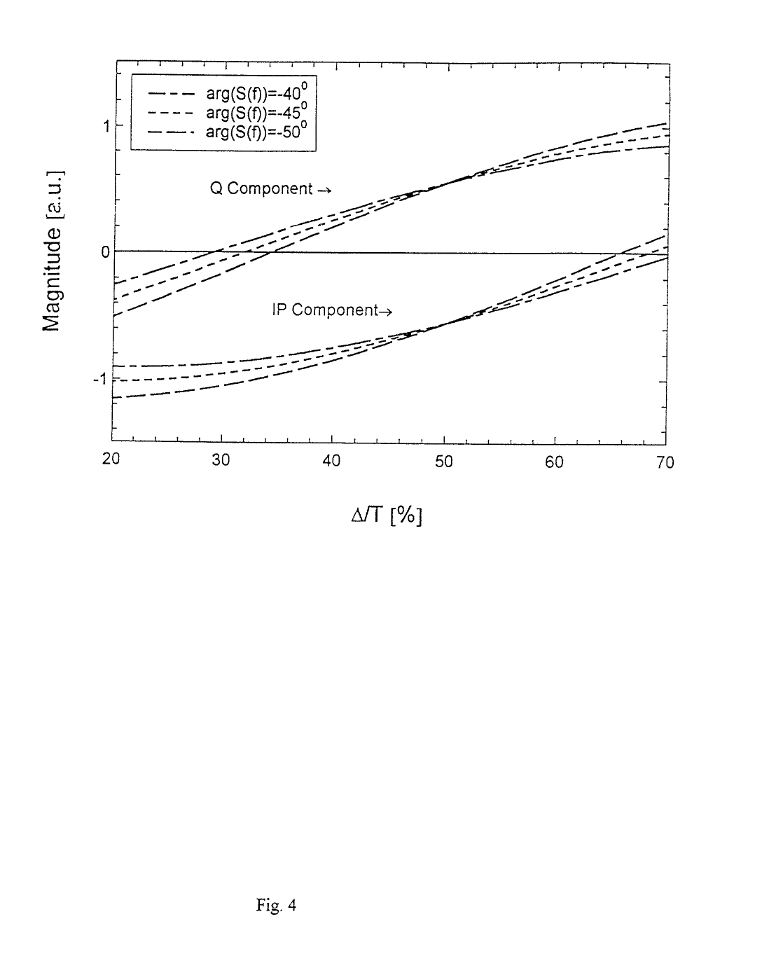

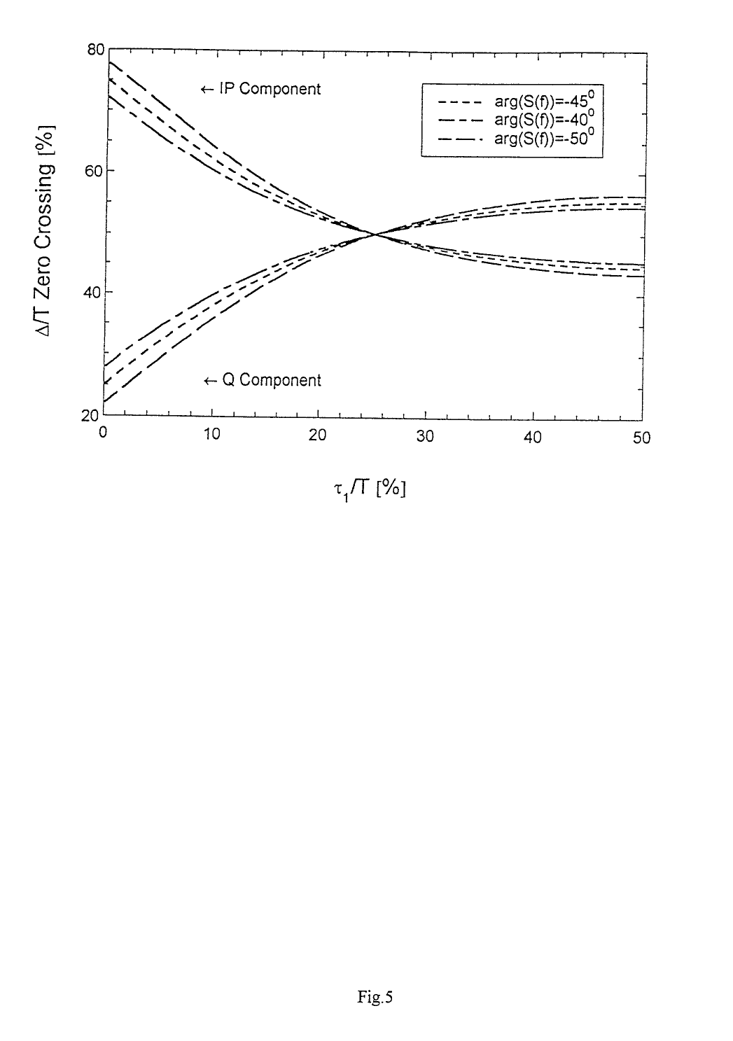

In FIG. 4 both the IP and Q amplitude, calculated according to Eqs. (17) and (18), are shown as functions of the pulse separation for τ₁/T=5%, τ₂/T=25% and for different Im[S(f)]/Re[S(f)] ratios corresponding to the arg[S(f)] values reported in the inset. The Q component crosses the zero magnitude axis at lower values of Δ than the IP component. This can be understood in terms of the fact that the odd w(t) weighing function used at the mixing stage to obtain the Q component is the one actually shown in FIG. 2(c). The even weighing function used to obtain the IP component is shifted by T/2, which implies an equivalent shift of the zero positions close to the upper edge of the Δ/T axis. FIG. 5 shows the locus of zeroes as a function of τ₁ for τ₂/T=25% and for the arg[S(f)] values shown in the inset. It is seen that the greater the difference in value between pulsewidths τ₁ and τ₂, the better the loci positions are resolved. This reflects, again, the fact that the use of two different pulse widths forces the response to show a measurably different behavior in the two half periods. These facts corroborate the use of narrow pulsewidths. Long pulsewidths limit the available Δ scan range and hence the resolution of the experiment. In some experimental situations, such as photothermal measurements in transmission across the thickness of a material, the magnitude of one of the two LIA channels is much greater than that of the other, zero-crossing, channel. This may adversely affect the effectiveness of the technique by forcing the LIA baseline to remain high for both channels. In those situations the baseline can be lowered and the effectiveness of the technique can be restored by e.g. using an appropriate lock-in analyzer, such as the EG&G models 7220, 7260 or 7265 with the availability of a synchronous oscillator signal to produce an offsetting voltage or current signal into the differential input amplifier. The offsetting method is described in the EG&G Application Note AN 1001, “Input Offset Reduction using the model 7265/7260/7220 Synchronous Oscillator/Demodulator Monitor Output” and must be used in combination with the lock-in common-mode rejection method as an integral part of the present invention.

c) An Application of the Lock-In Common-Mode-Rejection Method Using Laser PTR Diagnostics.

In this application, measurements obtained on a homogeneous Zr alloy sample will be presented by way of example for the present invention. These measurements will be further compared with that obtained by irradiating the sample with the conventional 50% duty-cycle square wave, in order to compare their noise characteristics. Finally, some preliminary measurements on Zr-2.5Nb shot-peened samples will be presented as a case study of weakly inhomogeneous solids and for comparison with that obtained with the conventional frequency scan.

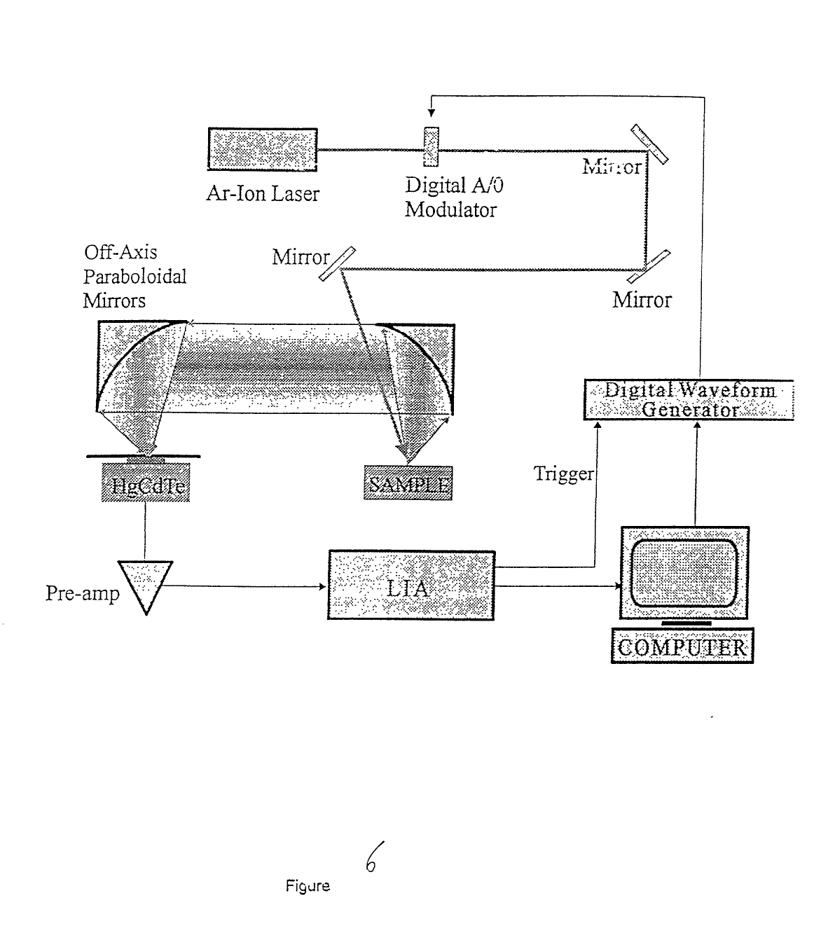

A simple PTR embodiment of the common-mode-rejection LIA methodology was constructed. A schematic diagram of the experimental setup used to perform the PTR measurements is shown in FIG. 6 and it comprises a sub-set of the full system shown in FIG. 1. An Ar-ion laser (514 nm) from Coherent, model Innova 100, was used as a 250-mW pump beam with a 2-mm spot size impinging on the sample surface. The beam was intensity modulated by an acousto-optic modulator (AOM), the digital driver of which was connected to a four-channel delay digital generator (Stanford Research Model DG535). The digital delay generator allows the construction of the variable-width two-square-pulse waveform through appropriate computer-controlled software and is used to drive the AOM through the driver. The emitted IR radiation from the sample was collected and focused onto the detector using two Ag coated off-axis paraboloidal mirrors. The PTR optical detection circuit was as described in FIG. 1. The PTR signal from the detector was pre-amplified (EG&G Judson Model PA 350) and fed to an analog LIA (EG&G Model 5210), which also provided the external triggering signal for the digital delay generator. A personal computer was used to control the modulation waveform and to store the LIA signal components.

Several experiments were performed using a crystalline Zr alloy “reference” sample. One experiment consisted of recording the PTR signal as a function of the two-pulse separation for different widths of the first pulse while the width of the second pulse was kept fixed (τ₂/T=25%). The separation scan range was limited by the necessity to avoid the overlapping of the two pulses. In fact, linear conduction heat transfer theory relies on a linear superposition of the effect of each pulse, which further implies that the optical intensity should be two times higher when the pulses are driving the AOM in tandem. This condition is not fulfilled under normal, single-ended working conditions of the modulator. The aim of these measurements was to measure the instrumental time-delay shift that inevitably occurs between the reference and the optical excitation waveform due the finite risetime of the modulator and the peripheral electronics. In order to fit the data, the theoretical expressions for the IP and Q components of the LIA have been modified by inserting a time delay term d

$$\begin{matrix}\begin{matrix}{Y}_{IP} ( f ) = - \frac{2 {I}_{0}}{π} \{ cos ( \frac{π ( Δ + d )}{T} ) [ sin ( \frac{{πτ}_{1}}{T} ) + \\ sin ( \frac{{πτ}_{2}}{T} ) ] Re [ S ( f ) ] + \\ sin ( \frac{π ( Δ + d )}{T} ) [ sin ( \frac{{πτ}_{1}}{T} ) - \\ sin ( \frac{{πτ}_{2}}{T} ) ] Im [ S ( f ) ] \}\end{matrix} \\ and & ( 21 ) \\ \begin{matrix}{Y}_{Q} ( f ) = \frac{2 {I}_{0}}{π} \{ sin ( \frac{π ( Δ + d )}{T} ) [ sin ( \frac{{πτ}_{1}}{T} ) - \\ sin ( \frac{{πτ}_{2}}{T} ) ] Re [ S ( f ) ] - \\ cos ( \frac{π ( Δ + d )}{T} ) [ sin ( \frac{{πτ}_{1}}{T} ) + \\ sin ( \frac{{πτ}_{2}}{T} ) ] Im [ S ( f ) ] \}\end{matrix} & ( 22 )\end{matrix}$$

The introduction of the delay term d shifts the crossing points for the IP and Q channels, which, according to Eqs.(21) and (22), must be modified as follows

$$\begin{matrix}tan [ \frac{π}{T} ( {Δ}_{0 , IP} + d ) ] = \{ \frac{Re [ S ( f ) ]}{Im [ S ( f ) ]} \frac{sin ( \frac{{πτ}_{1}}{T} ) + sin ( \frac{{πτ}_{2}}{T} )}{sin ( \frac{{πτ}_{2}}{T} ) - sin ( \frac{{πτ}_{1}}{T} )} \} & ( 23 ) \\ tan [ \frac{π}{T} ( {Δ}_{0 , Q} + d ) ] = \{ \frac{Im [ S ( f ) ]}{Re [ S ( f ) ]} \frac{sin ( \frac{{πτ}_{1}}{T} ) + sin ( \frac{{πτ}_{2}}{T} )}{sin ( \frac{{πτ}_{2}}{T} ) - sin ( \frac{{πτ}_{2}}{T} )} \} & ( 24 )\end{matrix}$$

The experimental results have been fitted to the theoretical expressions (21) and (22) by using d as an adjustable parameter (fixed for a given repetition frequency), and assuming Re[S(f)]=−Im[S(f)], which is theoretically consistent with the assumption of a homogeneous (reference) sample [See, for example, G. Busse and H. G. Walther in Progress in Photothermal and Photoacoustic Science and Technology Vol. I: Principles and Perspectives of Photothermal and Photoacoustic Phenomena, (A. Mandelis, Ed., Elsevier, New York, 1992), Chap. 5, pp. 207-298]. It should be noted that, like the single-ended technique, the use of a “reference” sample here may be confined to calculating the one-point instrumental transfer-function phase shift at the given frequency. Furthermore, the position of the two zero-crossing signal magnitude points (one for the IP and one for the Q channel) can also be labeled as belonging to a homogeneous sample. Nevertheless, the former operation is not essential when only the degree of departure from homogeneity of a test sample is required. This method may thus be used without signal normalization requirements to measure small relative signal variations between slightly different samples.

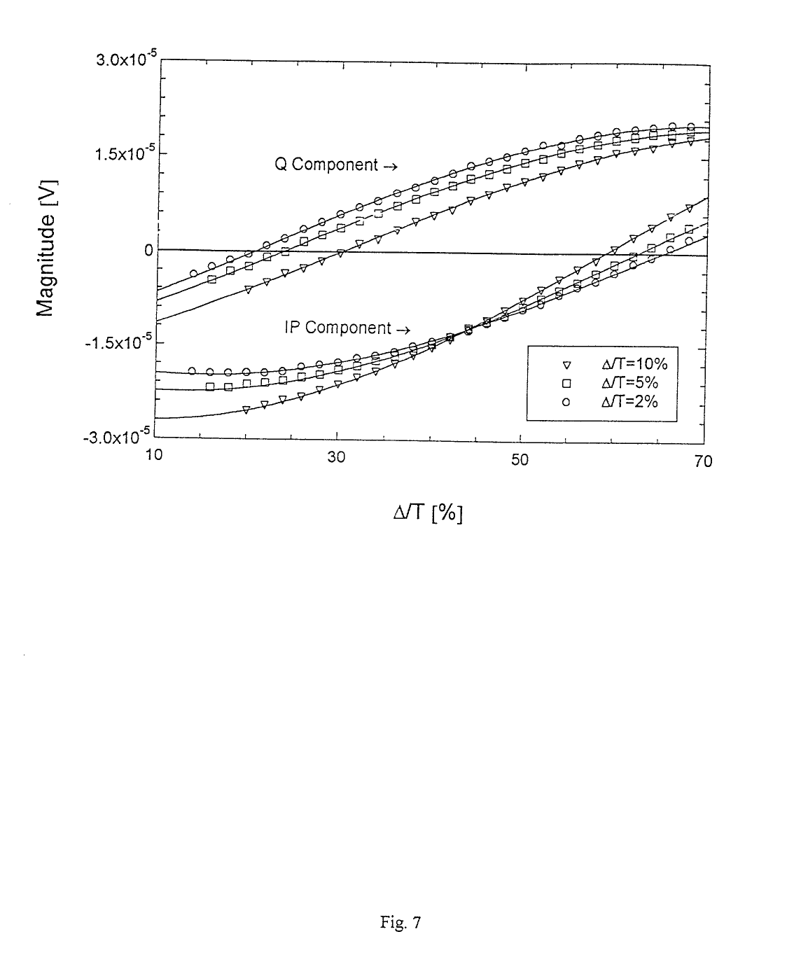

Measurements with the Zr alloy sample were performed at three modulation frequencies (0.5, 5 and 10 kHz). Typical experimental results are shown together with their theoretical fits in FIG. 7. We wish to point out the excellent agreement between theory and experimental results, which is indicative of the potential of the technique, in view of the very low signal levels encountered, especially at 10 kHz. This is the result of the efficient noise suppression, in part due to the common-mode rejection by the differential operation performed by the LIA, and in part due to the constant noise bandwidth of the fixed-frequency operation, as discussed earlier on.

In Table I, the instrumental delays obtained for both the IP and Q components are shown for the various modulation frequencies of this application. It is noted that for a given frequency the delay values for the Q component are quite independent of τ₁ as they should be, while those for the IP component reveal a greater scatter. It is believed that this is due to the fact that the zeroes of the IP component are close to the upper edge of the Δ scan, FIG. 7, and the fitting procedure cannot afford the same quality as that for the Q component. For this reason attention will henceforth be limited only to the Q component of the signal.

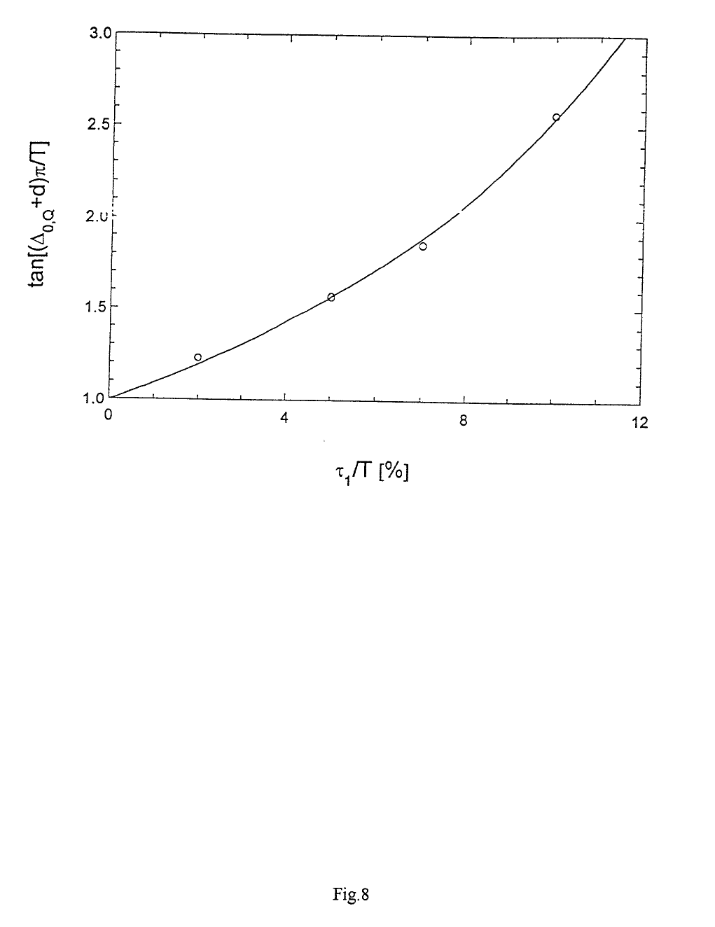

In order to study the influence of the scatter in the delay data on the performance of the experiment, we inserted the average d value in Eq. (22) reported in the last row of Table I, and we fitted again all the data in order to find the Im[(S(f)]/Re[S(f)] ratio or, equivalently, the Δ_{0,Q} zero crossing positions. The tan[(Δ_{0,Q}+d)π/T] values obtained for the Q component at 5 kHz as a function of τ₁/T are reported in FIG. 8, together with the theoretical interpolation given by Eq. (10) with Im[(S(f)]/Re[S(f)] as a parameter. The quality of the fits for the remaining frequencies (0.5 and 10 kHz) was very similar. It is concluded that the d-value scatter has a negligible effect on the output response, which results in excellent agreement between the experimental data and the expected theoretical result for Zr (Im[S(f)]/Re[S(f)]=−1); see first row of Table II. This agreement means that, in general, the instrumental delay can be assumed constant for a given frequency, as long as distortions are not introduced in the optical waveform shape. Moreover it should be noted that this calibration is sample independent. This means that for a given experimental apparatus the delay values remain the same and it is not necessary to repeat the calibration.

TABLE I
Delay term d/T as a function of f and τ₁/T obtained by
fitting the IP and Q components of the Zr response to Eqs. (1) and
(2) assuming Re[S(f)] = −Im[S(f)]. τ₂/T was
equal to 25%. Last row shows the average d value in each column.

| | | |
|---|---|---|
| f = 500 Hz | f = 5 kHz | f = 10 kHz |

| τ₁/T [ | IP | Q | IP | Q | IP | Q |
|---|---|---|---|---|---|---|
| 2 | 2.2 | 2.36 | 2.22 | 2.39 | 6.98 | 7.13 |
| 5 | 2.1 | 2.28 | 2.02 | 2.87 | 5.47 | 8.09 |
| 7 | 2.1 | 2.39 | 2.07 | 3.11 | 4.44 | 8.10 |
| 10 | 1.9 | 2.05 | 1.22 | 2.76 | 2.88 | 7.94 |
| | 2.1 | 2.3 | 2.9 | 2.8 | 5 | 8 |

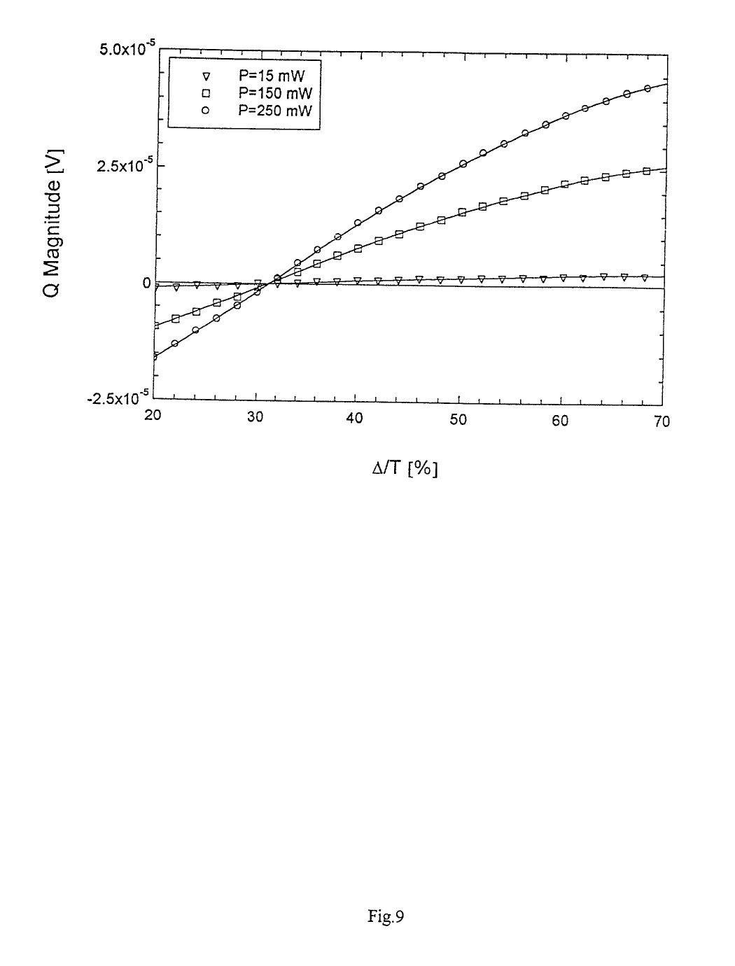

In order to evaluate the robustness of this new methodology, the same pulse separation scans have been performed for various pump laser powers. Conventional frequency scans have also been carried out in parallel under the same experimental conditions, in order to compare the relative SNR. In FIG. 9 the Q component is reported as a function of pulse separation. As can be seen, even the data corresponding to the lowest power are in agreement with the other sets despite the very low magnitude (less than 2 μV). The varying slopes of the experimental data about the zero crossing point are due to the corresponding S(f) amplitudes. The zero crossing points are coincident for all experimental laser powers, as expected from the same sample, and very good noise rejection is observed.

TABLE II
Im[S(f)]/Re[S(f)] ratio values for the three investigated
samples (two shot-peened Zr-2.5 Nb alloys and the reference Zr
sample), obtained by fitting the zero crossing points to Eq. (18).

| SAMPL | f = 0.5 kHz | f = 5 kHz | f = 10 kHz |
|---|---|---|---|
| Zr | −1.01 | −0.99 | −1.00 |
| C5 | −0.928 | −0.955 | −0.996 |
| N7 | −1.12 | −0.929 | −0.964 |

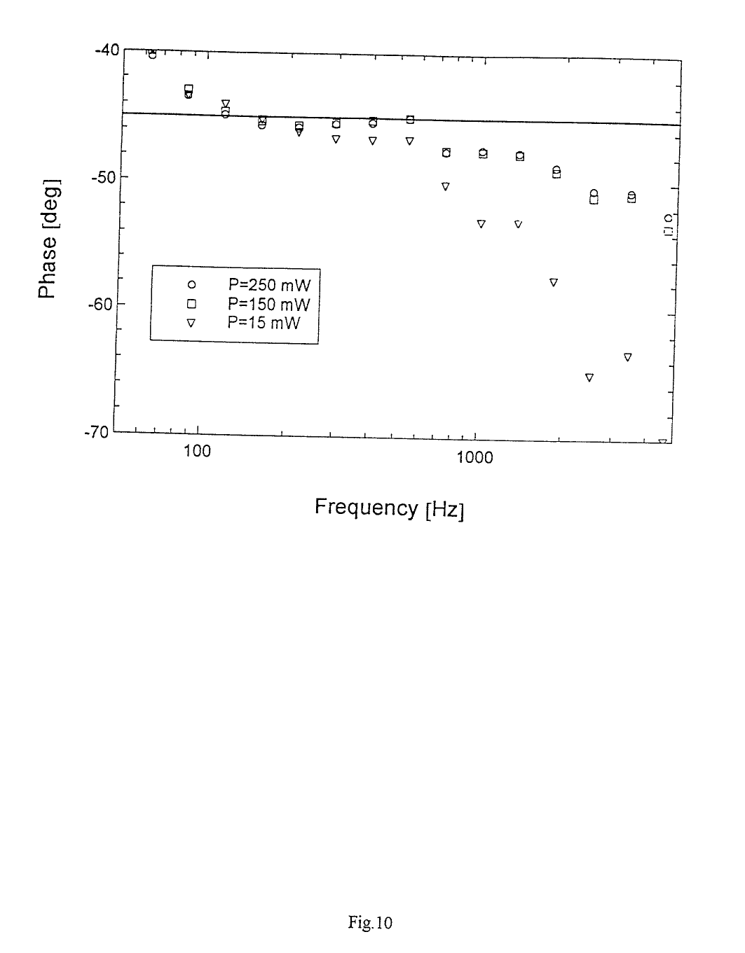

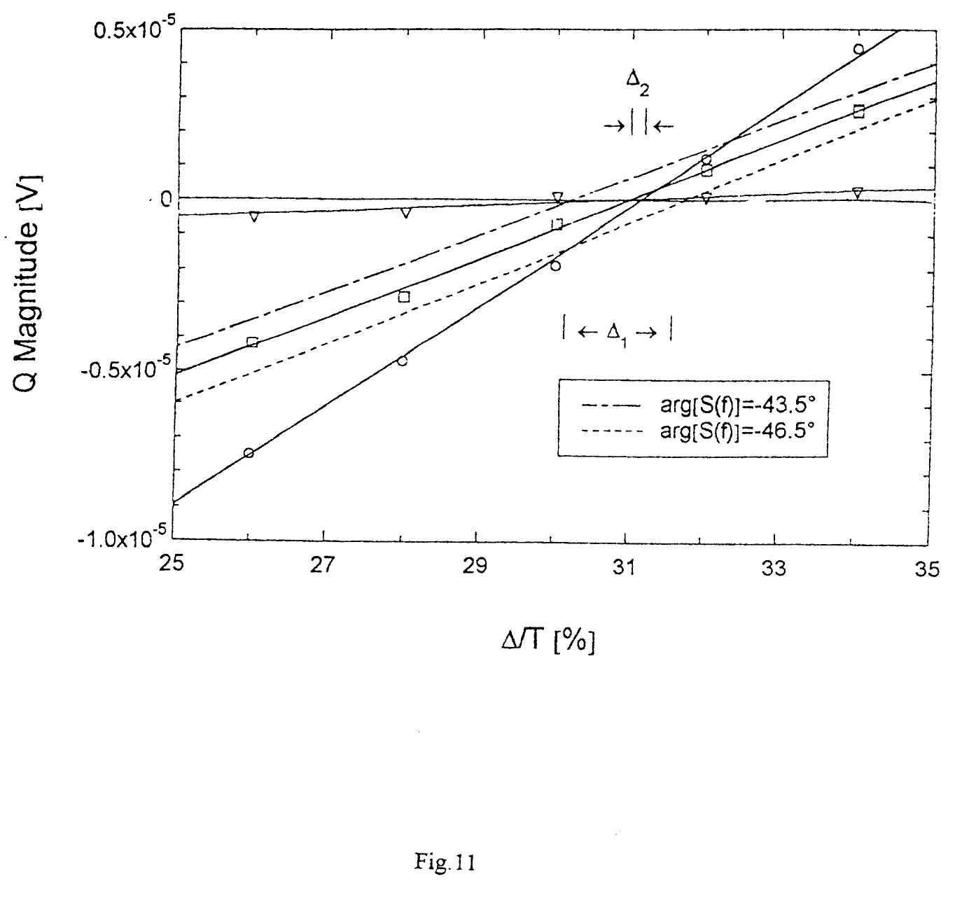

The corresponding signal phase data, obtained by temporally varying the pump intensity as a 50% duty-cycle square wave, are reported in FIG. 10. The data corresponding to the two highest power values are in agreement, but those obtained at the lowest power are increasingly shifted with increasing modulation frequency. In the frequency range utilized in the pulse-scan measurements (f=500 Hz), the phase shift is approx. −1.5°. In order to give a comparison between the two methodologies, FIG. 11 shows a zoom in the vicinity of the zero crossing region of the curves reported in FIG. 9. Here two additional curves are included, showing the theoretical interpolation of the data obtained for P=150 mW, arbitrarily shifted by ±1.5° with respect to arg[(S(f)]=−45° (the semi-infinite photothermal case). It is evident that the spread Δ₂ among the crossing points at all laser powers is much less than the phase-error equivalent spread Δ₁ (1.5° exhibited by the frequency scan). Once again, this confirms the superior noise suppression resulting from the lock-in differential action.

After the preliminary tests with the Zr alloy reference and the ensuing calibration procedure, experiments were performed with two Zr-2.5Nb shot-peened samples in order to test the sensitivity of the new instrumental methodology to minute thermomechanical inhomogeneities and to compare the results with those obtained by means of the conventional 50% duty-cycle frequency-scan PTR method. Shot peening [S. A. Meguid, ed., Surface Engineering, (Elsevier Applied Science, New York, 1990)] is employed as an effective mechanical surface improvement method in metallic materials. This method basically consists of bombarding the metal surface with a large number of small spheres of steel, glass or ceramic, totally covering the surface with indentations. As a result, a thin surface layer (on the order of 100 μm) is plastically deformed. Plastic deformation causes strain hardening, which improves the fatigue life and corrosion resistance of the treated metal surface. In selecting and controlling shot peening parameters to optimize surface improvement, it is very important to monitor the effects caused by the shot peening process. These effects to-date are usually evaluated by destructive methods, such as Transmission Electron Microscopy (TEM).

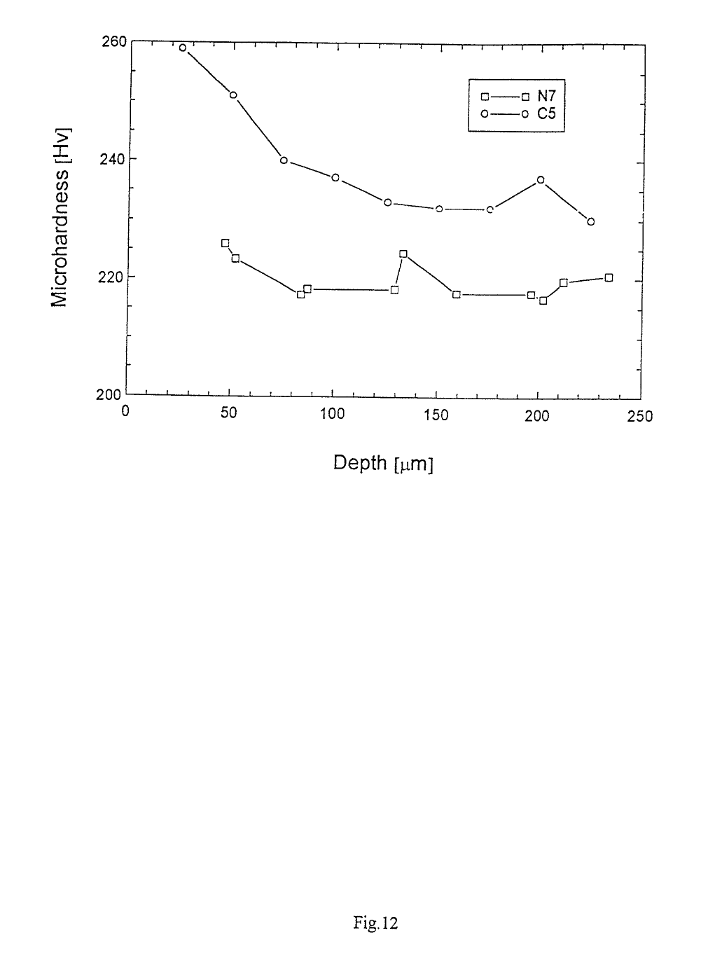

The two examined samples were shot peened at Almen intensities C5 and N7, respectively. The microhardness profiles obtained by Vickers indentation tests are shown in FIG. 12. The sample C5 reveals quite a small variation (≈10%) in the hardness value over a depth distance on the order of 100 μm, while the sample N7 exhibits an essentially flat hardness profile. Nevertheless, TEM examinations performed on this same sample have indicated that shot peening at N7 Almen intensity does affect the grain structure over a depth lower than 60 μm [K. F. Amouzouvi, L. J. Clegg, R. C. Styles and J. E. Winegar, private communication]. The foregoing shot peening process was chosen to test the new technique because its effects on the thermophysical properties of metals are minuscule. For comparison, photothermal depth profilometry of hardened steels by heat treatment, generates a phase contrast less than 5° even for hardness variations of one order of magnitude [T. T. N. Lan and H. G. Walther, J. Appl. Phys. 80, 5289 (1996)]. This suggests than a very small contrast signal should be expected from shot peened samples.

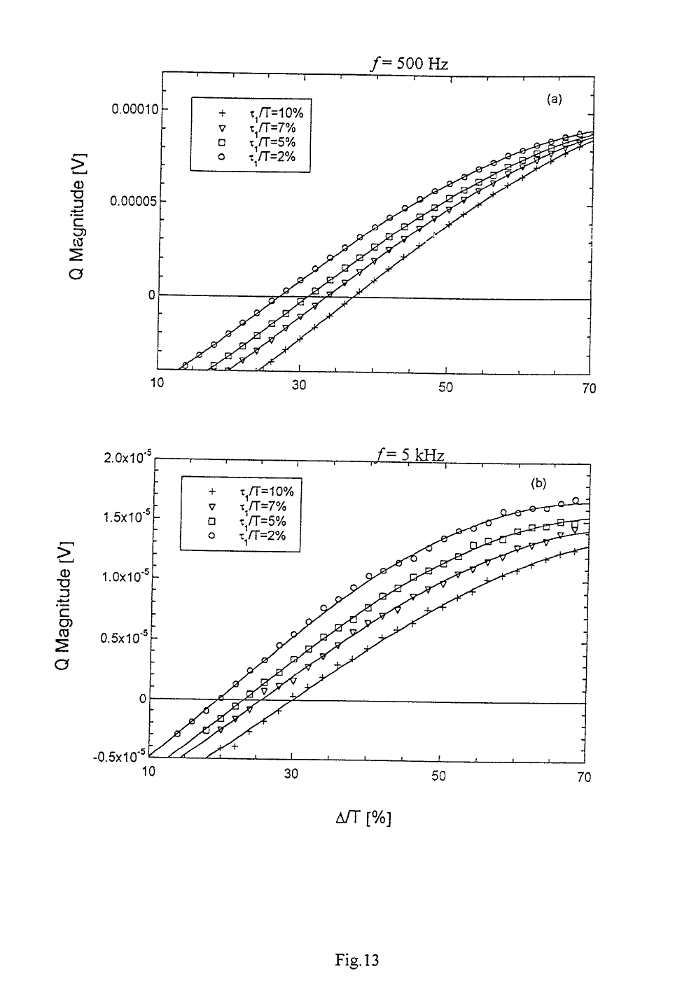

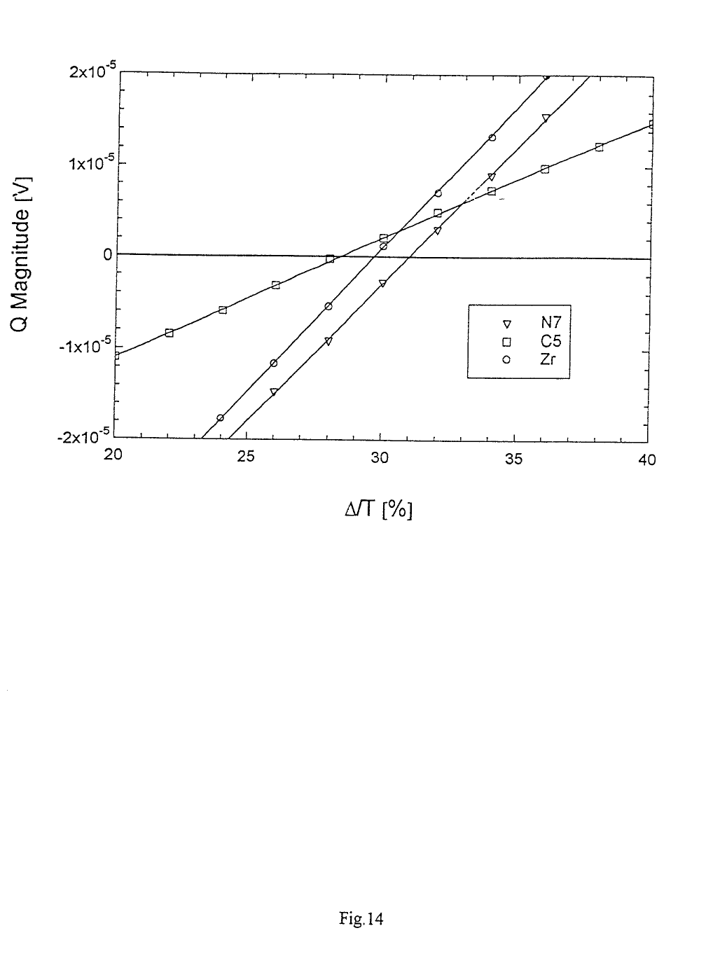

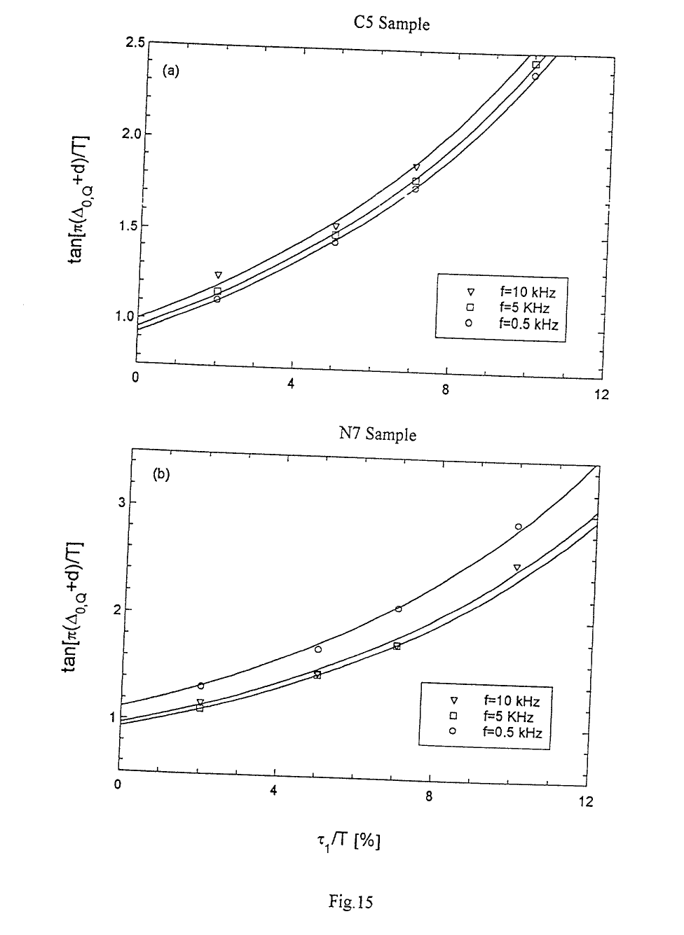

In FIG. 13 the Q signals corresponding to various τ₁ pulsewidths and fixed τ₂ are reported as functions of the normalized pulse separation for the N7 sample and for two different modulation frequencies (500 Hz and 10 kHz). FIG. 14 shows the shift of the zero position due to thermal response changes for both samples C5 and N7 at 500 Hz. The results are compared to that from the reference Zr sample. The excellent agreement between theory and experimental results is confirmed: By fitting the data to Eq. (16), with the d value determined for the Zr sample obtained from the last row of Table I, we were able to precisely determine the Q component zero-crossing positions Δ_{0,Q}. The tan [([(Δ_{0,Q}+d)π/T] values shown in FIG. 15, were compared to the theoretical interpolations given by Eq. (18), in order to calculate the Im[S(f)]/Re[S(f)] values which are reported in Table II. The Im[S(f)]/Re[S(f)] values obtained for the C5 sample reveal a trend as a function of the modulation frequency, which is quite consistent with the hardness profile. A shift from the homogenous sample response is expected when the thermal-wave diffusion length is on the order of the depth where the hardness profile shows significant variations. Considering that the nominal thermal diffusivity value of the Zr-2.5Nb alloy is 0.093 cm²/sec [ASM Handbook, 10^{TH} Edition, (Joseph E. Davis et al., Ed., ASM International, Materials Park, Ohio, 1992) Vol. II, p. 666.], at 0.5 kHz the thermal diffusion length is on the order of 75 μm, i.e. commensurate with the hardness depth. Therefore, the Im[S(f)]/Re[S(f)] value at f=0.5 kHz is higher than −1 expected from a semi-infinite homogeneous solid, or, equivalently, the phase lag is less than −45° (−42.8°). This is consistent with the fact that the hardened layer has an effective thermal diffusivity lower than that of the bulk [See, for example, G. Busse and H. G. Walther in Progress in Photothermal and Photoacoustic Science and Technology Vol. I: Principles and Perspectives of Photothermal and Photoacoustic Phenomena, (A. Mandelis, Ed., Elsevier, New York, 1992), Chap. 5, pp. 207-298]. At higher modulation frequencies, 5 kHz and 10 kHz, the thermal diffusion length becomes ˜20 μm. The corresponding hardness profile does not show large variations over this distance. This means that the sample can be assumed homogeneous over this depth and, accordingly, the Im[S(f)])]/Re[S(f)] ratio assumes values roughly corresponding to −45°. On the contrary, the Im[S(f)]/Re[S(f)] data obtained for the N7 sample do not reveal any measurable trend with modulation frequency, reflecting the corresponding flat hardness profile behavior.

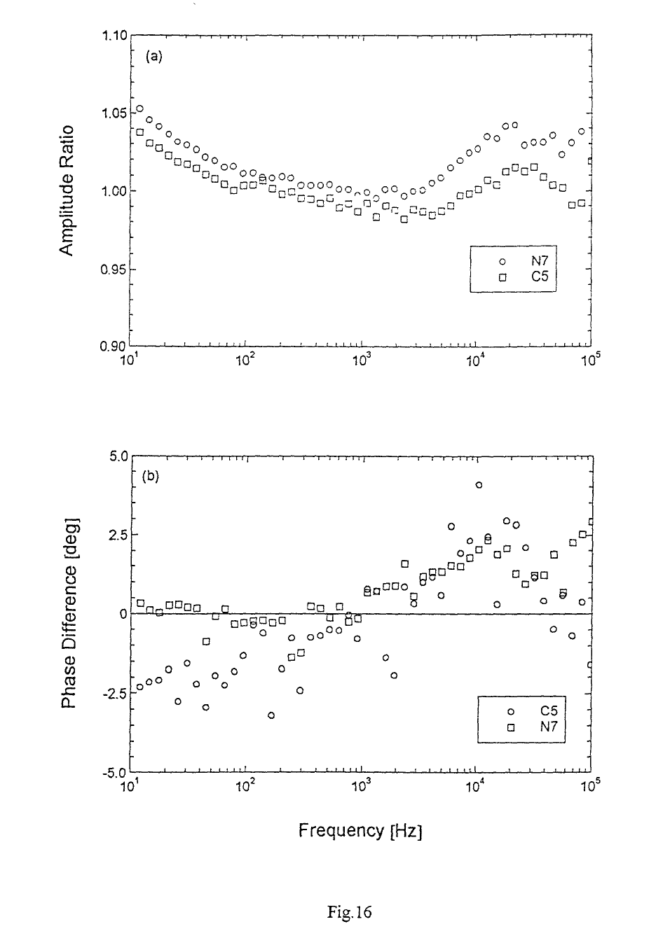

For the purposes of this application of the present invention, conventional PTR frequency scans were further performed for comparison by using the same setup and the same 250-mW optical power for all the measurements. The only change was in the excitation-laser-beam modulation waveform, a 50% duty-cycle square wave. The experimental data, normalized by the data obtained from the Zr reference, are reported in FIG. 16. The systematic high-frequency-amplitude differences of the two curves in FIG. 16(a) are not meaningful, as extensive satellite PTR experiments with these and different Almen-intensity shot peened Zr-2.5Nb samples have shown that there exists no consistent trend of the signal with degree of hardening. Furthermore, unlike the Im[S(f)])]/Re[S(f)] ratios of Table II, the presence of a hardness depth profile in the C5 sample, FIG. 12, cannot be measured from the similar amplitude trends of both samples throughout the entire frequency range in FIG. 15(a). The N7>C5 amplitude ratio in FIG. 16(a) is, however, consistent with the lower slope of the C5 curve in FIG. 14, which indicates a lower-amplitude thermal-wave signal at 500 Hz for the C5 shot peened Zr-2.5Nb alloy. The phase channel, FIG. 16(b), also clearly shows insensitivity to the differences in hardness between the two shot-peened samples. Doubtless, any such differences are masked by the large data scatter in this figure.

In conclusion, the PTR experimental calibration of the novel common-mode-rejection demodulation technique was shown to be a very promising high-detectivity measurement method for low-dynamic-range and poor-SNR signals, such as those obtained with thermal-wave diagnostics. Results with two shot-peened Zr-2.5Nb samples have shown that this technique is sensitive enough to resolve minute differences in thermophysical properties resulting from mechanical structure changes of these materials after shot peening and to monitor hardness depth profiles by means of the value of the Im[S(f)])]/Re[S(f)] ratio at several frequencies. Conventional single-ended frequency-scanned PTR detection proved unable to resolve these differences.

ii) Frequency-Swept (“Chirp”)/PTR Combination Method

A combination of chopped illumination and frequency swept (“chirped”) detection has been used for a quantitative kinetic PTR study based on the real-time monitoring of the temporal evolution of the low-injection minority-carrier transport properties of two silicon wafers which exhibited PTR transients. Depending on crystal growth and wafer manufacturing conditions, some lower quality Si wafers exhibit mild or strong temporal transients under the PTR probe. PTR frequency scans were performed in the steady state following the complete saturation of the PTR transient. The two 6″ Si wafers used in this study were provided by Mitel SCC (Bromont, Quebec, Canada). One wafer was unprocessed 10-15 Ω-cm n-type (100) wafer with oxygen content between 30-to-38 ppma. The wafers were polished using a colloidal suspension of SiO₂ as the polishing slurry. After polishing the wafers were cleaned, first in a wet bench and then in a scrubber. In the wet bench the wafers go through three solutions with water rinses in between. The first one removes particles and organics and leaves a thin oxide layer. The second solution is used to etch this oxide and dissolve metals like Cu that tend to diffuse into the oxide. The third solution removes metals and leaves the wafers hydrophobic. The other wafer was 24-40 Ω-cm p-type silicon, with a thermally grown oxide. This wafer was ramped from 800 to 1175° C. under low concentration O₂ and N₂ for 40 min. This was followed by oxidation at 1175° C. in O₂ for 6 hours and 50 minutes and a ramp-down from 1175 to 800° C. in N₂ for 1 hour and 20 minutes.

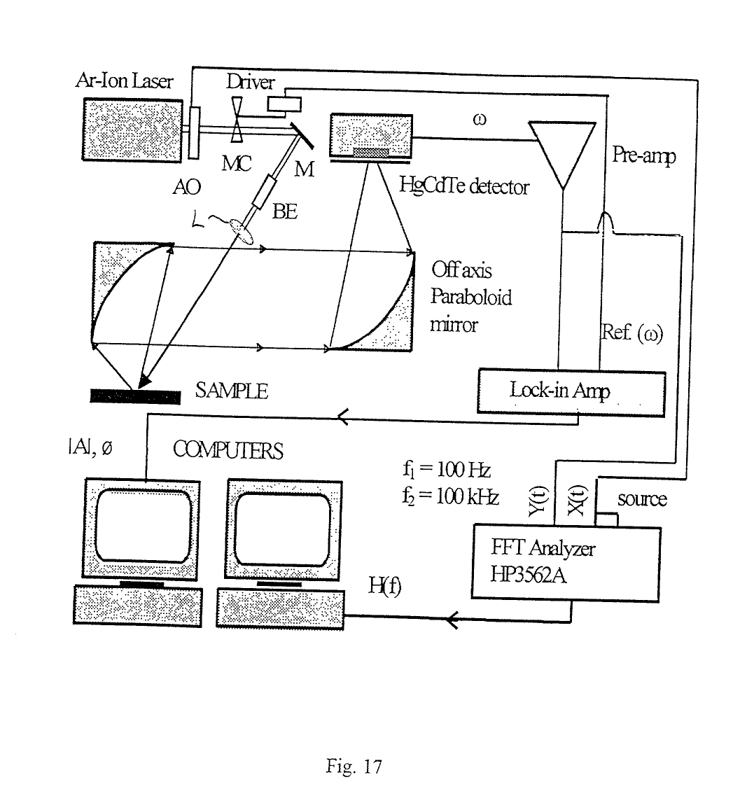

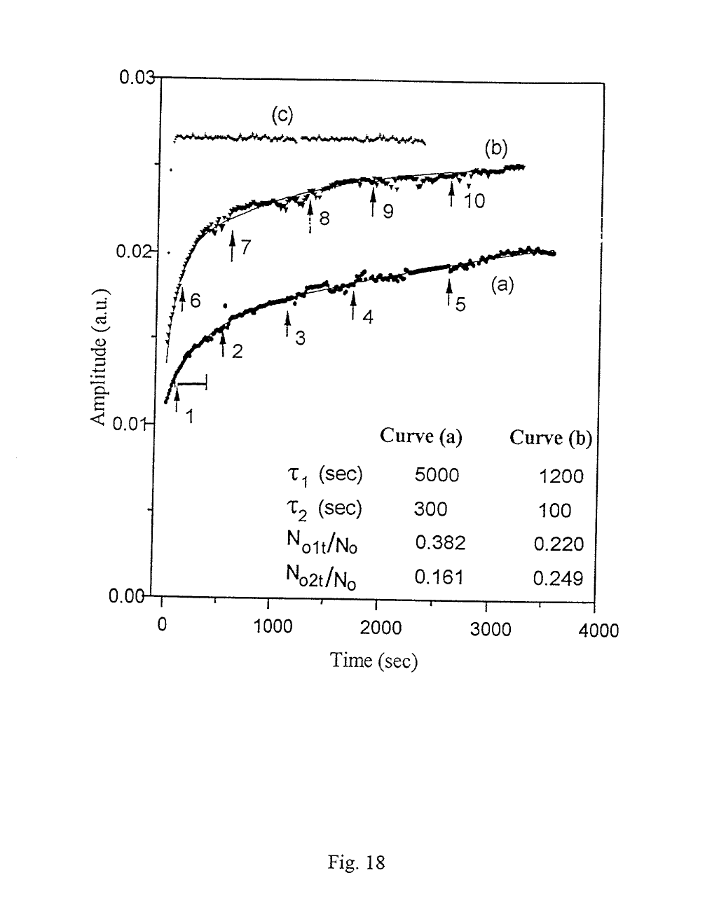

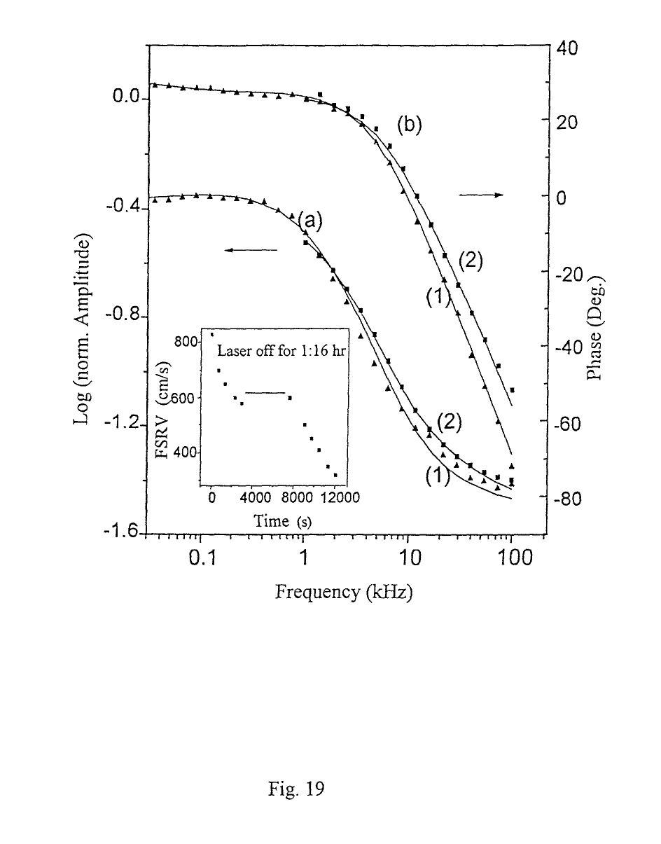

The experimental setup for the PTR method used to obtain conventional frequency scans has been described previously [S. J. Sheard and M. G. Somekh, Infrared Phys. 28, 287 (1988)]. The instrumental technique of photothermal chirped frequency sweep has also been described in detail by A. Mandelis, IEEE Trans. Ultrasonics, Ferroelectrics, Freq. Control, UFFC-33, 590 (1986)]. The new combined apparatus for the simultaneous monitoring of transient evolution and chirped-PTR correlation and spectral analysis is shown in FIG. 17. An Ar⁺-ion laser emitting at 514 nm was used as the excitation source. The beam was chopped at f₀=83 Hz with a mechanical chopper (MC). Then it was expanded, collimated and focused by a lens (L) on the sample surface. The incident power was 40 mW. A square-waveform chirp from a dual-channel FFT analyzer was used to drive the acousto-optic modulator (AO), which produced periodic frequency sweeps of the probe beam in the range 100 Hz to 100 kHz. The low-power laser beam was used to induce temporal effects on the sample. The amplitude, A(f₀,t), and phase, φ(f₀,t), of the PTR signal in the lock-in amplifier were recorded as functions of time. For each intermittent (quasi-steady) measurement 1000 frequency chirps were co-added and averaged, and the spectral transfer function, H(f), was generated and stored in the FFT analyzer. Quasi-steady chirps were obtained intermittently at various time-windows during the transient from the unoxidized n-type wafer as illustrated in FIG. 18. For the n-Si wafer, five consecutive chirps during a single continuous transient from start to saturation were obtained on a previously unirradiated spot. Each chirp measurement lasted 5 minutes. After the 5^{th} chirp, the optical source was blocked for 1 hour. Then the transient and five more chirps (not shown in FIG. 18) were measured again on the same spot of the wafer. When steady state was reached (>4000 s) a lock-in frequency scan was obtained as shown in FIG. 19. For the p-Si wafer only the lock-in temporal behavior of a previously unirradiated spot was monitored. No chirps were introduced because the response was flat, FIG. 18.

The amplitude and the phase of the PTR frequency response of the unprocessed n-Si at steady-state, FIG. 19, were fitted simultaneously, by using the computational multi-parameter fitting procedure (described in the next section below) to a three-dimensional theoretical model, taking into account the laser beam spotsize, the thickness of the wafer, the photoexcited minority-carrier plasma-wave generation, and the optical-to-thermal energy conversion following lattice absorption. The following values were used to obtain the best fit for both signal channels: lifetime τ=110 μs; photoexcited minority carrier diffusion coefficient Dₚ=10 cm²/s; front-surface recombination velocity S₁=320 cm/s; and sample thickness L=570 μm. FIG. 18 shows that the transient behavior of the n-Si sample is semi-reversible following the cut-off of the radiation and the one-hour recovery time. Spots with fully reversible transient behaviour have also been observed in the same wafer.

The phase and amplitude of the spectral transfer function H(f) of the PTR signal from the frequency-sweep measurements at the onset of the laser (curve 2) and at steady state (curve 1) are shown in FIG. 19. A point-by-point lock-in frequency scan was also performed in the steady state and at the same spot on the n-Si wafer. The steady chirped amplitude and phase were normalized to those of the higher-quality lock-in signal to eliminate the instrumental transfer-function effects of the dual-gate FFT analyzer. The steady state chirp measurements were smoothed with double adjacent 5-points filter and then fitted with a 5th order polynomial function. This polynomial function was the one used for the normalization procedure. These corrections were subsequently applied to all other quasi-steady PTR chirps. The 3-D PTR model was used for theoretical best fits to the data to obtain the quasi-steady and steady-state carrier transport parameters. Dramatic quantitative changes in the front-surface recombination velocity were found. On the contrary, the minority carrier lifetime (τ) and the and diffusion coefficient (Dₚ) did not exhibit any measurable change. The temporal evolution of the front-surface recombination velocity for the n-Si sample is shown in the inset of FIG. 19. When the laser beam is turned on, the surface recombination velocity, S, starts decreasing steeply from 830 cm/s, until it reaches the saturation value (steady state) at 320 cm/s, a sign of electronic-quality improvement of the laser irradiated wafer surface.

In conclusion, we have presented an example of the Si-wafer diagnostic use of frequency-swept PTR in the form of combined frequency-swept and single-frequency-modulated technique suitable for the simultaneous kinetic measurement of surface-state annealing temporal evolution and minority-carrier transport properties at several time windows along the transient generated by low-power-laser-irradiation on n- and p-type silicon wafers subjected to optical annealing. A quantitative dependence of the front-surface recombination velocity decrease on the total annealing time in laser-irradiated unoxidized n-Si was extracted. The use of frequency-swept PTR to obtain fast frequency scans, time-averaged on the order of one minute, at pre-determined sites on a Si wafer and extract the local electronic and thermal transport properties is a straightforward extension of this example.

iii) Multi-Parameter Computational Method for Thermo-Electronic Parameters Determination of Semicondutor Wafers

a) Description of the Method.

In order to obtain a particular set of parameters from PTR measurements of a Si wafer, a multi-parameter fitting procedure based on the simulation trends was developed. The total blackbody (Plank) radiation emitted from a silicon sample illuminated with a modulated laser beam arises from two sources: emission of IR radiation from the photo-excited carrier plasma-wave (injected excess carrier density) and from direct lattice photon absorption and optical-to-thermal (nonradiative) power conversion leading to temperature rise (a thermal wave) [S. J. Sheard, M. G. Somekh, and T. Hiller, Mat. Sci. and Eng, B 5, 101; (1990) A. Mandelis, Solid State Electron. 42, 1 (1998); M. Hiller, M. G. Somekh, S. J. Sheard, and D. R. Newcombe, Mat. Sci. and Eng. B 5, 107 (1990)] Sheard and co-workers observed experimentally that under infrared photothermal radiometric (PTR) detection, carrier emission dominates and the thermal-wave contribution can be neglected for some Si samples. This observation was addressed theoretically recently [see, A. Salnick, A. Mandelis, H. Ruda, and C. Jean, J. Appl. Phys. 82, 1853 (1997); A. Salnick, A. Mandelis, and C. Jean, Appl. Phys. Lett. 69, 17 (1996)]. These authors generated a composite plasma- and thermal-wave PTR model of semiconductors and showed that the plasma-wave signal component can dominate in high-quality materials virtually at all modulation frequencies. However, in this model the radial spatial variation of laser-generated excess carriers and of the temperature rise was not considered [T. Ikari, A. Salnik, and A. Mandelis, J. Appl. Phys. 85, 7392 (1999)] have presented a general theoretical model for the laser-induced PTR signal from a semiconductor wafer of finite thickness using a three-dimensional geometry. In this model, carrier diffusion and recombination, as well as heat conduction, along the radial and axial directions in the sample were taken into account using cylindrical coordinates. A pair of conventional coupled plasma- and heat diffusion-wave equations were written and solved in Hankel space. In this theoretical framework, the plasma and thermal components can be written as follows:

$${S}_{PTR} ( ω ) = \frac{{C}_{1}}{A} {\int }_{0}^{∞} F ( λ , ω ) {J}_{1} ( λ a ) ⅆ λ + \frac{{C}_{2}}{A} {\int }_{0}^{∞} T ( λ , ω ) {J}_{1} ( λ a ) ⅆ λ \qquad ( 24 )$$

In Eq. (24), A is the effective detector area: A=πa², where a is the detector radius; J₁(x) is the Bessel function of the first kind and order one; and F(λ, ω) and T(λ, ω) are the radial Hankel transforms of corresponding frequency-dependent solutions to the plasma-wave and thermal-wave boundary-value problems under optical excitation by a Gaussian laser beam. These functions have been reported previously [A. Salnick, A. Mandelis, and C. Jean, Appl. Phys. Lett. 69, 17 (1996); T. Ikari, A. Salnick, and A. Mandelis, J. Appl. Phys. 85, 7392 (1999)]. They contain the thermal and electronic transport parameters of the electronic solid: recombination lifetime (τ), carrier diffusion coefficient (Dₙ,), front surface recombination velocity (S₁), back surface recombination velocity (S₂) and thermal diffusivity (α). In practice, for accurate measurements, both thermal-wave and plasma-wave contributions must be considered in the interpretation of PTR data (amplitude and phase) from semiconductor samples, such as Si wafers. The electronic quality of industrial semiconductor wafers varies widely and they frequently exhibit strong thermal behavior, especially at low modulation frequencies. Semiconductor PTR is an excellent candidate technique for non-destructive multi-parameter measurements in electronic materials because it can offer measurements of several important properties, which are crucial for device fabrication control. The major problem, facing the implementation of the three-dimensional model by Ikari et. al for use with experimental radiometric data, is the reliability of the measured values of any and all of the foregoing electronic transport parameters, in view of the intrinsic non-uniqueness of the theoretical fit (maximum of five unknown material parameters plus the constants C₁ and C₂ in Eq. (24)) to only two data channels (amplitude and phase) available to the experimenter.

The present invention presents a computational methodology developed to address precisely the uniqueness problem of the PTR signal interpretation. The effects of the various transport parameters on the shape of the frequency response curves (amplitude and phase) are studied theoretically. Then a robust computational best-fit algorithm is described, based on the specifics of signal sensitivity dependence on a given transport parameter across particular regions of the modulation frequency spectrum. As a result, the conditions for unique fits and reliable parameter measurements are deduced and examples of such measurements are given.

Theoretical Simulations. A pair of conventional coupled plasma and heat diffusion equations based on Eq. (24) can be written and solved in Hankel space. The three dimensional PTR signal is finally obtained by taking a weighted superposition of the plasma and thermal contributions [A. Mandelis, Solid State Electron. 42, 1 (1998)]

S_{PTR}(ω)=CₚS_{Plasma}(ω)+CₜS_{Thermal}(ω) (25)

where parameters Cₚ and Cₜ represent the weight of each component (plasma and thermal) contributing to the PTR signal and S_{PTR} represents a vector in the sense of a function with complex argument. In Eq. (25), the plasma-wave component (Sₚₗₐₛₘₐ) is obtained from the Hankel transform N (z,λ;ω) of the 3-dimensional N(\vec{r},ω) by integrating over the thickness of the wafer, which takes into account deep-lying Plank radiation emission from photogenerated and diffused carriers, according to Kirchhoff's law of Detailed Balance. The result for the plasma contribution in the Hankel space is

$$\begin{matrix}F ( λ , ω ) = {\int }_{0}^{L} N ( z , λ ; ω ) ⅆ z \\ = \frac{{ⅇ}^{\frac{- {λ}^{2} {d}^{2}}{8}} ( 1 - {ⅇ}^{- {b}_{n} L} )}{h v π ( {D}_{n} {b}_{n} + {S}_{1} ) {b}_{n}} ( \frac{{A}_{2} + {ⅇ}^{- {b}_{n} L}}{{A}_{2 } - {A}_{1} {ⅇ}^{- 2 {b}_{n} L}} ) .\end{matrix} \qquad ( 26 )$$

the parameters in equation (26) are defined as follows.

$${A}_{1} = \frac{{D}_{n} {b}_{n} - {S}_{1}}{{D}_{n} {b}_{n} + {S}_{1}} \\ {A}_{2} = \frac{{D}_{n} {b}_{n} + {S}_{2}}{{D}_{n} {b}_{n} - {S}_{2}} \qquad ( 27 )$$

where σₙ²=(1+iωτₙ)/Dₙτₙ, Dₙ is the minority electron carrier diffusivity, τₙ is the carrier lifetime, S₁ and S₂ are the front and back surface recombination velocities. The thermal component is calculated in the same manner:

$$T ( λ , ω ) = {B}_{1} ( \frac{1 - {ⅇ}^{- {b}_{i} l}}{{b}_{t}} ) + {B}_{2} ( \frac{{ⅇ}^{{b}_{i} L} - 1}{{b}_{t}} ) + {B}_{3} ( \frac{1 - {ⅇ}^{{b}_{n} L}}{{b}_{n}} ) + {B}_{4} ( \frac{1 - {ⅇ}^{- {b}_{n} L}}{{b}_{n}} ) {ⅇ}^{- {b}_{n} L} \qquad ( 28 )$$

The parameters in the above equation are defined as follows.

$${B}_{1} = \frac{{h}_{1} - {h}_{2} {ⅇ}^{- {b}_{i} L}}{1 - {ⅇ}^{- 2 {b}_{i} L}} \\ {B}_{2} = ( \frac{{h}_{1} {ⅇ}^{- {b}_{i} L} - {h}_{2}}{1 - {ⅇ}^{- 2 {b}_{i} L}} ) {ⅇ}^{- {b}_{i} L} \\ {B}_{3} = \frac{{E}_{g} {ⅇ}^{- {λ}^{2} {d}^{2} / 8}}{π h υ k {τ}_{n} ( {b}_{n}^{2} - {b}_{t}^{2} ) ( {D}_{n} {b}_{n} - {S}_{1} )} ( \frac{{A}_{2}}{{A}_{2} - {A}_{1} {ⅇ}^{- 2 {b}_{n} L}} ) \\ {B}_{4} = \frac{{B}_{3}}{{A}_{3}} \\ {h}_{1} = \frac{- {S}_{1} {τ}_{n}}{{b}_{t}} ( {b}_{n}^{2} - {b}_{t}^{2} ) ( {B}_{3} + {B}_{4} {ⅇ}^{- 2 {b}_{n} L} ) - \frac{{b}_{n}}{{b}_{t}} ( {B}_{3} - {B}_{4} {ⅇ}^{- 2 {b}_{n} L} ) \\ {h}_{2} = \frac{1}{{b}_{t}} [ {S}_{2} {τ}_{n} ( {b}_{n}^{2} - {b}_{t}^{2} ) ( {B}_{3} + {B}_{4} ) - {b}_{n} ( {B}_{3} - {B}_{4} ) ] {ⅇ}^{- {b}_{n} L} \qquad ( 29 )$$

bₜ²=λ²+σₜ²;

This 3-D PTR model takes into account the finite size of the exciting laser beam, the effective detector size, and the sample thickness [T. Ikari, A. Salnik, and A. Mandelis, J. Appl. Phys. (1999)]. The parameters involved in a typical multi-parameter fitting procedure are: recombination lifetime (τ), ambipolar carrier diffusion coefficient in n- or p-type material (D_{n,p}), front surface recombination velocity (S₁), thermal (Cₜ) and plasma (Cₚ) contribution coefficient, back surface recombination velocity (S₂) and thermal diffusivity (α).

b) Application of the Multi-Parameter Best-Fit PTR Metrology to Uniquely Determine Thermo-Electronic Parameters of High and Low Resistivity Silicon Wafers

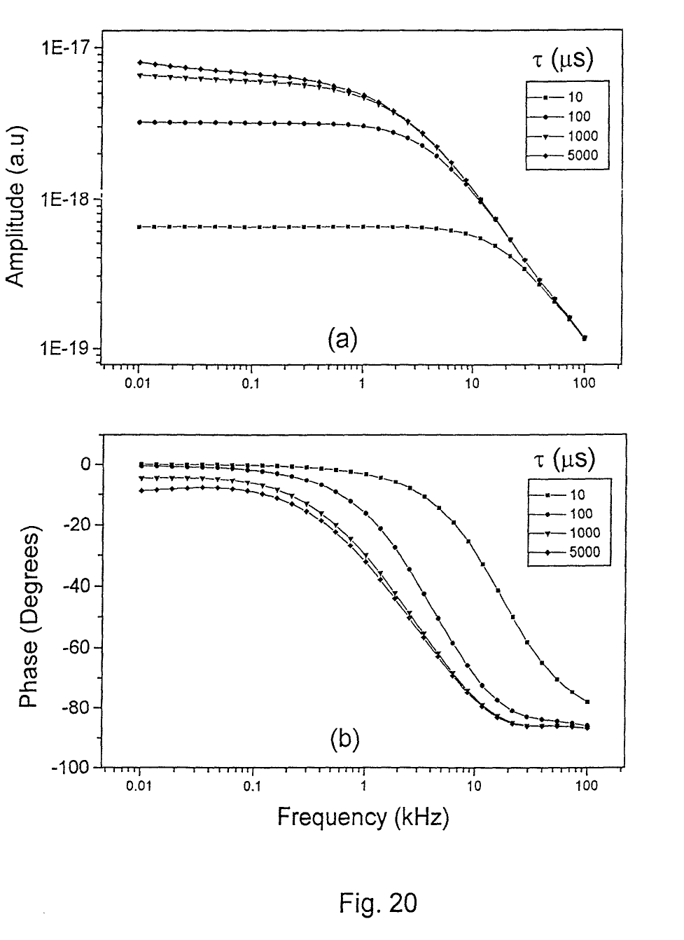

By way of example for the purposes of the present invention, the theoretical, experimental and computational PTR methodology of the present invention is applied to two samples, a high resistivity (25-44 ohm-cm) and a low resistivity (14-24 ohm-cm) wafer. Both wafers were thermally annealed and had a polished front surface and a rough (matte) back surface. These wafers contained centerpoint oxygen concentration between 24 to 32 ppma and carbon concentration of 0.5×10¹⁷ atoms/cm³. Thermal dry isochronal annealing was carried out using a horizontal furnace BDF-200 (see FIG. 20). The gas inlet was located at the back of the furnace (“source”) and the gas exit was located at the opposite end of the furnace (“door”). Inside the tube there was a negative static pressure of 0.3 psi to evacuate the gas. The system was, nevertheless, considered to be under STP conditions, without vacuum. The polished side of the wafers was facing the door. Thus, the gas was flowing toward the back of the wafers. Each tube could accommodate four quartz boats and each boat could hold 25 wafers. The spacing between two adjacent wafers was 3 mm. The tube was surrounded by heating elements, which provided uniform temperature across its length. All wafers were subjected to the following thermal cycle: they were first exposed to 800° C. for 10 minutes. After reaching thermal equilibrium, the wafer temperature was ramped-up from 800 to 1175° C. under low flows of O₂ and N₂ gases for 40 minutes, at a rate of 5° C./mim. The temperature was stabilized at 1175° C. and dry oxidation was induced in pure O₂ for 6 h:50 minutes. At the end of the oxidation process, the furnace temperature was ramped-down to 800° C. in pure N2 at a rate of 5° C./min. Both surfaces of the wafers used in this work were exposed to the same gas flow and temperature conditions, under the isochronal dry oxidation process. Therefore, they were expected to exhibit similar surface recombination velocities, even if the front surface had been polished chemically and mechanically. PTR diagnostics of both surfaces of the aforementioned wafers were performed and the results are discussed below.

The computational best-fit procedure includes the following steps: a) selection of initial values within the adequate range of the physical; b) variation of the thermal and plasma coefficients (Cₜ and Cₚ), until a good fit is obtained at the low-frequency range of both experimental phase and amplitude; c) variation of the recombination lifetime value, until the characteristic knee of the experimental curve is best-fitted and is consistent with the 2πf_{c}τ˜1 criterion. These procedures are then followed by re-adjusting the thermal and plasma coefficients to match phase and amplitude at the low frequency range; d) variation of Dₙ until the intermediate region of the phase and the amplitude signal converge to the experimental data. Then phase and amplitude are adjusted while Cₜ and Cₚ are also varied, as required; e) variation of S₁, until the signal phase spread between two typical frequency range extremes (10 Hz-100 kHz) is matched to the experimental spread. Since the amplitude is also affected by this parameter, this procedure is followed by a re-adjustment of the amplitude at low frequencies by varying Cₜ and Cₚ, as required; f) variation of the back-surface recombination velocity, S₂, for fine-tuning at low frequencies, only when the data are sensitive to S₂. This is followed by a re-adjustment of both phase and amplitude at low frequencies by varying Cₜ and Cₚ, if necessary; and g) fine-tuning of the fit by repeating steps c-to-f.

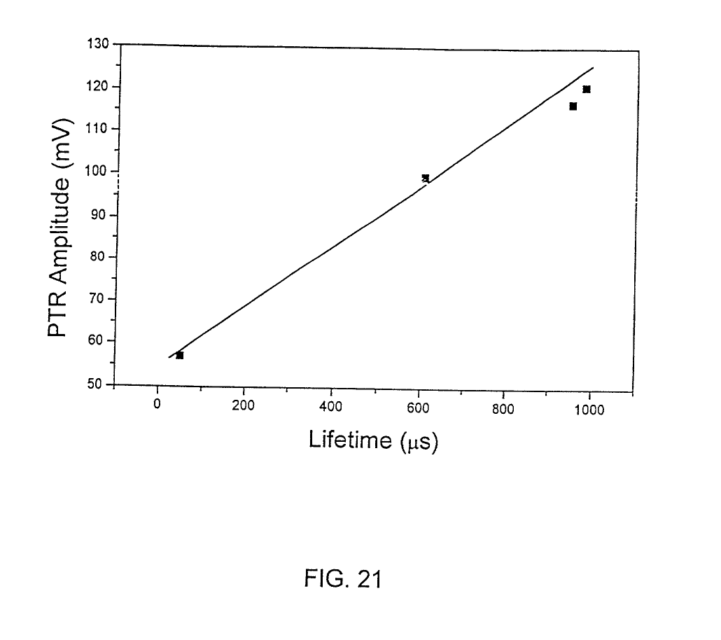

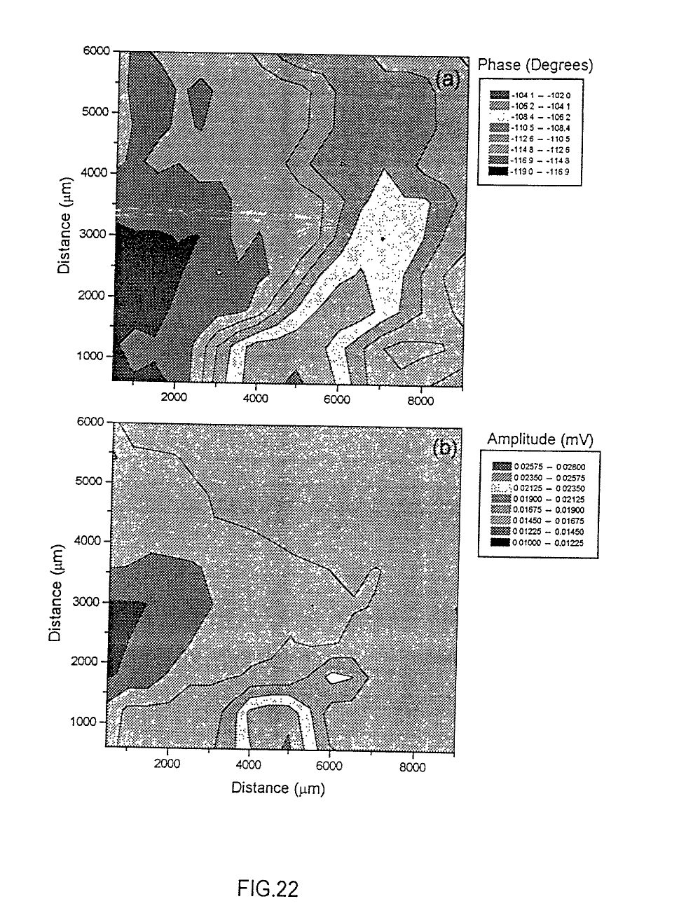

It is well-known that lifetime values vary across a silicon wafer [A. Salnick, A. Mandelis, F. Funak, and C. Jean, Appl. Phys. Lett. 71, 1531 (1997)]. This has also been observed during the development of the present PTR metrologic technology. However, this variation has a special significance in the case of PTR amplitude measurements. When multi-point measurements across the surface of a single sample are performed, an extra channel of information is available, that is the relative positions of the flat (low-frequency) region of the amplitude curves scale linearly with lifetime at a given point [A. Mandelis, Solid-State Electron. 42, 1 (1998)], see also FIG. 20 and FIG. 21. The relative values of the amplitude with respect to other locations further reinforce the consistency of the foregoing computational procedure by cross-correlation of the measured lifetimes. Based on FIG. 21, amplitude scans can immediately yield lifetime maps upon calibration, as in the case of FIG. 22.

For a reliable and unique multi-parameter fit it was found very helpful to establish realistic initial “seed” values for the various electronic parameters. The thermal diffusivity is a bulk property and simulations indicate that it has a weak influence in the PTR signal (both amplitude and phase). The values chosen for these simulations were 0.75 and 0.96 cm²/s for low and high resistivity wafers, respectively. These values are in close agreement with those reported in the literature [W. M. Bullis and H. R. Huff, J. Electrochem. Soc. 143, 1399 (1996); G. Zoth and W. Bergholz, J. Appl. Phys. 67, 6764(1990); E. Yablonovich, D. L. Allada, C. C. Chang, T. Gmitter, and T. B. Bright, Phys. Rev. Lett. 57, 249 (1986)]. The range of values reported in the literature for the front surface recombination velocity of n- and p-silicon is between 0.25 cm/s, for a very passivated surface, and 10⁷ cm/s for highly doped p-silicon. A low value of the front surface recombination velocity (i.e. 100 cm/s) for a p-silicon, which represents a moderately passivated surface, was chosen as our initial value. For the Si wafers of this study, the back surface was subjected to the same thermal process as the front surface. Therefore, the S₂ value of 100 cm/s, same as S₁, was chosen to initialize the fitting procedure. Initial relative values for Cₜ and Cₚ were 1 and 3×10⁻²⁰ a.u, respectively. The reported values for D_{n,p} are in the range between 8 cm²/s and 36.4 cm²/s. We chose 7.5 cm²/s (lower limit) as the initial value for our fitting procedure. Finally, to start the fitting procedure, values of 1500 μs and 100 μs were chosen for minority carrier lifetimes of high and low resistivity wafers, respectively. Once the initial values were chosen, the cyclic fitting procedure with the feedback described above was followed, steps a-to-f.

Results of the simulations using the aforementioned methodology has been reported in detail in. This procedure was performed manually in an electronic sheet program. However, an automated computer program for the sequential cyclic multi-parameter fitting procedure can be implemented. An embodiment of the computational algorithm is appended to this invention. It will be appreciated by those skilled in the art that numerous other configurations for this algorithm may be used. The above example is meant to be non limiting and illustrative only.

c) An Application of the Multi-Parameter Best-Fit PTR Metrology to Intact and Damaged Wafers.

Front- and back-surface PTR measurements and recombination lifetime scanning imaging. Frequency and imaging scans were performed at the center-point of a test wafer (high resistivity wafer), with the laser beam impinging successively on the front surface and on the corresponding spot of the back surface. The wafer used for these measurements and their preparation were described in the previous section (iv.b).

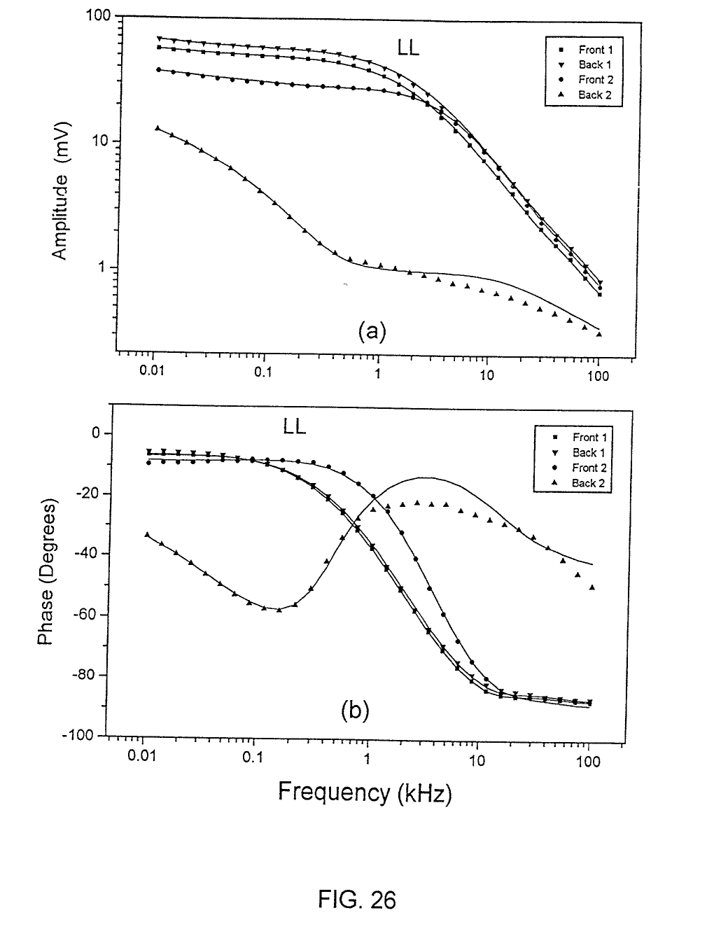

A small area on the back surface of the wafer was intentionally scratched very lightly and frequency scans were repeated. Silicon carbide paper with an average particle size of 22 μm was used to scratch the surface. The experimental PTR signal for this Si sample obtained from these frequency scans are shown in FIG. 26. The solid squares and inverted triangles represent frequency scans for both surfaces prior to damaging the back surface. The solid circle and upright triangles represent frequency scans for both surfaces after damaging the back surface. In the former case the experimental amplitude and phase curves are almost identical indicating similar electronic transport parameters in both directions. The solid lines represent the best fits to the experimental data following the aforementioned procedure. The measured values of the various parameters for the front and back surface before (front 1 and back 1), and after (front 2 and back 2), scratching the back surface are shown in Table III.

TABLE III
Thermal and electronic transport parameters for long
lifetime ρ-Si (high resistivity wafer), determined by 3-D
PTR model and the multi-parameter best fit; intact sample
(front 1, back 1); and scratched back surface (front 2, back 2).

| | Amplitude | α | τ | Dₙ | S₁ | S₂ | Cₚ | Cₜ |
|---|---|---|---|---|---|---|---|---|
| | (mV) | (cm²/s) | (μs) | (cm²/s) | (cm/s) | (cm/s) | (a.u) | (a.u) |
| Front 1 | 56.652 | 0.96 | 950 | 3.2 | 90 | — | 4.5 × 10⁻²⁰ | 3.1 |
| Back 1 | 66.505 | 0.96 | 950 | 3.2 | 110 | — | 4.5 × 10⁻²⁰ | 3.0 |
| Front 2 | 37.388 | 0.96 | 80 | 3.2 | 90 | — | 0.15 × 10⁻²⁰ | 2.0 |
| Back 2 | 12.776 | 0.12 | 12 | 3.2 | 3 × 10⁶ | — | 3.0 × 10⁻²³ | 1 × 10⁻⁴ |

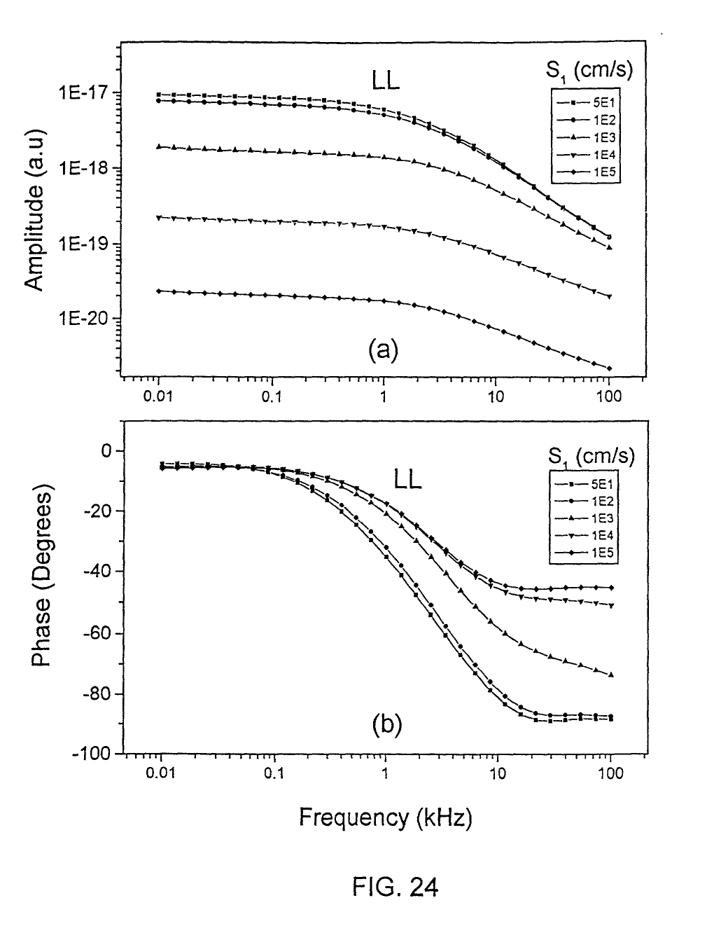

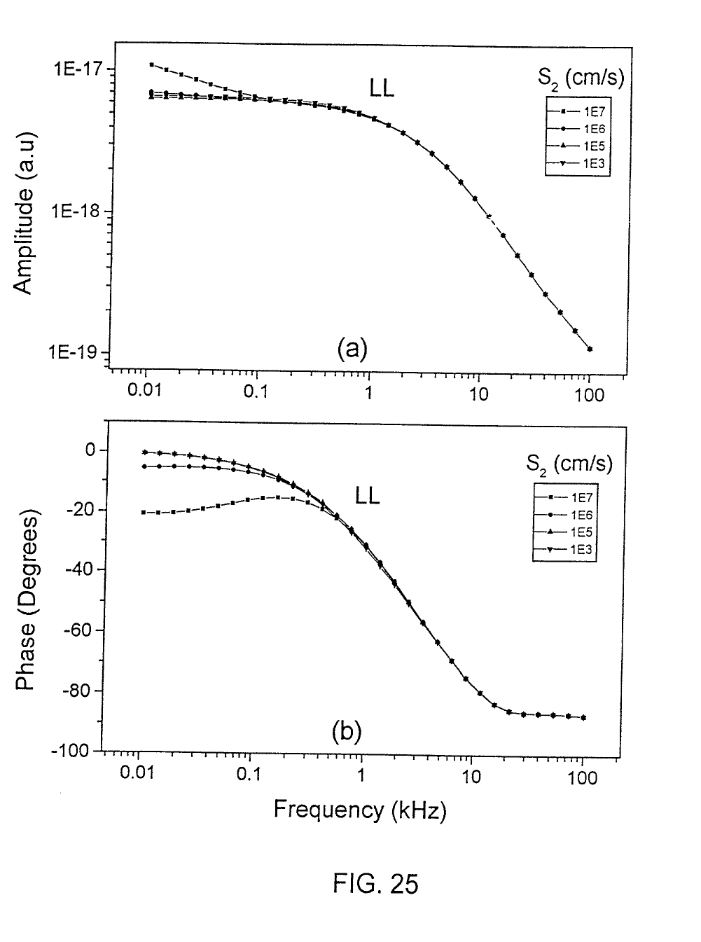

The fitting values obtained for S₂ (1000 cm/s) were in the non-sensitive region according to simulations of the theory (see FIG. 25). Therefore no conclusion regarding this parameter could be made. The electronic parameters obtained for the front and back surface (before scratching) were similar except that S₁ was slightly higher. These results indicate that the dry oxidation process (described at the onset of section iii.b) did, indeed, have the same effect on both surfaces. The solid circles and solid upright triangles represent the frequency scans after the damage on the back surface. The PTR amplitude, in the high frequency range, of the front-surface signal (front 2) in the case with the damaged region is similar to that obtained from the case with the intact-wafer-surface (front 1). However, there are significant changes regarding the PTR signal obtained from the back surface (back 1) and the damaged region case (back 2). In Table III, the value of τ for the scratched back surface represents an average recombination lifetime and could not be measured with accuracy. The low value found for α is related to the state of the surface, and represents the effective thermal diffusivity of the rough surface and the layer immediately below. This result shows that the PTR method is very sensitive to near-surface thermophysical properties. The value found for S₁ (back 2) is as expected for damaged surfaces; it is also in agreement with the theoretical predictions for bare surfaces (FIG. 24, and Table III). After the mechanical damage on the back surface of the wafer, the recombination lifetime decreased dramatically. A scanned image of the amplitude and phase over the defect region is shown in FIG. 22. This figure shows the sensitivity of the phase and amplitude to the extended defect area. The linearity of the PTR amplitude on the minority carrier lifetime is shown in FIG. 21.

These results suggest that the carrier recombination lifetime is not only affected by the bulk lifetime, but also by the recombination on the front surface of the sample exposed to the laser beam. This result is consistent with the very shallow optical absorption depth, β⁻¹=10⁻⁴ cm at 514 nm. Under front-surface detection, the very-near-surface photo-injected carrier lifetime may be affected by the electronic state of the surface itself. The effective lifetime, τ_{eff}, is known to be given by [H. Daio, A. Buckowski, and Shimura, J. Electrochem. Soc.,141, 1590 (1994)].

$$\frac{1}{{τ}_{eff}} = \frac{1}{{τ}_{b}} + \frac{1}{{τ}_{s}} \qquad [ 30 ]$$

where τ_{b} is the bulk lifetime, and τₛ represents the surface lifetime. It is possible that the PTR-measured lifetime under 514-nm laser irradiation is more closely related to τₛ, rather than to τ_{b}. Measurements at longer wavelengths and greater optical absorption depths are likely to be more representative of bulk lifetime, as shown in our earlier work [A. Mandelis, R. Bleiss, and F. Shimura, J. Appl. Phys. 74, 3431 (1991)]. Such measurements are part of the spirit of the present invention and are not meant to be excluded from the applications discussed in this section.

In conclusion, according to the results from the high resistivity sample presented here, FIG. 26 and Table III, the state of the back surface plays an important role in determining the thickness-averaged PTR carrier-recombination lifetime. Also the ability of the present invention methodology for lifetime mapping of damaged silicon wafers. This imaging capability can be easily extended to other applications as will be shown in the sections below.

d) Surface Recombination Velocity and Minority Carrier Lifetime Anti-Correlation

Diagnostics of oxidized silicon wafers. In order to demonstrate the capability of measuring surface recombination velocity and minority carrier lifetime using the computational methodology presented in this invention, results from high and low resistivity wafers positioned differently in wafer tubes inside a horizontal furnace are presented. These results are part of a more extensive study carried out for a major semiconductor manufacturer.

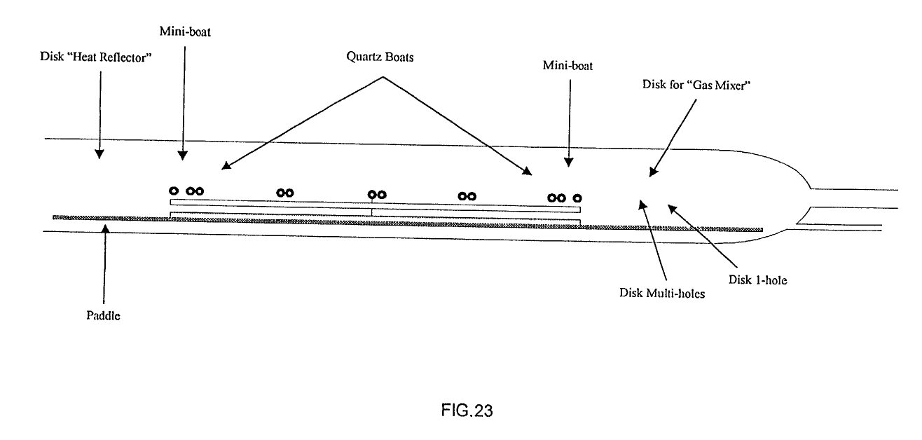

The oxidation and preparation process for the wafers utilized in this study is similar to the one reported previously in section iii.b. A schematic of the wafer tube and the boat arrangement inside the furnace is shown in FIG. 23 (Horizontal Furnace BDF-200). The test batch of wafers included groupings oxidized inside different tubes: Two wafers, one of low resistivity (front/door position, FIG. 23) and one of high resistivity (back/source position, FIG. 23), were placed near the door location. Two similar wafers were placed in the same order near the rear end of the tube (source). The spacing between two adjacent wafers was 3 mm, and the distance between the wafer pair at the front and the pair at the rear was about 16.5 cm.

The results of lifetime and front surface recombination velocity are discussed. The rest of the parameters (α, η, Dₙ and S₂) showed no significant variations with respect to position in the furnace. The range of values found for Dₙ for the various examined wafers was between 3-12 cm²/s. Our simulations have shown that for this type of variations in Dₙ the signal amplitude and phase do not show a significant change. Similar results for S₂ were also found.

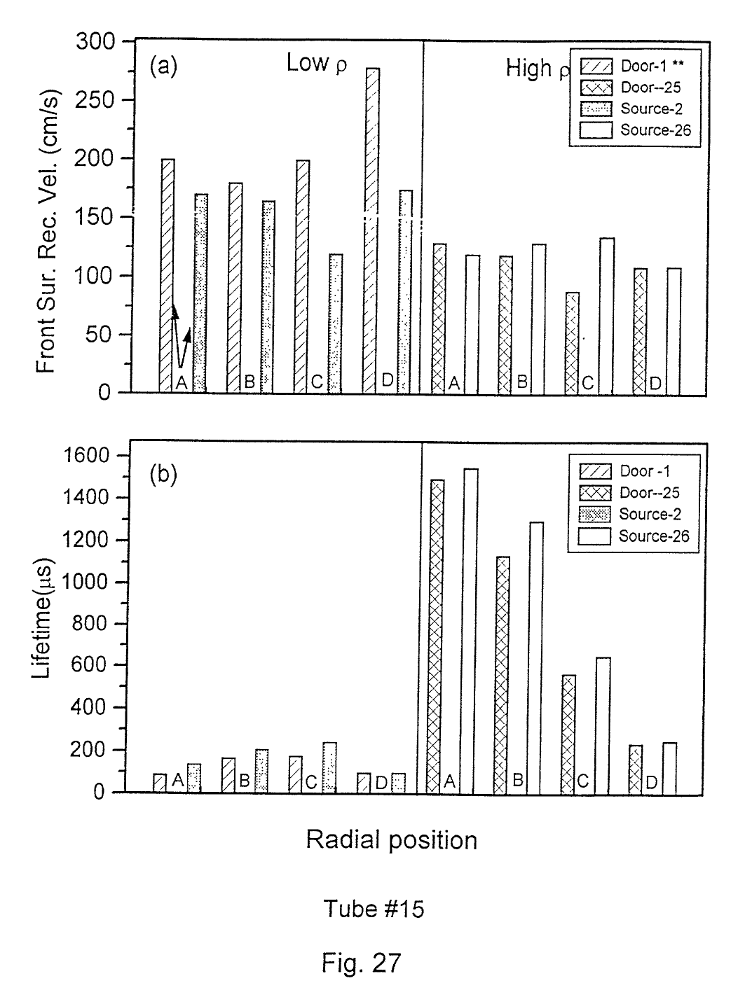

Four wafers (1, 2, 25 and 26) were analyzed with the 3D-PTR model/computational methodology. The lifetime values associated with the low resistivity wafers (LR) 1 and 2 are substantially lower that those with higher resistivity (HR) 25 and 26 (see histogram, FIG. 27(b)). The results indicated a monotonically decreasing lifetime from the center to the edge of the HR samples. We found that, in general, there is an inverse correlation between lifetime and surface recombination velocity. In FIG. 27, wafers 1 and 2 with lower lifetimes have somewhat higher front surface recombination velocities than wafers 25 and 26, histogram FIG. 27(a).

In conclusion, the longest lifetimes and lowest surface recombination velocities were measured for samples with high resistivity located near the source in a given tube, compared to those located near the door. We can speculate that this may be attributed to significant turbulence phenomena near the door location due to possible currents, and/or to heavy metal contamination of the door. There is a strong correlation between nominal wafer resistivity and transport properties: the longest lifetime values and lowest front surface recombination velocities were found in high-resistivity samples.

e) An Application of the Multi-Parameter Best-Fit PTR Method for Iron Concentration (Imaging) Measurements on p-Si Wafers.

A comparative study of electronic transport properties of p-Si wafers intentionally contaminated with Fe was performed using infrared photothermal radiometry (PTR) and micrometer photoconductance decay (μ-PCD). Strong correlations were found between PTR and μ-PCD lifetimes in a lightly contaminated wafer with no significant PTR transient behavior. The absolute PTR lifetime values were larger than the local averaged μ-PCD values, due to the different excitation wavelengths and probe depths. In a heavily contaminated wafer the μ-PCD and PTR lifetime correlation was poorer. PTR measurements were highly sensitive to Iron concentration, most likely due to the dependence of the bulk recombination lifetime on it. Rapid-scanned (non-steady-state) PTR images of the wafer surface exhibited strong correlations with both μ-PCD lifetime and [Fe] concentration images in both heavily and lightly contaminated wafers. For the lightly and uniformly contaminated wafer, PTR scanning imaging was found to be more sensitive to the Iron concentration and lifetime variations than μ-PCD

Two p-type (boron-doped) Si wafers grown from magnetic Czochralski ingots, 5 and 6 inches in diameter (labeled 1 and 2, respectively), with resistivities between 10-20 Ω-cm and (100) crystallographic orientation were investigated. The wafers were oxidized under standard oxygen flow (500 cm³/min) in a mini furnace at 1000° C. for 70 minutes. They were inspected with a μ-PCD probe after processing. Sample 1 was placed in a quartz boat vertically, while sample 2 was placed between two Silicon Carbide (SiC) boats horizontally. As a result, sample 1 received a relatively homogeneous Fe contamination of lower concentration than sample 2. This wafer was in contact with the SiC boats and thus received very inhomogeneous and heavier Fe contamination from both the solution and by contacting the boats.

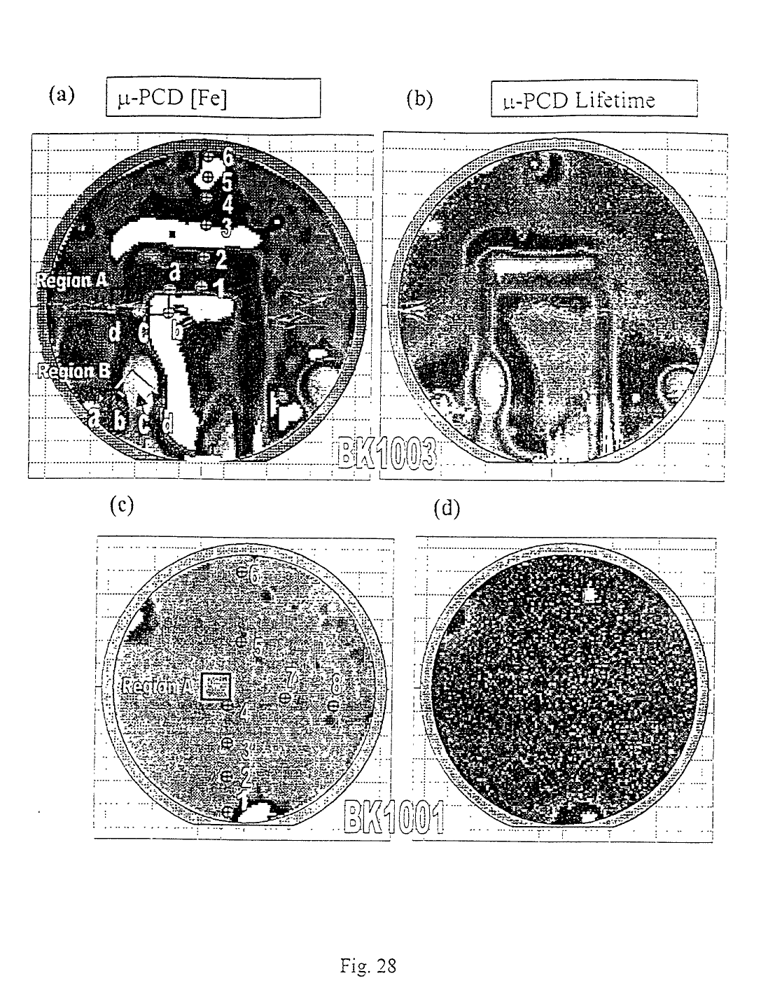

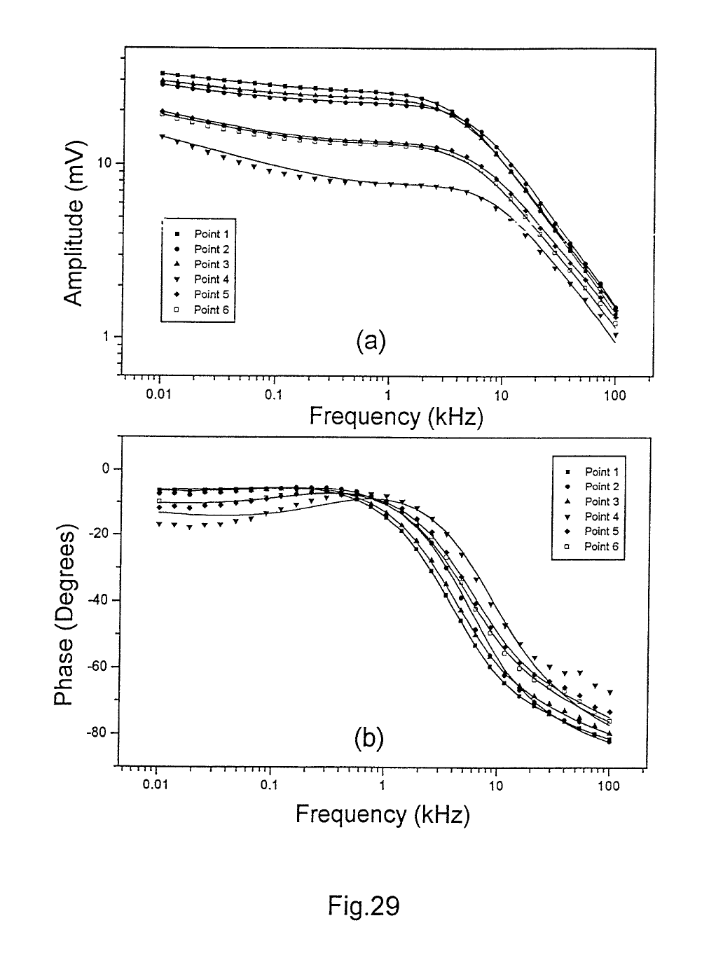

The influence of Fe concentration on the thermoelectronic properties was studied in the low-injection regime (typically about 30 mW of optical power). FIG. 28 shows the μ-PCD Fe concentration and lifetime maps of the entire wafers surface (samples 1 and 2). In sample 2 six radial points 1-6 and two regions were studied (1 cm×2 cm, region A; and 1 cm×1 cm, region B) (see FIG. 28a). μ-PCD scans showed that sample 1 was much more uniform than sample 2 and was thus examined with PTR at eight locations along the radial direction as well as inside a small area (1 cm×1 cm, Region A, FIG. 28b). Unfortunately, μ-PCD could not yield information about Fe concentration values inside the light regions across sample 2, FIG. 28a; and, to a much lesser extent, along the rims of sample 1, FIG. 28c. The Π-like shape in wafer 2 is the trace of a contact between the SiC boat pedestal and the Si wafer during the oxidation process and is a seat of heavy Fe contamination. The existence of PTR signal transients in these samples, a phenomenon exhibited by some wafers with electronically poor surfaces [A. Cuevas, P. A. Basore, G. Giroult-Matlakowski, C. Dubois, J. App. Phys. 80, 1996] was observed, especially with sample 2. Therefore, frequency scans at each point used to calculate thermoelectronic properties, were carried out only after steady state signal conditions were established. FIG. 29 shows the PTR signal for the six radial positions in sample 2. The theoretical fits are shown as continuous lines in that figure. Table IV shows the thermal and electronic values associated with each spot as were obtained through the computational multi-parameter data fit explained above. The average local μ-PCD carrier recombination lifetime values, extrapolated from the images in FIG. 28 with the help of calibration histograms (not shown) and the average [Fe] concentration, calculated for each spot in the same manner, are also given in Table IV. It is seen that the lifetime trends between PTR and μ-PCD measurements are well correlated, even though the PTR values are consistently higher. Recall that the PTR laser source wavelength was 514 nm, whereas μ-PCD data were obtained with optical excitation at 904 nm. At this excitation wavelength, the optical absorption coefficient of Si is β=1.1×10² cm⁻¹, and the μ-PCD skin depth is λ=100 μm [A. Dargys, J. Kundrotas in Handbook on Physical Properties of Ge, Si, GaAs and InP, Vilnius, Science and Encyclopedia Publishers, p. 100 (1994)]. Both microwave and PTR detection for this wafer were effected from the front (polished) surface. Given the long excitation wavelength, the μ-PCD optical probe “sees” deeper into the substrate and can be reasonably expected to yield shorter lifetime values from thoroughly Fe-contaminated wafers than the very-near-surface PTR probe.

In conclusion, PTR scanning imaging at 515-nm optical excitation produces amplitude and phase images which may be directly related to the near-surface [Fe] concentration distributions and are in good-to-excellent agreement with μ-PCD-derived recombination lifetime and [Fe] images. Quantitative PTR measurements of the thermal and electronic transport parameters from steady-state frequency scans are well-correlated with local averaged μ-PCD lifetime values and μ-PCD-derived [Fe] concentrations for lightly and uniformly contaminated p-Si; they are not as well correlated with heavily and non-uniformly contaminated samples. For the lightly and uniformly contaminated wafer, PTR scanning imaging was found to be more sensitive to [Fe] concentration and lifetime variations than μ-PCD-derived images.

TABLE IV
Thermal and electronic transport parameters for wafer sample 2
(6-inch diameter), determined from the 3-D PTR model,
for six radial positions 1-6, and region A and B, Fig. 28a.
μ-PCD lifetime and [Fe] concentration values are also shown.

| Location | Amplitude | α | τ_{PTR} | Dₙ | S₁ | Average τ_{μPCD} | |
|---|---|---|---|---|---|---|---|
| from center | (mV) | (cm²/s) | (μs) | (cm²/s) | (cm/s) | (μs) | Average [Fe](cm⁻³) |
| 0.00 (1) | 32.745 | 0.75 | 71 | 3.10 | 300 | 30 | <10¹⁰ |
| 1.27 (2) | 28.333 | 0.70 | 38 | 3.20 | 210 | 11 | >10¹² |
| 2.54 (3) | 29.674 | 0.73 | 63 | 3.10 | 370 | 25-30 | No-data |
| 3.81 (4) | 14.275 | 0.65 | 26 | 5.00 | 850 | 19 | 5 × 10¹¹ |
| 5.08 (5) | 19.707 | 0.70 | 45 | 4.60 | 750 | 25-30 | No-data |
| 5.58 (6) | 19.120 | 0.70 | 46 | 3.40 | 560 | 25-30 | No-data |
| Region A | | | | | | | |
| a | 26.632 | 0.70 | 70 | 3.40 | 300 | 19 | 5 × 10¹⁰ |
| b | 30.110 | 0.70 | 75 | 3.40 | 240 | 24 | 2 × 10¹⁰ |
| c | 26.818 | 0.70 | 70 | 3.40 | 330 | 12 | 5 × 10¹¹ |
| d | 17.8681 | 0.50 | 35 | 3.40 | 280 | 18 | 6 × 10¹⁰ |
| Region B | | | | | | | |
| a | 32.850 | 0.80 | 52 | 3.0 | 300 | 13 | 3 × 10¹¹ |
| b | 30.287 | 0.80 | 45 | 3.0 | 430 | 9 | 1 × 10¹² |
| c | 11.261 | 0.20 | 6 | 8.0 | 360 | 6 | >1 × 10¹² |
| d | 9.830 | 0.80 | 4 | 10.0 | 100 | 4 | >3 × 10¹² |

f) Application of the Multi-Parameter Best-Fit PTR Method for Thermoelectronic Characterization of p-Si Wafers Annealed in the Presence of an Electric Field.

The exact nature of the Si—SiO₂ interface is not yet fully understood. A simple picture of thermal oxidation is single crystalline silicon followed by a monolayer of SiOₓ, that is incompletely oxidized silicon. This, in turn, is followed by a strained region roughly 10-40 Å thick, and the remainder is an overlayer of stoichiometric, strain-free, amorphous SiO₂. For a typical oxide semiconductor (OS) device, interface traps and oxide charges exist that will, in one way or another affect the operating characteristics of devices, such as metal oxide semiconductors (MOS). The basic classification of these traps and charges involves [D. K. Schroder, Semiconductor Material and Device Characterization (Wiley, New York, 1998); Chap. 6, pp. 337-419.]: a) Interface trapped charges, Qᵢₜ, located at the Si—SiO₂ interface with energy states within the silicon bandgap. This type of charge exists in interface (or surface) electronic states, which can exchange charges with silicon in a short time. Qᵢₜ can possibly be produced by excess silicon (trivalent silicon), excess oxygen, and impurities. The interface trap states occupied by Qᵢₜ can be affected by the surface potential and can become charged or discharged. b) Fixed oxide charges, Q_{f}, located at, or near, the interface. These charges are immobile under an applied electric field and do not interact through exchanges with the underlying Si lattice. c) Oxide trapped charge, Qₒₜ, due to holes or electrons trapped in the bulk of the oxide. This charge does not normally interact with the underlying silicon, under room-temperature conditions. It can be annealed by allow-temperature (<500° C.) treatments. Finally, d) mobile ionic charges, Qₘ, such as Na⁺, K⁺, Li⁺, as well as negative ions and heavy metals. These charges are, nevertheless, typically immobile below 500° C. Early measurements on clean Si wafer surfaces in ultra high vacuum have confirmed that the interface trap density can be very high—of the order of the density of surface atoms (10¹⁵ atoms/cm²) [F. G. Allen and G. W. Gobeli, Phys. Rev. 127, 50 (1962).]. The foregoing classification of the various types of interface charges is helpful in understanding the mechanism of the laser radiometric results obtained under the influence of an external electric field in the present work.

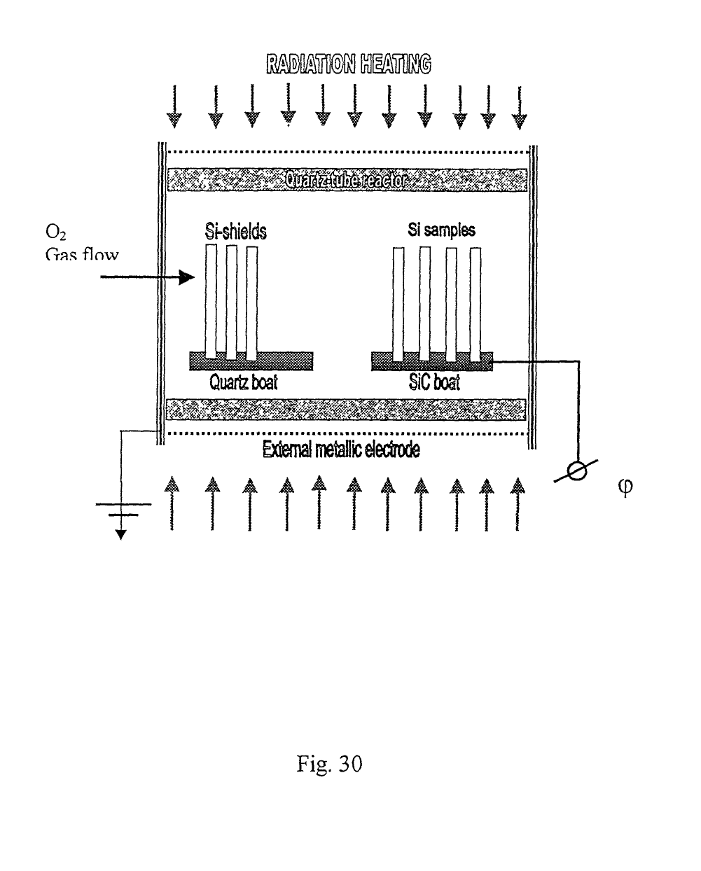

A typical configuration of thermal annealing of industrial Si wafers under an applied electric field is shown in cross-section in FIG. 30. The electric field was created by a voltage difference between the external grounded metallic electrode and the SiC boat at V=0, +1000 V, or −500 V. The vertically positioned Si wafers inside a quartz boat prevented direct contact of the cool O₂ gas flow with the heated sample wafers inside the SiC boat and were only used as O₂ gas flow dispersion devices or “Si shields”. The samples used in this work were usually positioned vertically in the standard silicon carbide boat as shown in FIG. 30. Samples were heated using quartz lamps as radiation heaters. Three p-Si wafers, 6″ in diameter, were thus studied, as follows.

1. Sample p-Si #1 was annealed without an electric field.

2. Sample p-Si #2 was annealed under an applied electric field of +1000 V.

3. Sample p-Si #3 was annealed under an applied electric field of −500 V.

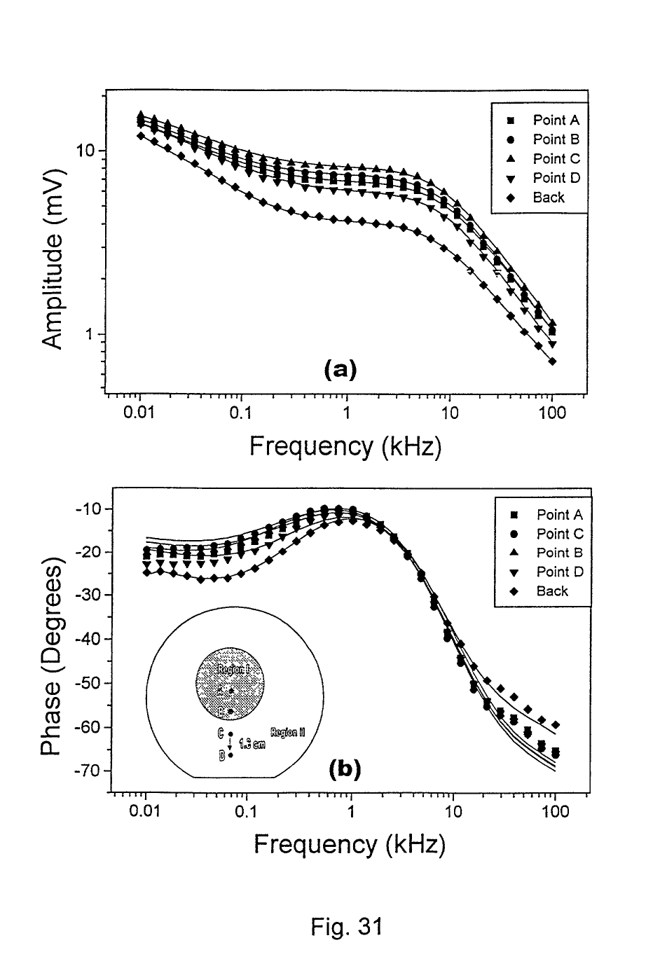

Thermal annealing was performed in standard pressure and O₂ flow rate of 500 cm³/min, at a temperature of 1050° C. for 70 min. The furnace was equipped with a tube-reactor of 10″ diameter and a pedestal; both made of fused quartz. The three foregoing wafers were examined under the PTR probe at four different positions across the front surface, and at one position located near the center of the back surface. The insert in FIG. 31 shows the locations of these points. Positions A-D were scanned along the radial direction from center to edge at 1.8-cm intervals. Regions I (grey) and II (white) refer to broadly observed uniformities in the distributions of both the carrier recombination lifetime and the surface recombination velocity of the p-Si#1 wafer, which was annealed without the application of a static electric field.

FIG. 31 shows the PTR signal amplitude (a) and phase (b) of Sample p-Si#3 (annealed with a positive electric field), for the four positions located as in insert. The continuous lines represent the best-fit results using the 3D-PTR-model/computational multi-fit parameter methodology of the present invention. The thermal and electronic parameters obtained at these positions, as well as at the one position in the back surface for all the samples studied, (carrier de-excitation or recombination lifetime, τ, minority carrier (electrons) diffusion length, Dₙ, front surface recombination velocity, S₁, and thermal diffusivity, α) are presented in Table V.

TABLE V
Thermoelectronic parameters of various wafers under various
electric field conditions

| Position | τ (μs) | S₁ (cm/s) | Dₙ (cm²/s) | α (cm²/s) |
|---|---|---|---|---|
| Wafer p-Si #1 | | | | |
| No Electric Field | | | | |
| A | 28 | 2900 | 3.6 | .55 |
| B | 28 | 2500 | 3.6 | .55 |
| C | 33.5 | 3500 | 7.0 | .57 |
| D | 33.5 | 3500 | 7.0 | .55 |
| Back | 32 | 3000 | 5.0 | .55 |
| Wafer pSi #2 | | | | |
| With Electric Field (+1000 V) | | | | |
| A | 53 | 4300 | 10 | .70 |
| B | 54 | 4200 | 10 | .70 |
| C | 52 | 4200 | 10.4 | .75 |
| D | 51 | 4200 | 10.4 | .70 |
| Back | 38 | 4500 | 6 | .40 |
| Wafer p-Si #3 | | | | |
| With Electric Field (−500 V) | | | | |
| A | 45 | 2200 | 8.3 | .65 |
| B | 46 | 1800 | 7.5 | .65 |
| C | 45 | 1700 | 7.5 | .65 |
| D | 44 | 1900 | 7.5 | .65 |
| Back A | 44 | 3200 | 6.0 | .50 |

According with FIG. 31(a) and (b) there exists good electronic uniformity across this wafer and the measured localized lifetimes lie between 28 and 33 μs. The results indicated that there exist roughly two regions in this sample: Region I (central part of the wafer) with relatively short lifetime and short front surface recombination velocity, located at r<3 cm from the center (see inset in FIG. 31); and Region II located at r>3 cm, in which both the lifetime and the surface recombination velocity values are longer.

The same procedures were applied to other wafers. The lifetime improvement for both wafers thermally annealed in the presence of an electric field of either sign is remarkable. Between the two polarizations of the electric field, the positive bias was most effective when applied to the SiC boat. The back surface response was somewhat different. Although the initial value of the lifetime at the single measured point was not different from those measured along one radius of the front surface of the p-Si#1 wafer, the improvement upon the application of the electric field was not as strong as that on the front surface, and its effectiveness with respect to polarity was reversed.

The most striking trend with the surface recombination velocity results is the significant increase of S₁ for the positive polarity of the field, and the also significant decrease for the negative polarity, both with respect to the zero-field case. The values of S on the back surface of the biased wafers p-Si#2 and p-Si#3 show the same relationship as the front-surface values, however, they both are higher than that in the zero-field case.

In conclusion, the methodology presented in this invention is able to measure the thermoelectronic parameter in samples annealed under the present of an electric field. Using this methodology it is also possible to detect differences between electronic transport parameters due the surface conditions.

g) Application of the Multi-Parameter Best-Fit PTR Method for Monitoring of Ion Implantation in Si with Carrier Plasma Waves.

Ion implantation is a very important technological process in the modern microelectronics industry. It is widely recognized that integrated circuit performance and yield are strongly dependent on the accuracy and uniformity of the implanted ion dose. This is specially true for some critical implantation steps such as the low-dose implant adjustment of the treshhold voltages of the integrated circuits.

For the purpose of this invention, we present quantitative experimental results on the sensitivity of the PTR set up and computational methodology (described previously, see section iv.c) to the implantation dose and energy.

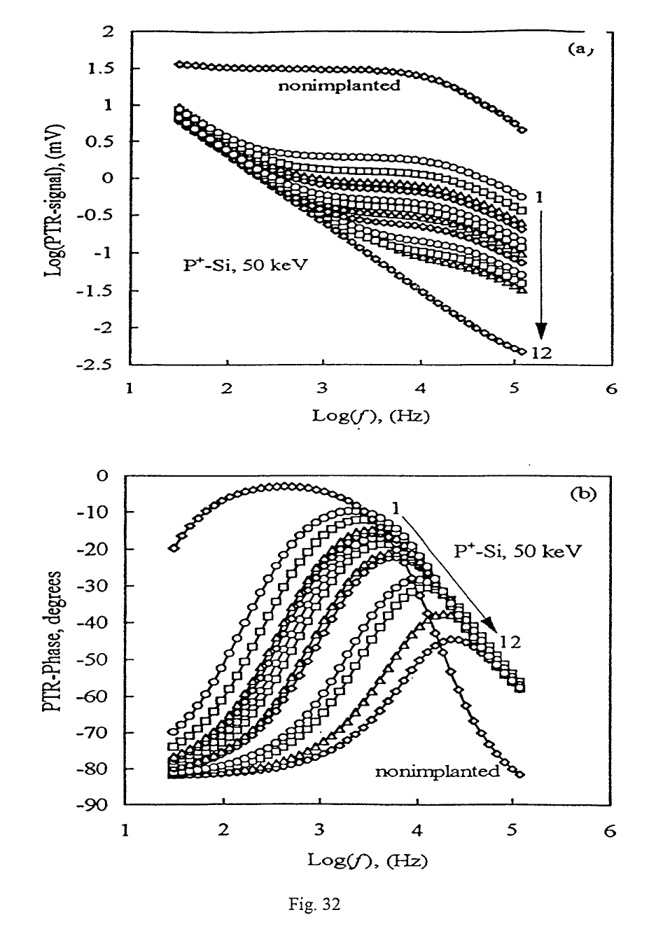

The PTR measurements were obtained from the near-center region of some Si wafers (B-doped, ρ˜14-24 Ohm-cm, thickness 510-520 μm) implanted with phosphorus to various doses from 5×10¹⁰ ions/cm² to 1×10¹⁶ ions/cm² at three different implantation energies: 50, 100, and 150 keV. The phosphorus implantation was performed through a thin oxide layer at room temperature. PTR amplitude (a) and phase (b) experimental results for one non-implanted silicon wafer and silicon wafers implanted with P⁺ ions of 50 keV energy to various doses are shown in FIG. 32. For the non-implanted wafer the PTR-amplitude exhibits carrier plasma behaviour [A. Salnick, A. Mandelis, and C. Jean, Appl. Phys. Lett. 69, 2522 (1996); A. Salnick, C. Jean and A. Mandelis, Solid-State Electron. 41, 591 (1997); A. Mandelis, A. Othonos, C. Christofides, and J. Boussey-Said, J. Appl. Phys. 80, 5332 (1996)] with the PTR amplitude saturated at low modulation frequencies and the PTR phase tending to saturate at −90° along the high frequency edge. For the implanted wafers a smooth transition from the plasma-dominated PTR-signal behavior at low doses to the nearly pure thermal signal at high implantation doses is observed (see FIG. 32). The solid lines in FIG. 32 correspond to the best fit obtained from the computational multi-parameter fitting methodology discussed previously in this invention. In the carrier plasma-dominated frequency region, the PTR signal has been found to be extremely sensitive to the damage introduced by ion implantation even at low doses and energies. At 10 kHz modulation frequency the difference between the PTR amplitudes from the non-implanted wafers and the wafer implanted with the lowest dose/energy (5×10¹⁰ cm², 50 keV) is more than one order of magnitude, thus allowing for the monitoring of ion implantation with dose and/or energy much lower than these values.

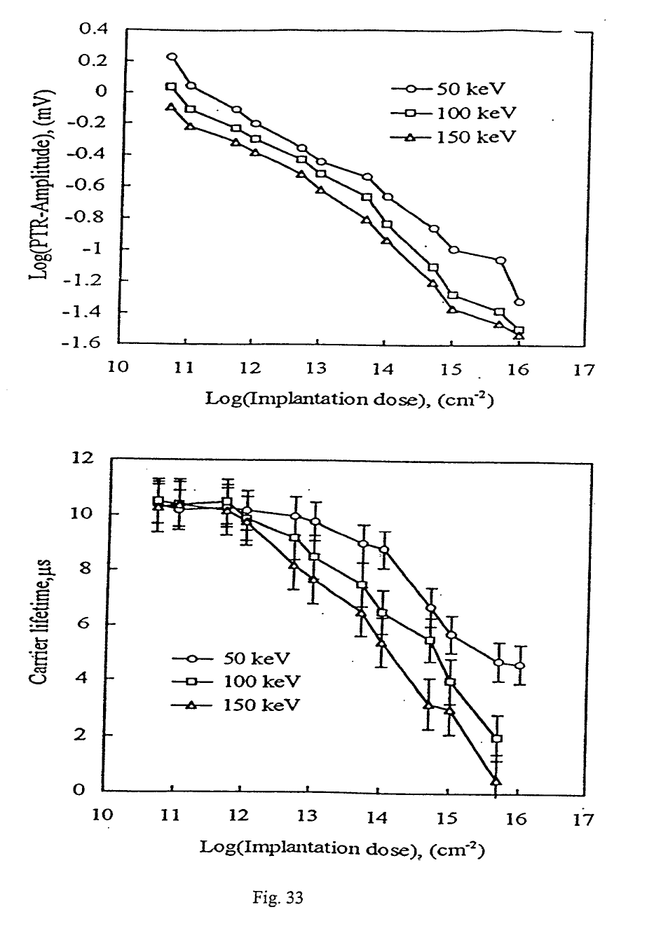

The variations of carrier lifetimes with implantation dose and energy are shown in FIG. 33(a). These results were obtained from the quantitative analysis performed by using the computational methodology presented in this invention. As the implantation dose/energy increases, the carrier lifetime remains unchanged and equal to that of a reference wafer (˜10 μs) up to a threshold value of the dose (˜10¹² cm⁻²) and then starts to decrease with a rate which is implantation rate dependent. This effect is related to the fact that the PTR technique is measuring the photoexcited carrier lifetime in layers lying deeper than the thickness of the implanted layer (<1 μm). Thus the value of τ in implanted Si wafers is unaffected by damage introduced by ion implantation to the uppermost layer until the effective depth of the electronically sensitive defects significantly exceeds the thickness of the implanted layer at high doses and/or energies.

The PTR amplitude in the plasma dominated region (10 kHz) as a function of the implantation dose for various implantation energies is presented in FIG. 33(b). The lattice damage induced by the ion beam causes the plasma wave signal to decrease below that of the non-implanted reference wafer in a pronounced manner. The functional dependencies exhibited by the data in FIG. 33(b) are smooth, monotonically decreasing and gradual, such that a very good sensitivity of the PTR amplitude to the implantation dose is maintained over more than five orders of magnitude dose.

h) Application of the PTR/Computational Methodology to Scribeline Characterization of Integrated Circuits.

There are four basic operations performed on a wafer during the fabrication process: layering, patterning, doping and heat treatments. Layering is the operation used to add thin layers to the wafer surface. These layers are insulators, semiconductors or conductors including interconnects; they are made of different materials and are grown or deposited by a variety of techniques [P. Van Zant in: Microchip Fabrication, McGraw-Hill, New York, 1997, p. 102]. Patterning is the series of steps that result in the removal of selected portions of the added layers. This process is also known as photomasking, masking, photolithography, and microlithography. It is the patterning operation that creates the surface parts of the device that make up a circuit. This operation sets the critical dimensions of devices. Errors in the patterning process can cause changes in the electrical functionality of the devices and of the circuit. Contamination in any and all of the process steps can introduce defects. Contamination problems tend to be magnified by the fact that patterning operations are performed on the wafer several times in the course of the wafer fabrication process.

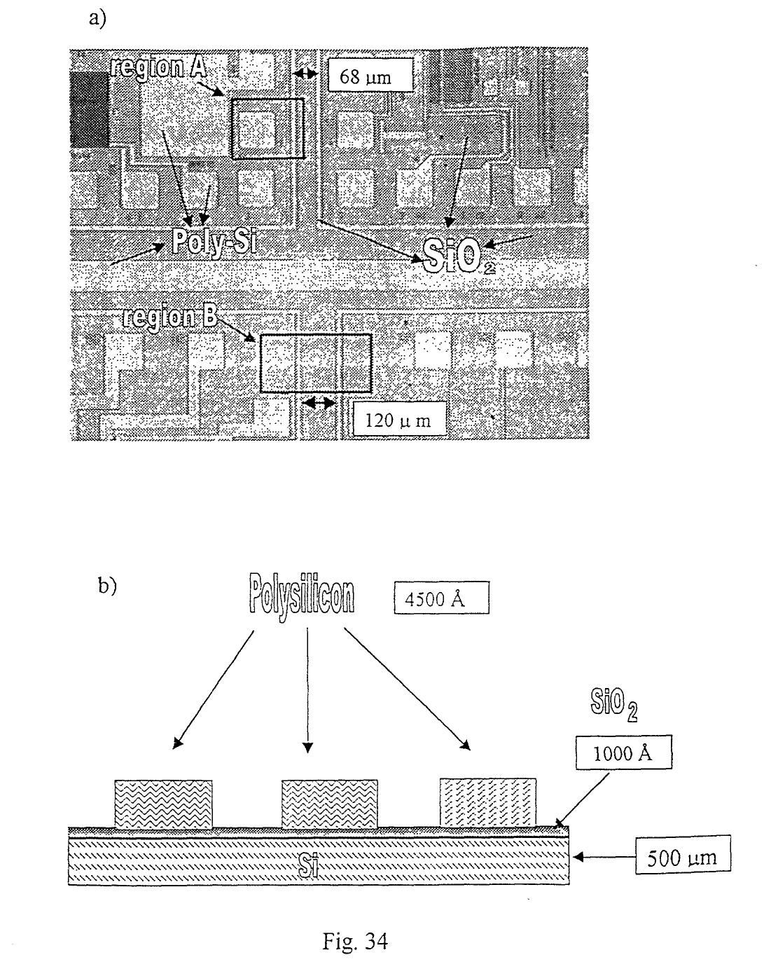

Recombination lifetimes were monitored within the scribelines of various processed wafers, for reliable diagnostics of the onset of furnace (and/or other process) contamination, with the PTR computational methodology discussed in this invention. The samples used in this work were four 4″ wafers of p-type Si, with patterned device structures. The wafers had been oxidized with a 1000-Å gate oxide. Polycrystalline Si (polysilicon) was deposited and patterned to form pads of different sizes and shapes. FIG. 34(a) shows an optical microscope photograph of two different sizes of scribelines. One type of scribeline was 120 μm in width; the other type was about 68 μm wide. Throughout this work, bright structures in photographs are (light scattering) poly-Si pads or devices, whereas darker regions are the more highly reflecting SiO₂—Si interfaces. FIG. 34(b) is a schematic of the cross-sectional geometry of the wafer. The poly-Si layer thickness was about 4500 Å.

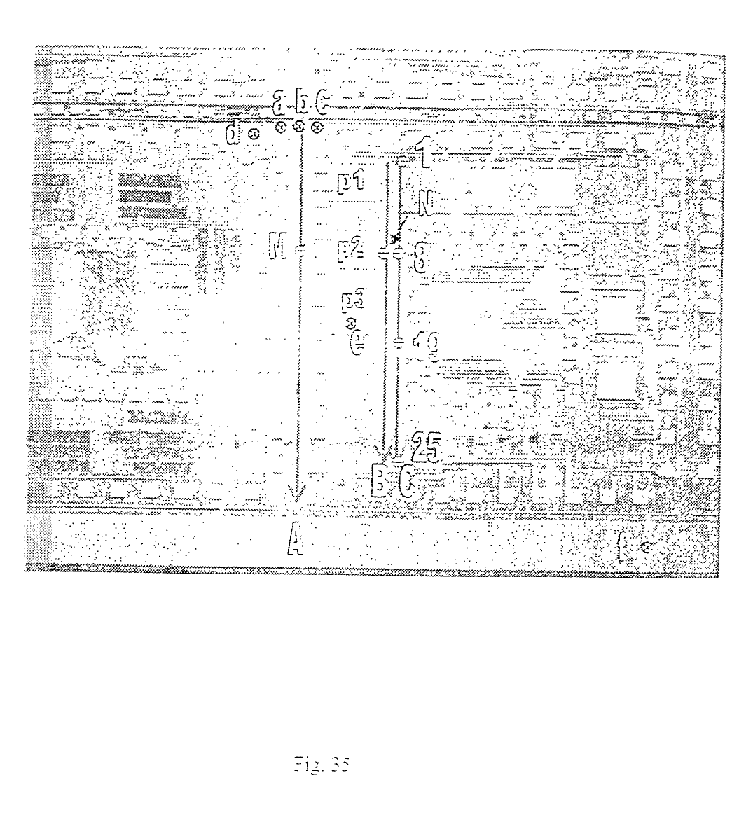

Radiometric images were generated using a manual scanning system. These images are PTR amplitude and phase scans at a fixed laser-beam-intensity modulation frequency. We have shown that the amplitude scales linearly with the recombination lifetime in some ranges of parameters, FIG. 21. Therefore, an x-y amplitude scan of Si substrate (with or without the presence of oxide) when it is properly calibrated in units of μs, yields, in principle, a recombination lifetime image of the scanned region. Such a radiometric image has been called a “thermoelectronic image”, or “thermoelectronic scan”. The resolution of each spot was 20 μm. Beam size was estimated to be 48 μm using a CCD camera and optical scan measurements through a 5-μm pinhole. The laser power on the wafer was about 40 mW, which corresponds to a low injection level. On scanning across typical wafer structures shown in FIG. 35, the CCD camera was used to determine the desired location and to guide the laser beam inside or around the neighborhood of a given scribeline.

The sample wafers were scanned along and across a scribeline, through poly-Si and oxide-covered regions. FIG. 35 shows the topology of a typical small area near the crossing of two scribelines, one of which contains test inserts. Frequency scans were carried out at six locations (a-f): three (a, b, c) across the insert-free scribeline (120-μm-wide) very near the crossing point and within the silicon oxide region; and three (d,e,f) at various poly-Si locations. The purpose of these scans was to explore the capabilities of PTR for measuring recombination lifetimes in and around scribeline locations with the goal of using these values as very convenient benchmarks for wafer contamination monitoring during (or after) processing.

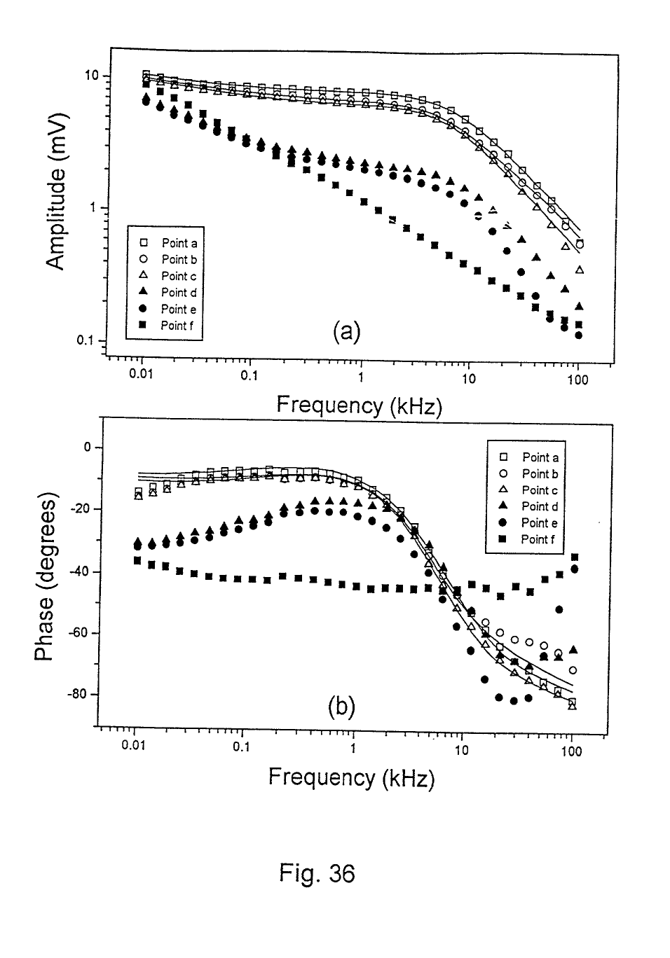

FIG. 36 shows the PTR frequency amplitude and phase obtained at the six locations of FIG. 35: three scans (open symbols) were performed through the oxide layer outside the scribeline (points a, c, f in FIG. 35); and three more scans (solid symbols) on three poly-Si pads of different sizes and 4500-Å thickness scribeline (points d, e, and f in FIG. 35). One scan was performed inside the scribeline (point b on the straight line A in FIG. 35). Continuous lines (over the open symbols) represent the multi-parameter best fits of the experimental data for SiO₂ locations using the 3-D PTR/computational method described in this invention. Point (d) lies inside a small poly-Si pad (150 μm×150 μm) close to the scribe line. Point (e) lies inside a larger poly-Si pad (300 μm×300 μm). Finally, point (f) lies inside a wide poly-Si strip perpendicular to the investigated scribeline. It is interesting to see that the PTR signals from these poly-Si regions exhibit different behavior in FIG. 36. The smallest pad (d) and the intermediate size pad (e) exhibit both thermal and carrier plasma behavior, with the free-carrier contributions clearly appearing at frequencies >500 Hz. On the other hand, the poly-Si strip (f) exhibits purely thermal contribution throughout the entire frequency range 10 Hz-100 kHz. These systems consist of three layers (Si substrate+gate SiO₂+poly-Si). For this reason, it was not possible to fit the experimental data using our 3D-PTR model, which predicts the response of a single-layer Si wafer. An extension of the single-layer PTR model to electronically active multi-layers along the lines of our earlier theoretical treatment of modulated thermoreflectance signals from similar geometries is currently under development. The fact that the responses of these three poly-Si layers were different may be likely due to the increasingly greater depletion of the photoexcited free carrier contribution with increasing lateral dimensions of the layer. Earlier work [A. Salnick, C. Jean and A. Mandelis, Solid-State Electron., 41, 591, 1997] showed that lifetime measurements through poly-Si layers in MOS capacitor structures are possible, since any photoexcited carrier within the Si substrate can emit infrared radiation through the pad, which can be captured by the PTR detection electronics. Under this hypothesis, scattered light propagating across a small-size poly-Si pad can eventually penetrate the oxide-Si underlayer and generate carriers, thus creating the partly plasma-wave scan of FIG. 36, curves (d, e). As the lateral dimensions of the poly-Si layer increase, the probability of the essentially spherically propagating scattered photons reaching the substrate diminishes due to the increased lateral (radial) scattering in the polysilicon. As a result, more of the incident optical power is converted readily into heat within the poly-Si layer, creating the purely thermal scan of FIG. 36, curve (f). This purely thermal behavior of the strip (f) is consistent with the expected very high optical-to-thermal (nonradiative) conversion efficiency of the laser radiation in the presence of a very high density of free thermal carriers within the poly-Si layer (nearly metallic behavior).

Electronic parameters for the probed SiO₂ locations (a-c) are shown in Table VI. According to these results the SiO₂ regions inside and around the scribeline exhibit the same lifetime (˜35 μs), without any great variations in the values of the carrier diffusion coefficient. Surface recombination velocity S₁, however, does vary substantially as a function of location. No transient behavior was found in any of the examined locations, thus indicating good quality surfaces with low surface defect state densities, as expected from oxidized SiO₂—Si interfaces.

TABLE VI
Electronic and thermal parameters for three points located
across the scribeline (see FIG. 35).

| | | α | τ | Dₙ | S₁ |
|---|---|---|---|---|---|
| Location | Amplitude | (cm²/s) | (μs) | (cm²/s) | (cm/s) |
| a | 10.613 | 0.55 | 36 | 2.0 | 440 |
| b | 10.475 | 0.55 | 35 | 2.4 | 630 |
| c | 9.730 | 0.55 | 35 | 2.0 | 600 |

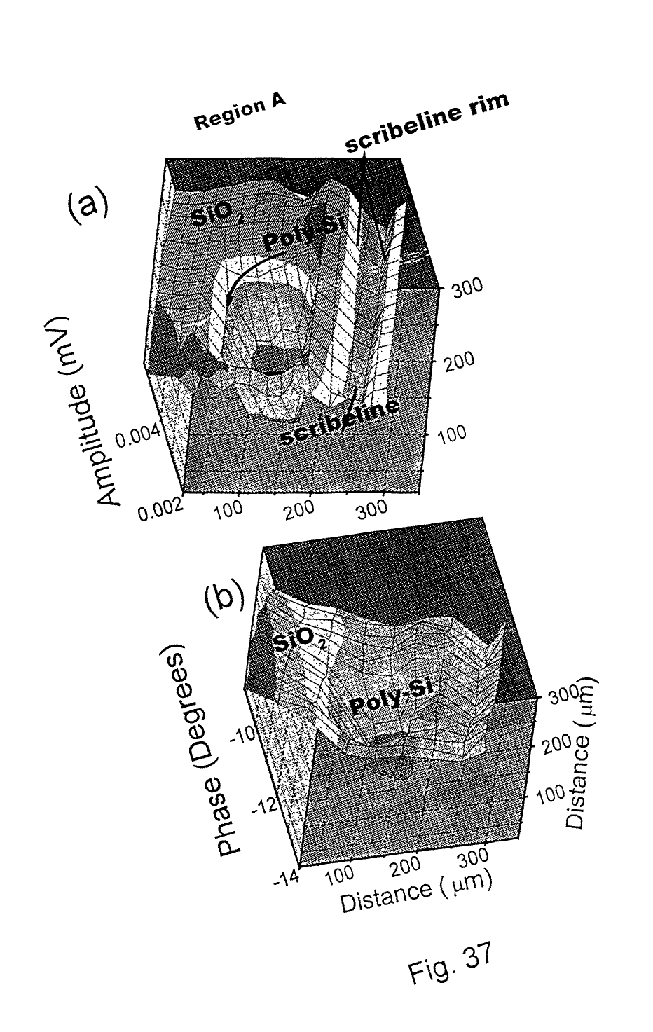

Thermoelectronic Images. One region close to the central part of a wafer was scanned with a step of 20 μm, 300 μm×340 μm in area (Region A in FIG. 34(a), located near the center of the wafer. This region was chosen for PTR scanning imaging because it encompasses a square poly-Si test pad, a poly-Si scribeline rim, and half the width of a 120-μm wide scribeline. The PTR signal amplitude and phase images of this region obtained at the modulation frequency of 1 kHz are shown in FIGS. 37(a) and 37(b), respectively. The low amplitude and large phase lag values correspond to the poly-Si regions as expected from the efficient nonradiative conversion at this location leading to the absence of measurable photoexcited free-carrier densities and the domination of the signal by the thermal-wave component within the detection area of the infrared detector. On the other hand, high amplitude and small phase-lag values are associated with direct probing of the Si—SiO₇ interfaces, due to the domination of the PTR signal by the free-carrier plasma component. These results demonstrate that PTR imaging can be used to identify areas of high and low electronic activity across a particular patterned region of a processed wafer. It is important to note that neither the amplitude nor the phase levels inside the half-scribeline image are equal to those from the oxide patches outside the scribeline.

iii) PTR Depth Profilometry and PTR Multi-Layer Metrology by Heuristically Eliminating Roughness

In the reconstruction of depth profiles of thermophysical properties in solids, there are two aspects to consider: (a) a forward problem (theoretical model) must be formulated; and (b) an inverse method (numerical model) must be applied to retrieve the inverse variable (thermal diffusivity).

(a) Theoretical Model for Discrete Homogeneous Layer on a Semi-Infinite Inhomogeneous Layer

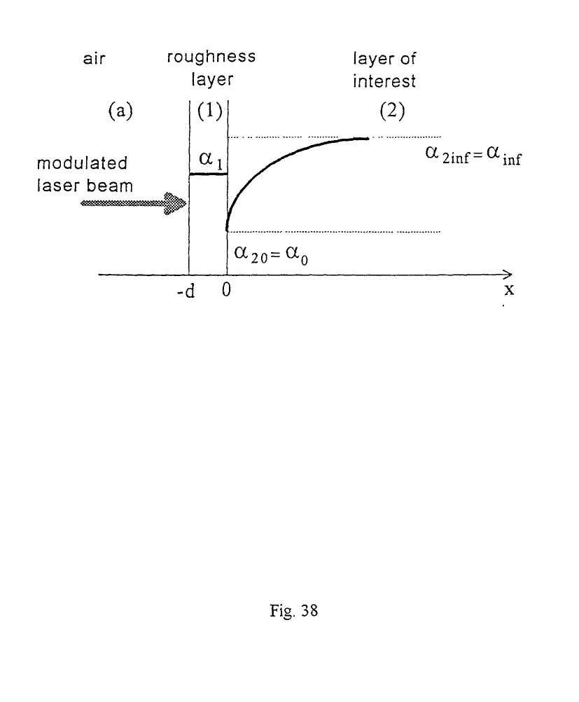

The regions surrounding the investigated layer are an air-solid interface and a solid-backing interface as shown in FIG. 38. The a.c. temperature fields in each region air (a), rough layer (1) and investigated inhomogeneous layer (2) are:

T₀(χ,ω)=De^{σ}^{₀}^{(χ+d)}; χ≦−d [symbol] χ+d≦0 (31a)

T₁(χ,ω)=Be^{σ}^{₁}^{χ}+Ce^{-σ}^{₁}^{χ}; −d≦χ≦0 (31b)

$${T}_{2} ( x , ω ) = \frac{1}{2 \sqrt{{e}_{2} ( x )}} [ {C}_{1} {ⅇ}^{{H}_{2} ( x )} - {C}_{2} {ⅇ}^{{H}_{2} ( x )} ] ; 0 \leq x \leq ∞ \qquad \text{(31c)}$$

Equation (31a) is the bounded (finite as χ→∞) solution to the thermal-wave equation for homogeneous semi-infinite medium [A. Mandelis, J. Math. Phys. 26, 2676 (1985)] and equation (31b) is the solution for a finite homogeneous region. In equation (31a) and (31b) σⱼ is the complex wave number defined in equation (4) with αⱼ the thermal diffusivity of the j-th medium (j: 0,1). Equation (31c) is the result of a treatment of the inhomogeneous layer thermal wave field in terms of the Hamilton-Jacobi formulation as shown by A. Mandelis, J. Math. Phys. 26, 2676 (1985) and applying the appropriate subscript (2) (see FIG. 38) to the expressions for identifying the investigated layer. Constants D, B and C depend on the boundary and limiting conditions of the system and C₁ and C₂ are as defined by A. Mandelis, J. Math. Phys. 26, 2676 (1985).

The boundary conditions for the investigated region at χ=−d, 0 are from continuity of temperature and heat flux:

T₁(χ=−dω)=T₀(χ=−d,ω) (32a)

$$- {k}_{1} \frac{ⅆ {T}_{1} ( x = - d , ω )}{ⅆ x} + - {k}_{0} \frac{ⅆ {T}_{0} ( x = - d , ω )}{ⅆ x} = \frac{1}{2} {Q}_{0} {ⅇ}^{ⅈω i} , \qquad \text{(32b)}$$

T₁(χ=0,ω)=T₀(χ=0,ω) (32c)

$$- {k}_{1} \frac{ⅆ {T}_{1} ( x = 0 , ω )}{ⅆ x} + - {k}_{0} \frac{ⅆ {T}_{0} ( x = 0 , ω )}{ⅆ x} = \frac{1}{2} {Q}_{0} {ⅇ}^{ⅈω i} , \qquad \text{(32d)}$$

where Q₀ represents the thermal source fluence at the material surface [W/m²] assuming 100% laser power absorption. In the limit χ→∞ the ac temperature, T₂(χ) generated should be zero. Applying this condition to equation (31c) yields,

$$\frac{{P}_{τ 0} {ⅇ}^{- π / 4}}{\sqrt{ω}} = - {τ}_{0} ( \frac{1 + {ⅇ}^{- {H}_{2} ( ∞ )}}{1 - {ⅇ}^{- 2 {H}_{2} ( ∞ )}} ) \qquad ( 33 )$$

Substituting equation (33) to (31c) gives,

$${T}_{2} ( x ) = \frac{{τ}_{0}}{\sqrt{{e}_{2} ( x )}} [ \frac{{ⅇ}^{- {H}_{2} ( x )} - {ⅇ}^{- [ 2 {H}_{2} ( ∞ ) - {H}_{2} ( x ) ]}}{1 - {ⅇ}^{- 2 {H}_{2} ( ∞ )}} ] \qquad ( 34 )$$

To be used in the boundary conditions the first derivative of T₂(χ) with respect to χ is taken and results in

$$\begin{matrix}\frac{ⅆ}{ⅆ x} {T}_{2} ( x ) = \frac{{τ}_{0}}{\sqrt{{e}_{2} ( x )}} \frac{ⅆ}{ⅆ x} [ \frac{{ⅇ}^{- {H}_{2} ( x )} - {ⅇ}^{- [ 2 {H}_{2} ( ∞ ) - {H}_{2} ( x ) ]}}{1 - {ⅇ}^{- 2 {H}_{2} ( ∞ )}} ] + \\ {τ}_{0} [ \frac{{ⅇ}^{{\_H}_{2} ( x )} - {ⅇ}^{- [ 2 {H}_{2} ( ∞ ) - {H}_{2} ( x ) ]}}{1 - {ⅇ}^{- 2 {H}_{2} ( ∞ )}} ] \frac{ⅆ}{ⅆ x} [ {e}_{2}^{- \frac{1}{2}} ( x ) ]\end{matrix} \qquad ( 35 )$$

An approximation is now made in neglecting the second part of equation (35) by setting the thermal effusivity derivative equal to zero:

$$\frac{ⅆ}{ⅆ x} [ {e}_{2}^{- \frac{1}{2}} ( x ) ] \approx 0 \qquad ( 36 )$$

This assumption amounts to a requirement for nonsteep local variations of the effusivity. This is easily satisfied when the thermophysical field is evaluated at small incremental depth slices where it is not expected that local steep diffusivity gradients may exist [A. Mandelis, S. B. Peralta and J. Thoen, J. Appl. Phys. 70, 1761 (1991)]. Solving for the constants by using the boundary conditions and substituting in equation (34), the temperature distribution at layer (2) becomes:

$$\begin{matrix}\begin{matrix}{T}_{2} ( x ) = \frac{{Q}_{0} \sqrt{{R}_{2} x )}}{{k}_{2} ( 0 ) {σ}_{2} ( 0 )} [ \frac{{ⅇ}^{- {H}_{2} ( x )} - {ⅇ}^{- [ 2 {H}_{2} ( ∞ ) - {H}_{2} ( x ) ]}}{1 - {ⅇ}^{- 2 {H}_{δ} ( ∞ )}} ] \times \\ [ \frac{{b}_{21} ( 0 ) {ⅇ}^{- {σ}_{1} d}}{( 1 + {b}_{21} ( 0 ) {F}_{2} ) - ( 1 - {b}_{21} ( 0 ) {F}_{2} ) {ⅇ}^{- 2 {σ}_{1} d}} ]\end{matrix} \\ where , & ( 37 ) \\ {F}_{2} = \frac{1 + {ⅇ}^{- 2 {H}_{2} ( ∞ )}}{1 - {ⅇ}^{- 2 {H}_{2} ( ∞ )}} & \text{(38a)} \\ {b}_{21} ( 0 ) = \frac{{k}_{2} ( 0 ) {σ}_{2} ( 0 )}{{k}_{1} {σ}_{1}} = {b}_{201} & \text{(38b)} \\ {R}_{2} ( x ) = \frac{{e}_{2} ( 0 )}{{e}_{2} ( x )} & \text{(38c)}\end{matrix}$$

In deriving equation (37) the air-solid interface was assumed negligible. This is a valid assumption since in most cases the thermal coupling coefficient b₀₁<<1 (near adiabatic conditions). Similarly, by substitution, the temperature distribution in the homogeneous layer (1) from equation (31b) becomes:

$$\begin{matrix}{T}_{1} ( x ) = \frac{{Q}_{0}}{2 {k}_{1} {σ}_{1}} [ \frac{{ⅇ}^{- {σ}_{2} ( x + d )} + {Γ}_{21} ( 0 ) {ⅇ}^{- {σ}_{2} ( d - x )}}{1 - {Γ}_{21} ( 0 ) {ⅇ}^{- 2 {σ}_{2} d}} ] \\ \text{where,} & ( 39 ) \\ {Γ}_{21} ( 0 ) = \frac{1 - {b}_{21} ( 0 ) {F}_{2}}{1 + {b}_{21} ( 0 ) F} & ( 40 )\end{matrix}$$

Although it will be seen that the results are valid for arbitrary thermal diffusivity depth profiles, for this analysis the following simple simulated functional dependence of the solid inhomogeneous region thermal diffusivity is assumed [see, A. Mandelis, F. Funak and M. Munidasa, J. Appl, Phys. 80, 5570 (1996)]:

$${a}_{2} ( x ) = {a}_{s} ( x ) = {a}_{0} ( \frac{1 + Δ {ⅇ}^{- qx}}{1 + Δ} ) \qquad ( 41 )$$

such that

aₛ(∞)=a_{∞}, aₛ(0)=a₀

and

$$Δ = \sqrt{\frac{{a}_{0}}{{a}_{∞}} - 1} \qquad ( 42 )$$

The parameter q is a constant that determines the rate of thermophysical decay if a₀>a_{∞} or growth if a₀<a_{∞}.

By defining a form for the inhomogeneous thermal diffusivity the integral for H(x) [A. Mandelis, J. Math. Phys. 26, 2676 (1985)] gives H₂(∞)→∞ which is also valid for a constant homogeneous thermal diffusivity in layer (2). Thus from equation (38a) F₂=1 and equation (40) Γ₁₂(0)=γ₂₁(0)=γ₂₀₁. The resulting temperature, for the inhomogeneous layer (2) from equation (37) simplifies to,

$$\begin{matrix}{T}_{2} ( x ) = \frac{{Q}_{0} \sqrt{{R}_{2} ( x )}}{{k}_{2} ( 0 ) {σ}_{2} ( 0 )} \frac{{b}_{21} ( 0 ) {ⅇ}^{- {σ}_{1} d - {H}_{2} ( x )}}{( 1 + {b}_{21} ( 0 ) ) - ( 1 - {b}_{21} ( 0 ) ) {ⅇ}^{- 2 {σ}_{1} d}} \\ = \frac{{Q}_{0} \sqrt{{R}_{2} ( x )}}{{k}_{1} {σ}_{1}} \frac{{ⅇ}^{- {σ}_{1} d - {H}_{2} ( x )}}{( 1 + {b}_{21} ( 0 ) ) ( 1 - {γ}_{21} ( 0 ) {ⅇ}^{- 2 {σ}_{1} d} )}\end{matrix} \qquad ( 43 )$$

The superposition principle is implemented in solving the complete expression for the thermal wave field in an inhomogeneous solid bounded by regions shown in FIG. 38. According to this principle, any complicate linear boundary-value problem can have a solution written as a linear combination of solutions to a number of simpler boundary value problems. The general solution of the thermal wave field for the regions shown in FIG. 38 is then,

T(χ)=aT₂(χ,ω),+bT₀(χ,ω)+cT_{∞}(χ,ω) (44)

where T₀ and T_{∞} are the temperature distributions with constant thermal diffusivities a₀ and a_{∞} in layer (2) respectively, and the expressions are

$$\begin{matrix}{T}_{0} ( x , ω ) = \frac{{Q}_{0} {ⅇ}^{- {σ}_{1} d - {a}_{20} x}}{{k}_{1} {σ}_{1} ( 1 + {b}_{201} ) ( 1 - {γ}_{201} {ⅇ}^{- 2 {σ}_{1} d} )} & \text{(45a)} \\ {T}_{∞} ( x , ω ) = \frac{{Q}_{0} {ⅇ}^{- {σ}_{1} d - {σ}_{2 ∞} x}}{{k}_{1} {σ}_{1} ( 1 + {b}_{2 ∞1} ) ( 1 - {γ}_{2 ∞ 1} {ⅇ}^{- 2 {σ}_{1} d} )} & \text{(45b)}\end{matrix}$$

where b₂₀₁ and γ₂₀₁ on are as defined in equation (38b) and (40) (F₂=1) respectively. b₂₀₁ and γ₂₀₁ are defined similarly by replacing 0 with ∞ in equations (38b) and (40) respectively.

Determination of the constants (a, b, c). Constants a, b and c are determined by the various limiting case requirements of the problem. In the limit of very large distances from the surface, χ→∞, equation (41) gives a constant diffusivity profile of a_{∞} and equation (44) leads to

$${lim}_{x \to ∞} \{ a \frac{{T}_{2} ( x , ω )}{{T}_{∞} ( x , ω )} + \frac{{T}_{0} ( x , ω )}{{T}_{∞} ( x , ω )} + c \} = 1 \qquad \text{(46a)}$$

By substituting equations (43), (45a) and (45b) and by setting b=0 to satisfy boundness results in

$$\begin{matrix}a = ( 1 - c ) \frac{Z}{\sqrt{{R}_{2} ( x )}} {ⅇ}^{- {a}_{2 ∞} {J}_{∞}} , \\ \text{where} & \text{(46b)} \\ {J}_{∞} = \frac{1}{2 q} ln ( \vert \frac{{a}_{20}}{{a}_{2 ∞}} \vert ) , & \text{(46c)} \\ Z = \frac{( 1 + {b}_{201} ) ( 1 - {γ}_{201} {ⅇ}^{- 2 {σ}_{1} d} )}{( 1 + {b}_{2 ∞1} ) ( 1 - {γ}_{201} {ⅇ}^{- 2 {σ}_{1} d} )} & \text{(46d)}\end{matrix}$$

In the very high frequency limitω→∞, the penetration depth of the thermal wave is zero which results in

T(0,ω→∞)=T₀(0,ω) (47)

Substituting (46b) in equation (44) and since σ_{2∞}→∞ as ω→∞ it can be shown that

$$c = \frac{{T}_{0} ( 0 , ω )}{{T}_{∞} ( 0 , ω )} \qquad ( 48 )$$

In the very low frequency limit ω→0, the penetration depth is infinite resulting in

T(0,ω→0)=T_{∞}(0, ω) (49)

Substituting (46b) and (48) in equation (44) and since σ_{2∞}→0 as ω→0 it can be shown that

$$( 1 - \frac{{T}_{0} ( 0 , ω )}{{T}_{∞} ( 0 , ω )} ) \frac{Z}{\sqrt{{R}_{2} ( ∞ )}} = \frac{{T}_{∞} ( 0 , ω )}{{T}_{0} ( 0 , ω )} = Z \qquad ( 50 )$$

which results in

R₂(∞)=1 (51)

Finally, substituting all the determined constants from equations (48), (51) in equation (44) and calculating the field at the front surface χ=−d,

$$T ( - d , ω ) = \frac{{Q}_{0}}{2 {k}_{1} {σ}_{1}} [ \frac{1 + {γ}_{201} {ⅇ}^{- 2 {σ}_{1} d}}{1 - {γ}_{201} {ⅇ}^{- 2 {σ}_{1} d}} ] ( 1 + ( Z - 1 ) {ⅇ}^{- {σ}_{2 ∞} {J}_{∞}} ) \qquad ( 52 )$$

where d cannot→∞.

(b) Numerical Method

Experimentally the amplitude and phase which correspond to the surface temperature distribution, T(0,ω) are obtained. The theoretical values of the data pair are calculated by

T(0,ω)=|M(ω)|e^{(Δφ(ω)} (53)

where M(ω) is the amplitude and Δφ(ω) is the phase at an angular frequency ω. At each frequency the amplitude, phase and the derivative of phase are use to calculate α₀, α₁, and q. Although a profile of the form in equation (41) is assumed, the actual profile is updated at each frequency by recalculating the parameters α₀, α₁, and q. The reconstruction method used to solve for the parameters α₀₍ⱼ₎, and qⱼ is a multidimensional secant method, known as Broyden's method [A. Mandelis, P. Funak and M. Munidasa, J. Appl. Phys. 80, 5570 (1996)], and is based on minimizing the difference between the experimental and theoretical data for amplitude, phase as follows,

|Mₑₓₚ(ωⱼ)|−|Mₜₕ(ωⱼ)|=0 (54a)

|Δφₑₓₚ(ωⱼ)|−|Δφₜₕ(ωⱼ)|=0 (54b)

The calculation of the depth parameter χⱼ is performed based on the fact that as modulation frequency decreases the thermal wave probing depth increases. Starting at the highest frequency, ω₀ the shortest depth is the shortest thermal diffusion length, i.e.

$${x}_{0} = \sqrt{\frac{2 {a}_{0}}{{ω}_{0}}} \qquad ( 55 )$$

The next (lower) frequency, ωⱼ₊₁ corresponds to an increased thermal wave depth

$${x}_{j + 1} = {x}_{j} + \sqrt{\frac{2 {a}_{j}}{{ω}_{j + 1}}} - \sqrt{\frac{2 {a}_{j}}{{ω}_{j}}} \qquad ( 56 )$$

which is used to calculated αⱼ₊₁ in Equation (41). Once the αⱼ₊₁ is calculated the method returns to calculate in recursive iteration the increased thermal wave depth as,

$${x}_{j + 1} = {x}_{j} + \sqrt{\frac{2 {a}_{j + 1}}{{ω}_{j + 1}}} - \sqrt{\frac{2 {a}_{j}}{{ω}_{j}}} \qquad ( 57 )$$

In reconstructing depth profiles from data it is important to first find a reliable set of initial values for α₀, α_{L}, and q. This could be achieved by finding the best theoretical fit (Eq. (52)—forward problem) to the first few end points (high frequency) using a single profile of the form of Equation (41) [M. Munidasa, F. Funak and A. Mandelis, J. Appl. Phys. 83, 3495(1998)].

(c) Instrumental System

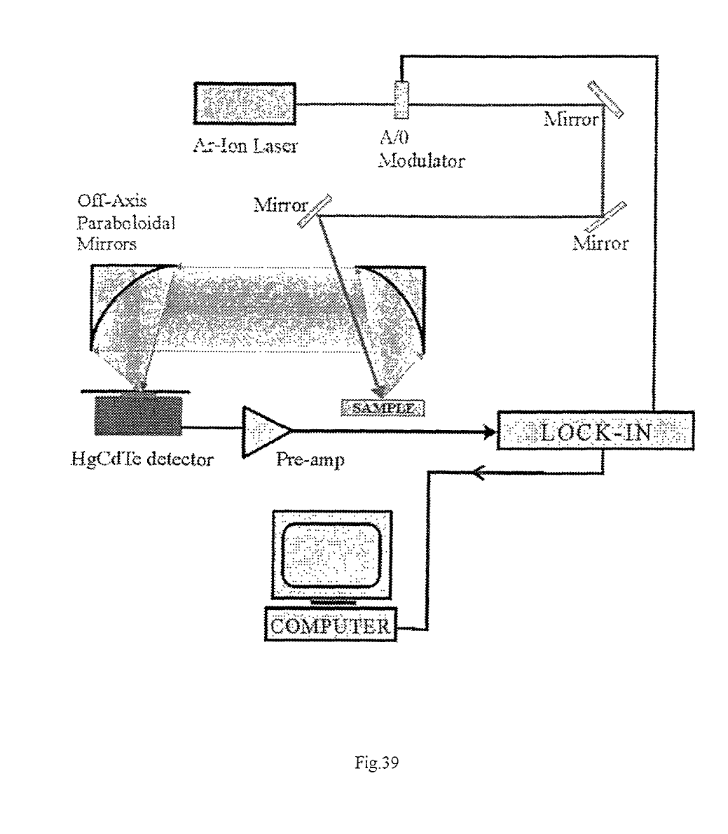

The instrumental setup for this application is of low spatial resolution since this is a one-dimensional problem. The pump beam spot size is made much larger than the maximum profile depth to maintain the one-dimensional heat diffusion formalism assumed in the theory. The instrumental apparatus is shown in FIG. 39. An Ar⁺ laser, modulated by an acousto-optic modulator (AOM-Isomet 1201E-1), is directed onto the sample surface. The emitted infrared radiation from the sample is collected and focused by two Ag-coated, off-axis paraboloidal mirrors onto a liquid nitrogen HgCdTe (Mercury-Cadmium-Telluride) infrared detector (EG&G Judson J15D12-M204-S050U) with an active area of 1 mm×1 mm. The detector signal is preamplified before being sent to a lock-in amplifier (Stanford Research System SR850), and the outputs, amplitude and phase, are recorded at a range of laser frequencies. The experimental surface temperature response on the sample is normalized by the surface temperature response of a reference sample giving for each frequency an amplitude ratio and phase difference. This normalizing procedure is necessary for the correcting of all frequency dependencies other that due to the sample [A. Mandelis, F. Funak and M, Munidasa, J. Appl. Phys. 80, 5570 (1996)].

With this experimental arrangement, a dynamic experiment can be performed at one location on the sample. The experiment generates depth-dependent information by scanning acousto-optic modulator frequency (“a frequency scan”). Two channels of information (amplitude and phase) are then obtained.

(d) Experimental Results

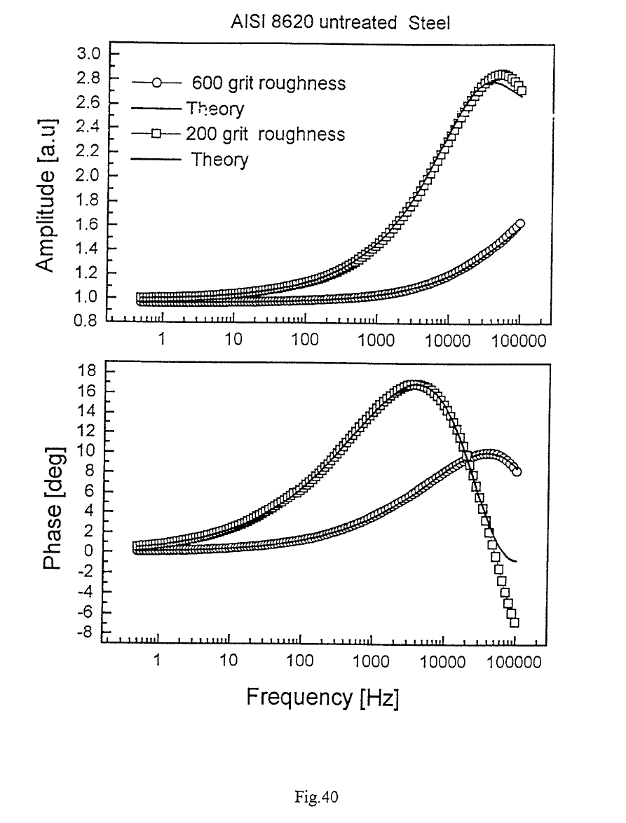

The case hardening process of carburizing, which is the absorption and diffusion of carbon into solid ferrous alloys by heating, is examined. The microstructure of the surface is changed by the process, producing carbon gradients and therefore changing the thermal diffusivity of the surface layer. A preliminary study shows that there is an anticorrelation between the thermal diffusivity and the hardness of the treated layer [M. Munidasa, F. Funak and A. Mandelis, J. Appl. Phys. 83, 3495(1998)]. Another important factor to examined is the effect of roughness on the depth profiles since thermal profiles are influenced by surface roughness. Roughness is monitored at the high frequency and FIG. 40 shows the different responses for two different roughness levels (200 grit and 600 grit). The roughest surface shows a peak in the phase data which affects the signal beyond the roughness depth and deviates from the theory of a homogeneous sample (constant phase). Therefore, it is necessary to use a finite thickness layer theory for depth reconstruction in order to obtain a reliable profile beyond the depth of the roughness. The effects of roughness are investigated and incorporated to the experimental data.

At high frequencies the penetration depth is close to the surface so lateral heat diffusion is negligible but at low frequencies the penetration depth is deep into the material and lateral heat diffusion is pronounced. To ensure one-dimensionality the size of the beam must be larger than the deepest penetration. Not only is the beam the important consideration here, but also the beam shape. The laser source has a Gaussian profile so what is needed experimentally is a top hat distribution of the beam. To alleviate these problems a thick diffuser with a lens is placed at the path of the beam to broaden the beam and reduce its Gaussian profile. As the beam is diffused more both the amplitude and phase graphs approach one-dimensional theory. The three-dimensionality effects are, as expected, more pronounced at the low frequencies.

Depth profiles of rough untreated AISI 8620 steels. With knowledge of the bulk thermal diffusivity and the thickness of the surface roughness (600 and 200 grit) of an untreated AISI 8620 a reconstruction is performed. The bulk thermal diffusivity was measured independently and was found to be α_{inf}=12.5×10⁻⁶ m²/s. The reconstruction is based on reconstructing from the high frequency end by fitting the α₀ at the interface with the geometry (d=roughness thickness) shown in FIG. 36. With this method the effect of surface roughness is greatly reduced from the system. For the samples in question, the input parameters of the 600 grit roughness layer were thermal diffusivity, α_{d}=2.15×10⁻⁶ m²/s, thermal conductivity k_{d}=6.95 W/mK and independently measured thickness d=1.6 μm and for the 200 grit the parameters were α_{d}=2.15×10⁻⁶ m²/s, thermal conductivity k_{d}=4.6 W/mK and independently measured thickness d=5 μm. It is observed that as roughness increases the thermal conductivity of the sample decreases. The experimental data with the theoretical fit which assumes two homogeneous layers (roughness and bulk) is shown in FIG. 38. The forward theoretical fit is in excellent agreement with the experimental data. Small discrepancies exist at the high frequency end where the roughness is more difficult to model. A reconstruction of the untreated AISI 8620 sample was then performed (FIG. 39). In a reconstruction the experimental data are numerically inverted to obtain the corresponding thermal diffusivity profile.

The simulation theoretically eliminates the roughness layer, which is assumed to be homogeneous with low thermal parameters, thus the reconstruction shown above commences after the roughness layer. It is seen from the reconstruction that the thermophysical properties are disturbed up to about 50 μm and that the bulk material is undisturbed approaching the experimentally independent measured value of α=12.5×10⁻⁶ m²/s. The near surface fluctuation can be attributed to the insufficient modeling of the roughness. This is not a relevant issue for hardness measurements since the interest is usually above 50 μm. Such a reconstruction can serve as a guide to determine the extent roughness influences a specific profile. As roughness increases the reliability of the reconstruction is less. The reason for this is dual: (1) the forward model is not represented well in the higher frequency spectrum and the randomness of roughness is more evident, (2) the ill-posedness of the inverse problem increases since more degrees of freedom are introduced.

(e) Heuristic Approach to Eliminate Roughness from Experimental Data

The method outlined above although effective for small roughness scale can be erroneous for the larger roughness as it appears in the signal response. With the idea that roughness is a random system, the effect of inhomogeneity and roughness is investigated. In a frequency domain method both the roughness and the inhomogeneity is felt throughout the spectrum. A simplistic approach of deconvolving the roughness from the inhomogeneity would not be valid since this is a non-linear system. The theoretical model represents roughness as a constant layer on top of an inhomogeneity and with a low-level roughness the results are satisfactory as is seen in FIG. 40. As the level (thickness) of roughness increases, the thermal-wave specimen becomes more involved, especially at high frequencies resulting in an erroneous thermal diffusivity profile. In this application of PTR diagnostics a heuristic approach is taken and tested for various levels of roughness and inhomogeneity. The theoretical results show great promise and as a result the method is implemented to reconstruct experimental data.

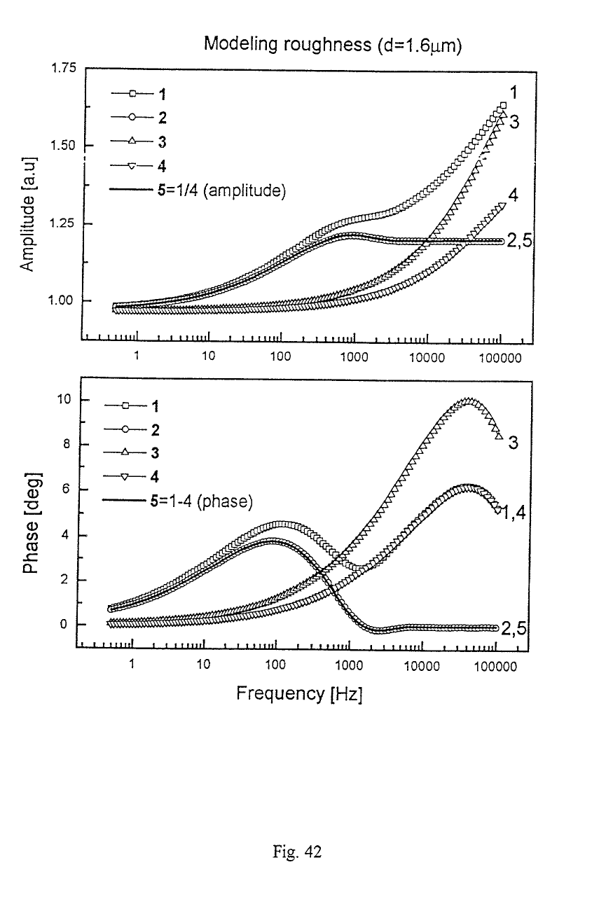

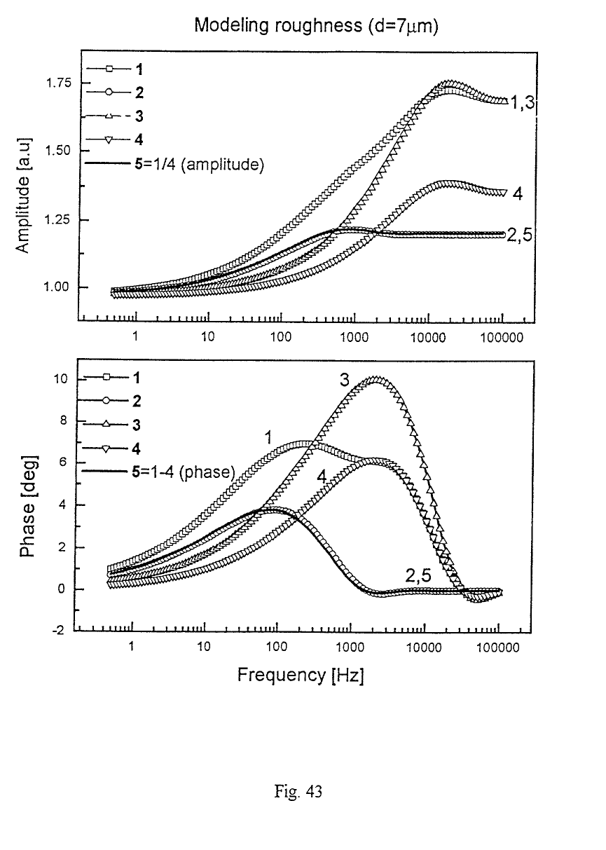

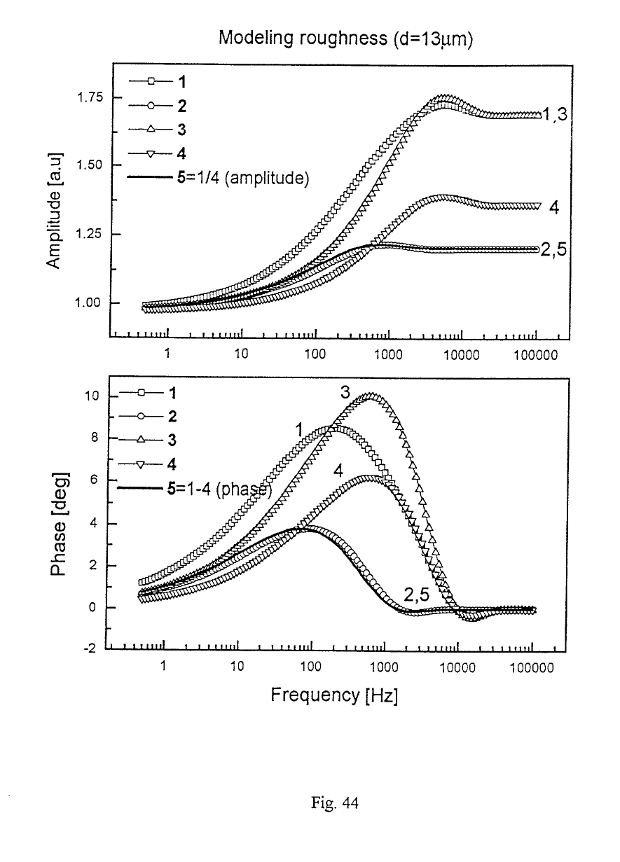

The roughness method is based on recognizing distinct features (phase maxima) from the frequency spectrum. Since roughness is associated with the surface of a sample the effects are seen the strongest at high frequencies whereas the low frequency is mostly related to substrate inhogeneities. The objective of the method is to deconvolve the roughness spectrum from the underliying profile (homogeneous or inhomogeneous). To demonstrate the method simulations of an inhomogeneous profile using a single profile of the form of equation (41) as derived in equation (52), with three roughness cases were made. FIG. 42 shows the amplitude and phase of case 1. Curve 1 shows the response of an inhomogeneous sample with roughness, d=1.6 μm. Curve 2 is the inhomogeneous field with no roughness. This would represent the ideal experimental situation where no roughness effects are present. Curve 3 is the homogeneous field with only roughness. In order to retrieve and eliminate roughness from curve 1 a theoretical fitting to the higher frequency end which is associated with the roughness is made. An effective thermal conductivity for roughness is found to model the high frequency phase response. This is curve 4 and it requires that an effective thermal conductivity is modified from curve 3. Curve 4 is an effective homogeneous field similar to 3 but with higher thermal conductivity. Table VI identifies the thermal properties for all three cases under conditions 1, 2, 3 and 4. Finally, the effective curve 4 is normalized with the total field 1. The response is as follows:

$$\begin{matrix}{T}_{final ( E )} ( 0 , ω ) = \frac{\vert {M}_{total} ( ω ) \vert {ⅇ}^{( Δ {φ}_{total} ( ω )}}{\vert {M}_{eff} ( ω ) \vert {ⅇ}^{ⅈΔ {φ}_{eff} ( ω )}} \\ = \vert \frac{{M}_{total} ( ω )}{{M}_{eff} ( ω} \vert {ⅇ}^{ⅈ [ Δ {φ}_{total} ( ω ) - Δ {φ}_{eff} ( ω ) ]}\end{matrix} \qquad ( 58 )$$

where the each temperature distribution is as defined in equation (52). Curve 5 is the result of the operation of equation (58) with dividing for the amplitude and subtracting for the phase. In this way the desired result of the inhomogeneity with no roughness is obtained. Comparing with curve B these two results are in excellent agreement with each other. The method is then tested for a higher level roughness, FIG. 43, shows case 2 where the roughness is d=7 μm. Apart from the roughness thickness the thermal properties are identical to case 1 as seen in table VII. The final result (curve 5) is in good agreement with the expected theoretical value (curve 2) with small deviations in the low frequency end. The interesting observation is that the effective thermal properties of curve 4 of case 2 are identical to case 1. A more complicated situation is then examined where the amplitude and phase does not show any characteristic maximum to distinguish from the inhomogeneities (FIG. 44), The knowledge that the same inhomogeneities affect the roughness spectrum in a similar manner is used in this case. Curve 4 is constructed with the same effective properties are in case 1 and 2. The result is that for this case the deviations from the theoretical value are satisfactory with small variations.

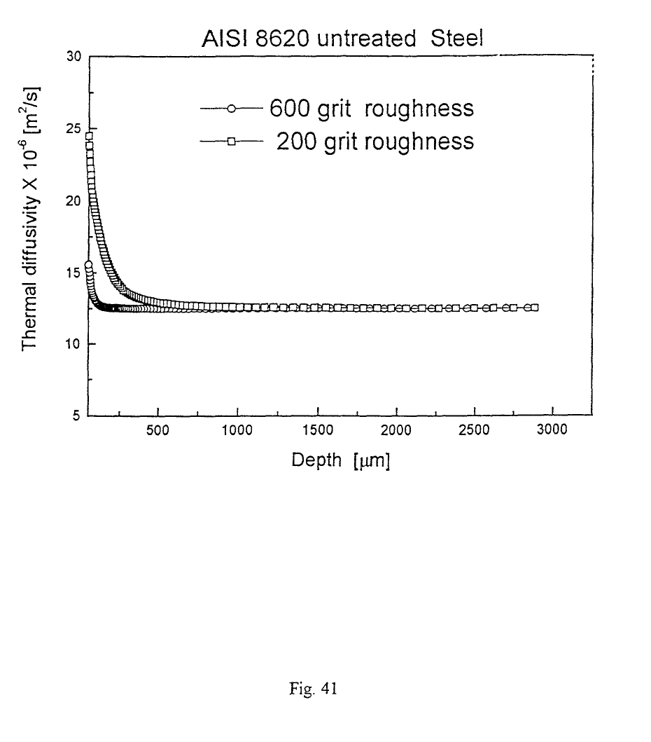

TABLE VII
Thermal properties of simulations shown FIGS. 40-42.

| Thermal Properties | Case 1 | Case 2 | Case 3 |
|---|---|---|---|
| A: Total field | α_{τ} = 6.15 × 10⁻⁶ m²/s | α_{τ} = 6.15 × 10⁻⁶ m²/s | α_{L} = 6.15 × 10⁻⁶ m²/s |
| | α₀ = 4.0 × 10⁻⁶ m²/s | α₀ = 4.0 × 10⁻⁶ m²/s | α₀ = 4.0 × 10⁻⁶ m²/s |
| | q = 2 × 10³ | q = 2 × 10³ | q = 2 × 10³ |
| | α_{d} = 2.1 × 10⁻⁶ m²/s | α_{d} = 2.1 × 10⁻⁶ m²/s | α_{d} = 2.1 × 10⁻⁶ m²/s |
| | k_{d} = 4.8 W/mk | k_{d} = 4.8 W/mk | k_{d} = 4.8 W/mk |
| | d = 1.6 μm | d = 7 μm | d = 13 μm |
| B: Inhomogencity | α_{L} = 6.15 × 10⁻⁶ m²/s | α_{L} = 6.15 × 10⁻⁶ m²/s | α_{L} = 6.15 × 10⁻⁶ m²/s |
| | α₀ = 4.0 × 10⁻⁶ m²/s | α₀ = 4.0 × 10⁻⁶ m²/s | α₀ = 4.0 × 10⁻⁶ m²/s |
| | q = 2 × 10³ | q = 2 × 10³ | q = 2 × 10³ |
| | d = 0 μm | d = 0 μm | d = 0 μm |
| C: Roughness | α_{L} = 6.15 × 10⁻⁶ m²/s | α_{L} = 6.15 × 10⁻⁶ m²/s | α_{L} = 6.15 × 10⁻⁶ m²/s |
| | α₀ = 6.15 × 10⁻⁶ m²/s | α₀ = 6.15 × 10⁻⁶ m²/s | α₀ = 6.15 × 10⁻⁶ m²/s |
| | α_{d} = 2.1 × 10⁻⁶ m²/s | α_{d} = 2.1 × 10⁻⁶ m²/s | α_{d} = 2.1 × 10⁻⁶ m²/s |
| | k_{d} = 4.8 W/mk | k_{d} = 4.8 W/mk | k_{d} = 4.8 W/mk |
| | d = 1.6 μm | d = 7 μm | d = 13 μm |
| D: Effective | k_{cff} = 5.96 W/mk | k_{cff} = 5.96 W/mk | k_{cff} = 5.96 W/mk |

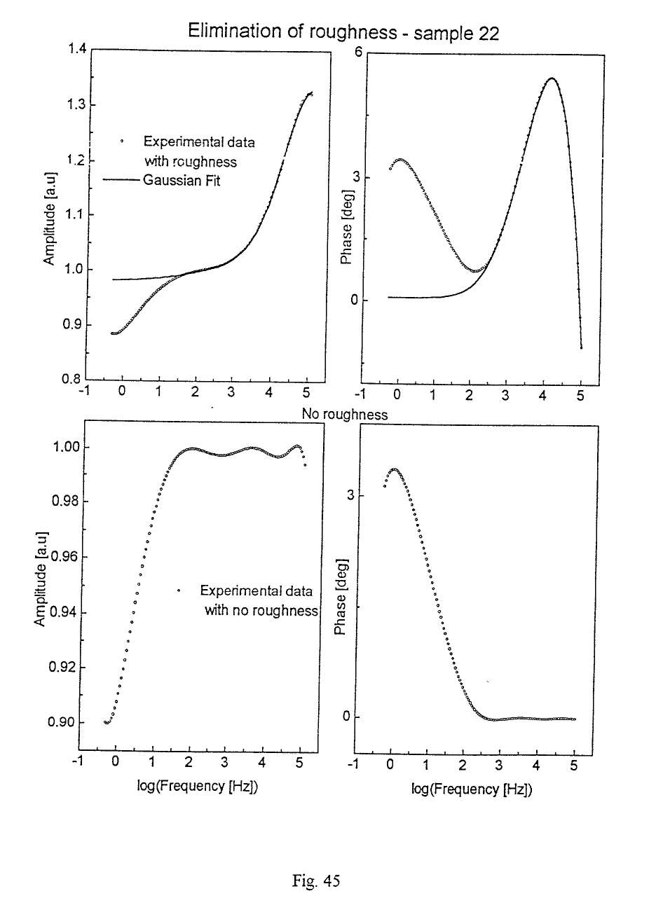

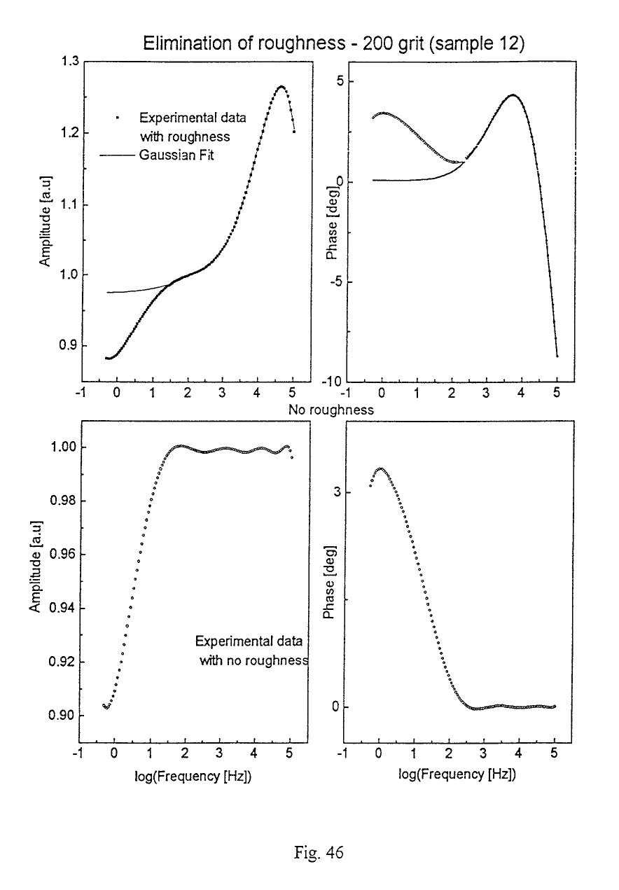

Although the above method proves to be very effective in theoretical application of inhomogeneous substrate with a rough layer, a more general expression for modeling the roughness can be obtained. Since roughness can be viewed as a random effect a Gaussian noise is fitted to the effective frequency-domain roughness profile (curve 4). The field created has to be a non-symmetrical field and thus the expression for amplitude and phase respectively, is as follows:

$$\begin{matrix}{M}_{eff} ( {ω}_{0} ) = {M}_{0} + \sqrt{\frac{2}{π}} {\sum }_{l = 2}^{∞} \frac{{A}_{1 i}}{{W}_{1 i}} {ⅇ}^{\frac{- {( {ω}_{n} - {ω}_{1 m} )}^{2}}{{W}_{1 i}}} & ( 59 ) \\ Δ {φ}_{eff} ( {ω}_{0} ) = {Δφ}_{0} + \sqrt{\frac{2}{π}} {\sum }_{i = 2}^{∞} \frac{{A}_{1 i}}{{W}_{1 i}} {ⅇ}^{\frac{- {( {ω}_{0} - {ω}_{1 si} )}^{2}}{{W}_{2 i}}} & ( 60 )\end{matrix}$$

where M₀ and Δφ₀ are the amplitude and phase offsets, W is the width, A is the area and ω_{c} is the center of the Gaussian. The summation of Gaussians is greater than one so that the asymmetry of the field is obtained. For more accurate results, the offset values can be derived from the first point of theoretical fit of the effective roughness. This can only be an approximation. The method is then applied to experimental data. FIG. 45 shows the elimination of roughness on experimental data. The sample has roughness of 1.6 μm on an inhomogeneous substrate. A Gaussian fit is performed on the roughness part of the data. The gaussian needed to perform such on operation on these data is a double Gaussian whose values can be found in table VIII. FIG. 46 shows the method of elimination on rougher data (d=5 μm) with an inhomogeneous substrate. Although the phase roughness is fitted to a double Gaussian as above, the amplitude for this data requires a summation of three Gaussians to satisfactory perform the operation. A double Gaussian would have been able to fit the data but the higher frequencies would have suffered from deviation from the experimental data. The values for the Gaussians can be found in table VIII.

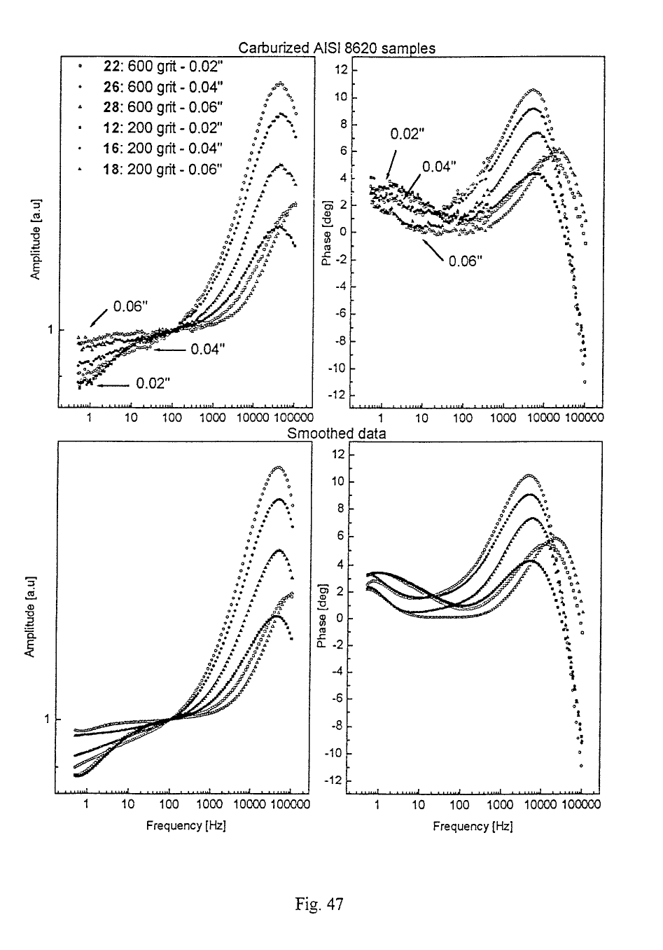

TABLE VIII
Gaussian fit parameters of experimental data
shown in FIGS. 46 and 47.

| | | |
|---|---|---|
| Gaussian | Sample 22 | sample 12 |

| Fit | Amplitude | Phase | Amplitude | Phase |
|---|---|---|---|---|
| y0 | 0.98 | 0.08 | 0.98 | 0.11 |
| xc1 | 4.89 | 4.61 | 4.81 | 4.96 |
| w1 | 3.69 | 2.03 | 0.81 | 2.28 |
| A1 | 0.29 | 21.29 | 0.12 | 41.86 |
| xc2 | 5.06 | 8.47 | 4.34 | 5.81 |
| w2 | 1.51 | 3.09 | 1.32 | 2.03 |
| A2 | 0.54 | −429.12 | 0.29 | −82.02 |
| xc3 | — | — | 3.38 | — |
| w3 | — | — | 2.47 | — |
| A3 | — | — | 0.13 | — |

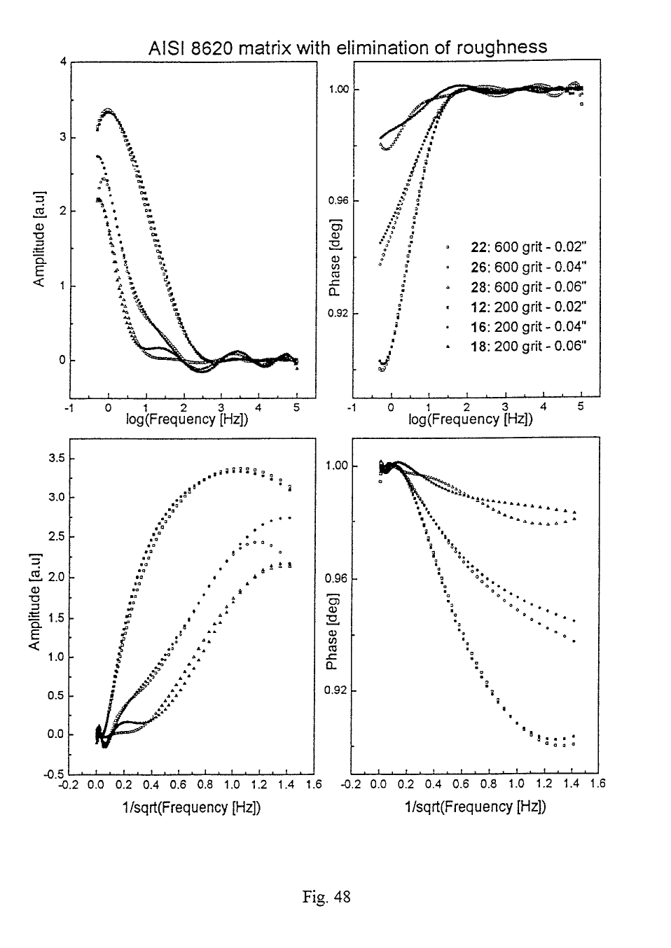

Depth profiles of carburized AISI 8620 steels through a roughness layer. A sample matrix is constructed as a function of roughness and case hardness depth. Samples with two levels of roughness (200 grit and 600 grit) were carburized at three different depths (0.02″, 0.04″ and 0.06″). The sample matrix is shown in Table VIII. The samples are AISI 8620 steel alloy from the same slab. Experimental frequency scans on the samples were taken on the rough surfaces before (FIG. 40) and after the case hardening process (FIG. 47). Above 1000 Hz strong effects of roughness are seen. Comparing these data with the untreated ones (FIG. 40) it is seen that the phase shift has decreased. This can be attributed to the fact that the thermal properties of this layer have changed after carburizing. Roughness elimination is performed on all the data as seen in FIG. 48. The success of the method is clearly seen here where two different levels of roughness result in the same inhomogeneous experimental response. The result is consistent for all the inhomogeneous depths as seen in FIG. 48.

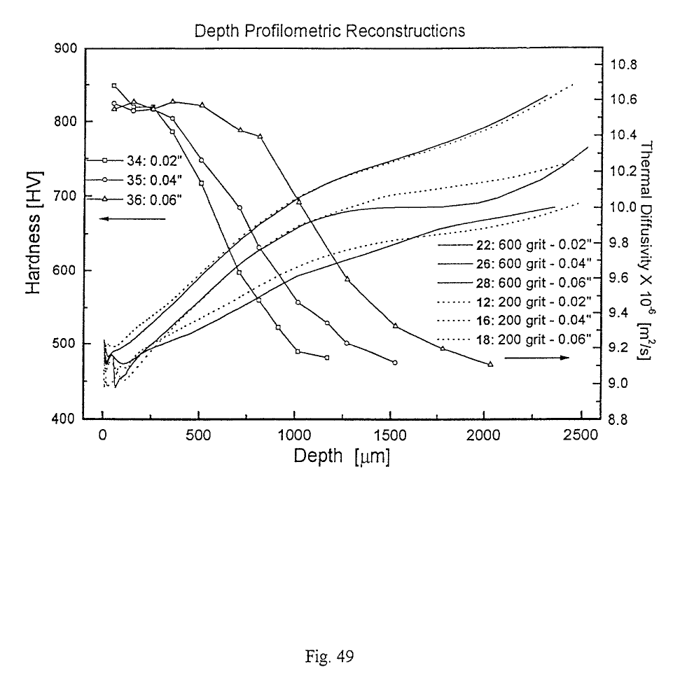

The reconstructions at the three depths are shown in FIG. 49. This figure also includes the conventional microhardness test. The depth profiles of the hardened samples exhibit an anticorrelation between thermal diffusivity and hardness. It is seen that a good one-to-one correspondence between hardness and thermal diffusivity is present although the curves are not each other's mirror images. The anticorrelation relationship is consistent with earlier results produced [T. T. N. Lan, U. Seidel and H. G. Walther, J. Appl. Phys. 77, 4739 (1995); M. Munidasa, F. Funak and A. Mandelis, J. Appl. Phys. 83 (5) 3495(1998)].

Thermal wave depth profilometry can be an invaluable application to surface treatment processes such as case hardening. In this process, important AISI steel types underwent industrially commonly used case hardening process and then a complete experimental and theoretical/computational analysis generated thermal diffusivity profiles. The elimination of roughness has been shown to be an important method of improving the experimental data and thus the reconstruction. The current methods used to characterize case hardening are destructive and therefore success in developing a correlation (anti-correlation) between hardness and thermal diffusivity profiles would mean a significant contribution to the steel industry. An anticorrelation between the thermal diffusivity profile of a hardened surface and its microhardness is found. Many approaches of the thermal diffusivity depth profiling have been introduced over the years with all the methods suffering from non-uniqueness, a distinct characteristic of ill-posed problems. By eliminating roughness the ill-posedness of the problem is reduced.

TABLE IX
AISI 8620 steel sample matrix.

| Case depth/Rough | 0.02″ | 0.04″ | 0.06″ |
|---|---|---|---|
| 600 grit | sample 22 | sample 26 | sample 28 |
| 200 grit | sample 12 | sample 16 | sample 18 |
| Test | sample 34 | sample 35 | sample 36 |

Thermal Spray coating roughness application. Thermal sprayed coatings of 316 stainless steel was applied to 9.5 mm thick, 1018 steel rectangular bars. The stainless steel were applied using the high velocity oxy-fuel (HVOF) process with the JP-5000 spray system. In order to account for the instrumental frequency dependence, the PTR signal of a Zr alloy reference sample was measured. For the low frequency range (1 to 1000 Hz) a defocused beam (˜6 mm diameter after the diffuser) was used to minimize three-dimensional effects of the heat diffusion. A bare laser beam (˜1 mm diameter) was used for the higher frequency range (1 to 100 kHz). All measured PTR signals from the thermal sprayed coatings were normalized to the Zr alloy reference sample.

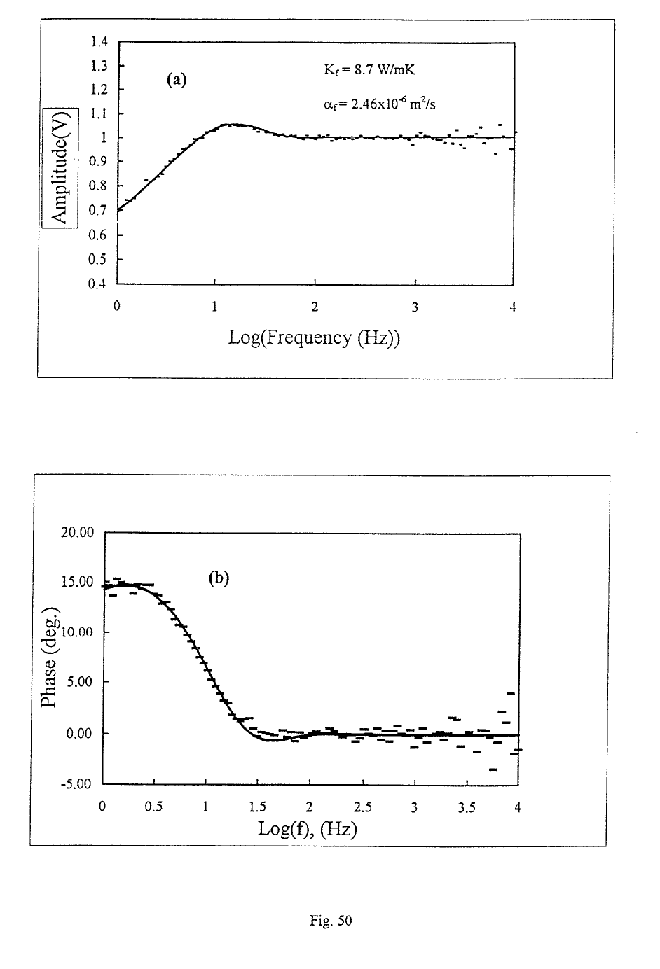

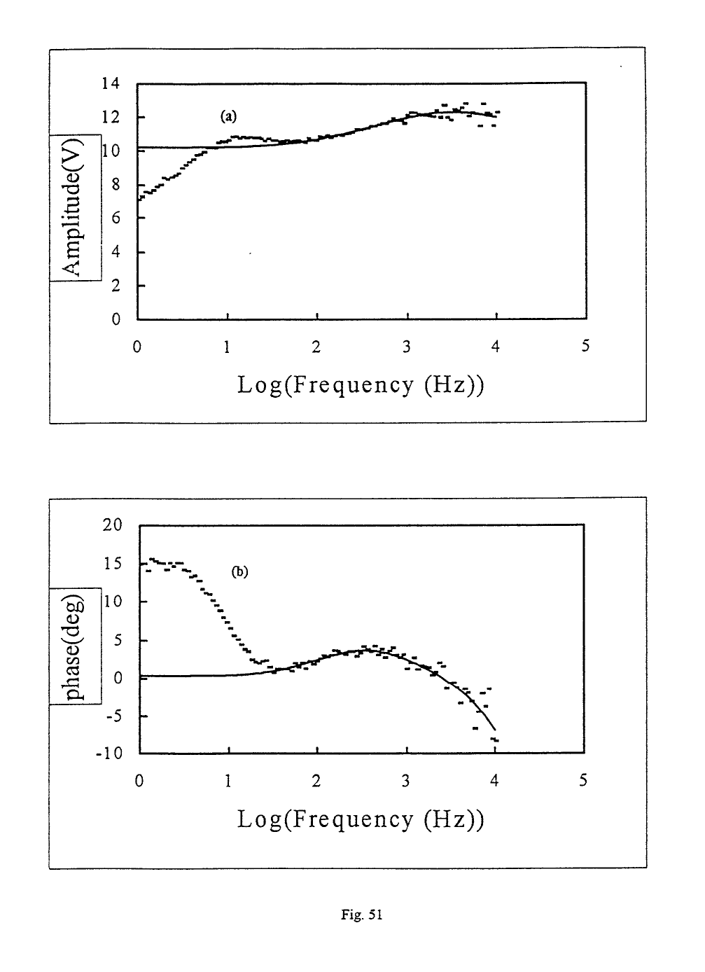

The amplitude (a) and phase (b) of the normalized PTR signal of a stainless steel sample are shown in FIG. 50. The frequency structure for both signals in amplitude and phase is dependent on the thermophysical and geometrical properties of the sample. This signal frequency-structure is due to thermal-wave interference resulting from coherent energy confinement within the spray coating layer. At higher frequencies the surface effects become more dominant and the observed structure is more likely due to roughness effects [J. A. Garcia, A. Mandelis, B. Farahbaksh and C. Lewitz, Int. J. Thermophysics, 20, 5, 1999]. The roughness elimination method was applied to this sample and the resultant corrected experimental data (see FIG. 51) was then fitted with a one-dimensional two-layer model. In this instance one has two channels of information, amplitude and phase and two unknown parameters, the thermal conductivity (k₂) and diffusivity (α₂) of the upper layer. These properties can then be determined uniquely and then correlated to the condition of the coating.

v) PTR Application to Micro-Welds

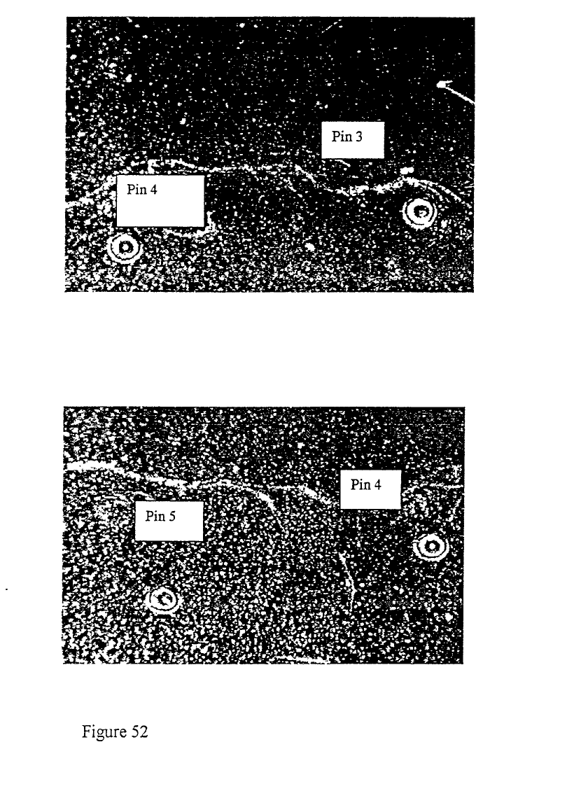

The apparatus described in this invention (see FIG. 1) was used for frequency-domain PTR of gold/aluminum microjoints. Experimental PTR frequency scans as well as PTR imaging have been obtained for two sets of samples (8f2 and 4f2). Samples 8f2, labeled “good bonds”, had gold wire (25 microns diameter) bonded to aluminum foil of 0.1 mm thickness. The force and frequency used in the 8f2 bonds were 90 gf and 60 kHz respectively. Samples 4f2, “bad bonds”, had the same material combination and same bonding parameters except for the bonding force which was 90 gf. FIG. 52 shows CCD camera images of four pins (gold wire/aluminum substrate) from samples 8f2. Pins 1-to-3 from sample 8f2 and pins 3-to-5 from sample 4f2, (CCD picture not shown) were examined using PTR.

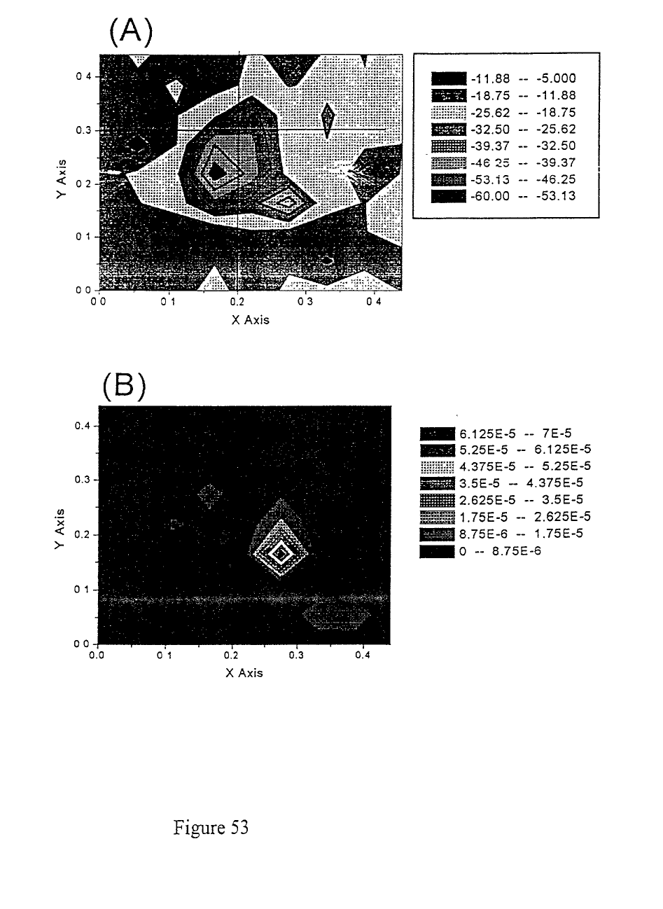

A typical PTR image (amplitude and phase) of pin 1 of sample 8f2 is shown in FIG. 53. Then PTR frequency scans were performed on the aluminum foil at approximately 100-to-200 microns away from the edge of the splat for each micro-weld as well as 50 microns inside the splat (see cross-hair in FIG. 53).

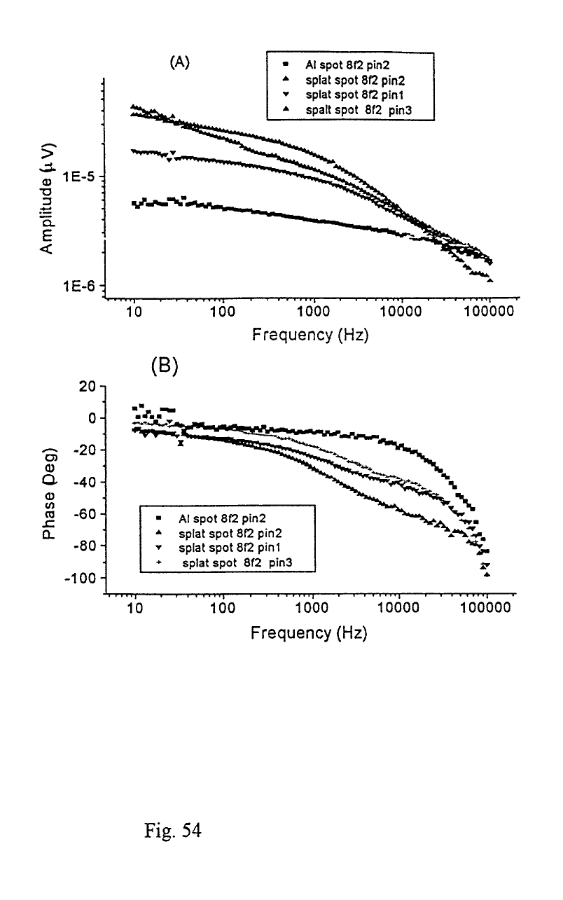

The frequency scans performed at 50 microns inside the splat showed significant differences between the poor (60 gf) (frequency scan not shown) and good (90 gf) bondings, FIG. 54. The minimum in the phase-frequency scan was more pronounced for the poor bonds when compared to the minimum in the phase-frequency scan of the good bonds. This result indicated differences in interfacial conditions that may be related to thermal resistances between the two types of samples. The maximum change in phase (obtained from the PTR images) of various pins in sample 4f2 and 8f2 were 41-to-62 degrees and 55-to-85 degrees respectively. These results indicated that the information given by the PTR phase image can be used to correlate to the quality of the bond (bonding force).

In summary there is provided a metrologic methodology comprising of novel combinations of new signal generation and analysis techniques, computational software, and photothermal radiometric instrumental configurations for measuring thermal and electronic properties of industrial semiconductor wafers and engineering materials.

The combination of frequency sweep (“Chirp”) and frequency scan methodology for rapid measurement of electronic and thermal transport properties of semiconductor and engineering materials presented in this invention involves providing a sample such as a semiconductor wafer or other engineering material, irradiating the sample with an excitation source (laser or other sources), generating a square-wave chirp from a dual-channel fast Fourier transform (FFT) analyzer to drive an acousto-optic modulator and produce periodic frequency sweeps (Chips) of the laser beam in the range including (but not confined to) dc to 100 kHz, generating a transfer function, H(f), by fitting the frequency-scan data from a silicon wafer with well known electronic and thermal parameters to a theoretical model, computing the necessary corrections to the amplitude and phase signal, and storing them in the FFT analyzer and in a personal computer, fitting the obtained signal from arbitrary semiconductor samples to the same theoretical model of the photothermal response, corrected for the instrumental transfer function to obtain the thermal and electronic parameters of these samples. This same methodology can be used for generating fast photothermal frequency scans from multilayered inhomogeneous materials, such as thermal barrier coatings and hardened steels.

The common rejection mode (dual pulse) methodology for detection of very weak inhomogeneities among materials involves: providing a sample of the material, irradiating the sample with an optical or otherwise excitation source of thermal waves, generating a real time periodic waveform consisting of two incident pulses, detecting the signal (photothermal) and feeding it to a lock-in amplifier. This methodology is not confined to thermal-wave signal generation, but encompasses all manner of modulated signals, such as acoustic, optical, ultrasonic, X-rays and other signal generation method accessible to those skilled in the art.

The multi-parameter computational methodology for determining a unique set of thermal and electronic parameters of industrial semiconductor (i.e. Si) wafers, from frequency domain measurements, involves: providing a semiconductor wafer (or sample), irradiating the sample with a periodic optical (laser) or other free-carrier raising energy source generating a photothermal signal, detecting said photothermal signal, inputting said signal to a lock-in amplifier, storing the frequency scans in a personal computer, and applying the multiparameter fitting procedure (by means of an electronic sheet or any other code program, i.e C, Fortran).

The depth profilometry and roughness elimination method for determining thermal diffusivity profiles of rough samples involves: (a) providing a sample of process-related inhomogeneous material or multi-layer structures; (b) irradiating the sample with a periodically excited source (laser); (c) detecting the photothermal frequency sweep signal with a lock-in amplifier and storing the experimental data in a personal computer; (d) processing the experimental data with a heuristic approach to roughness so as to eliminate the effects of roughness; (e) applying to the processed data the theoretical/computational model to reconstruct the thermal diffusivity profile.

While these methodologies and some of their applications have been described and illustrated with respect to various embodiments of radiometric instrumental arrangements, it will be appreciated that numerous variations of the instrument/methods may be made without departing from the scope of this invention defined by all of the embodiments encompassed within the following claims and their equivalents.

Therefore what is claimed is:

1. A photothermal radiometric method for measuring thermal and electronic properties of a semiconductor material, comprising:
(a) providing a sample of the semiconductor;
(b) irradiating the sample with an excitation pulse which is one of amplitude-modulated, frequency modulated and phase modulated with a linear frequency ramp wherein a photothermal radiometric signal is responsively emitted from said semiconductor;
(c) detecting amplitude and phase responses of said emitted photothermal signal using a detection means connected to a instrumental signal processing means;
(d) producing an instrumental signal processing means transfer function by fitting frequency-scan data from a material with known thermal and electronic properties to a multiparameter theoretical model which uses these properties, and normalizing the amplitude and phase of the photothermal response using said instrumental transfer function to produce a normalized photothermal response; and
(e) fitting said normalized photothermal response to said multiparameter theoretical model to calculate the thermal and electronic properties of the semiconductor.

2. The method according to claim 1 including calibrating said response by means of an appropriate reference sample response to normalize out the instrumental response and retain only the physical response of a sample under investigation.

3. The method according to claim 1 wherein said instrumental signal processing means is one of a dynamic signal analyzer, lock-in amplifier, phase-demodulator and cross-correlator.

4. The method according to claim 1 wherein said sample is a non electronic material (solid), wherein the sample is irradiated with an excitation pulse, which is amplitude-modulated with a linear frequency ramp (“chirp”), or, alternately, frequency- or phase-modulated, and cross-correlated with the received photothermal signal, wherein a photothermal radiometric signal is responsively emitted from said sample; wherein detecting said emitted temporal photothermal signal into a signal detection means (dynamic signal analyzer or lock-in amplifier, phase modulator or cross-correlator) that can capture one, several or all frequency components of the waveforms of the incident and response signal spectra; and thus transform the time-resolved, repetitive photothermal radiometric response into part or all of its Fourier spectrum (the frequency domain (FFT)); wherein normalizing such response with an instrumental (calibration) function obtained in conjunction with the particular modulation frequency-scan technique utilized in a given test; wherein fitting said photothermal response to a theoretical model to calculate the thermal properties (thermal diffusivity and conductivity) of said material or alternatively calibrating said response by means of an appropriate reference sample response to normalize out the instrumental response and retain only the physical response of a sample under investigation.

5. The method according to claim 1 wherein said sample is a coating on a non electronic material (solid), wherein the sample is irradiated with an excitation pulse which is amplitude-modulated with a linear frequency ramp (“chirp”), or, alternately, frequency- or phase-modulated, and cross-correlated with the received photothermal signal, wherein a photothermal radiometric signal is responsively emitted from said sample; wherein detecting said emitted temporal photothermal signal into a signal detection means (dynamic signal analyzer or lock-in amplifier, phase modulator or cross-correlator) that can capture one, several or all frequency components of the waveforms of the incident and response signal spectra; and thus transform the time-resolved, repetitive photothermal radiometric response into part or all of its Fourier spectrum (the frequency domain (FFT)); wherein normalizing such response with an instrumental (calibration) function obtained in conjunction with the particular modulation frequency-scan technique utilized in a given test; wherein fitting said photothermal response to a theoretical model to calculate the thermal properties (thermal diffusivity and conductivity) of said material or alternatively calibrating said response by means of an appropriate reference sample response to normalize out the instrumental response and retain only the physical response (thermal diffusivity and conductivity) and/or thickness of said coating.

6. A method for detection of weak inhomogeneities in semiconductor materials comprising:
(a) providing a sample of the semiconductor;
(b) irradiating the sample with an excitation source;
(c) generating a real time periodic waveform consisting of a bi-modal square-pulse waveform;
(d) detecting the signal response and feeding it to a lock-in amplifier (single or dual channel), by scanning the center-to-center time delay between the two pulses of the bi-modal waveform.

7. The method according to claim 6 wherein said sample is a ion-implanted semiconductor, wherein the sample is irradiated with an optical excitation source, wherein a real time periodic waveform consisting of a bi-modal waveform (two square-wave pulses) is generated, wherein a photothermal radiometric signal is responsively emitted from said sample; wherein detecting the photothermal signal response and feeding it to a lock-in amplifier (single or dual channel), by scanning the center-to-center time delay between the two pulses.

8. The method according to claim 6 wherein said sample is an epitaxial (epi-) layer semiconductor, wherein the sample is irradiated with an optical excitation source, wherein a real time periodic waveform consisting of of a bi-modal waveform (two square-wave pulses) is generated instrumentally, wherein a photothermal radiometric signal is responsively emitted from said sample; wherein detecting the signal response (photothermal, electrical, optical or any other form of modulated signal generation) and feeding it to a lock-in amplifier (single or dual channel), by scanning the center-to-center time delay between the two pulses.

9. The method according to claim 6 wherein said sample is a semicondutor with scribeline structure, wherein the sample is irradiated with an optical excitation source, wherein a real time periodic bi-modal waveform consisting of two pulses is generated, wherein a photothermal radiometric signal is responsively emitted from said sample; wherein detecting the photothermal signal response and feeding it to a lock-in amplifier (single or dual channel), by scanning the center-to-center time delay between the two pulses.

10. The method according to claim 6 wherein said sample is a semicondutor with diffusion and, space-charged layers, wherein the sample is irradiated with an optical excitation source, wherein a real time bi-modal periodic waveform consisting of two pulses is generated, wherein a photothermal radiometric signal is responsively emitted from said sample; wherein detecting the photothermal signal response and feeding it to a lock-in amplifier (single or dual channel), by scanning the center-to-center time delay between the two pulses.

11. The method according to claim 6 wherein said sample is a metal, wherein the sample is irradiated with an optical excitation source, wherein a real time bi-modal periodic waveform consisting of two pulses is generated, wherein a photothermal radiometric signal is responsively emitted from said sample; wherein detecting the photothermal signal response and feeding it to a lock-in amplifier (single or dual channel), by scanning the center-to-center time delay between the two pulses.

12. The method according to claim 6 wherein said sample is a liquid mixture, wherein the sample is irradiated with an optical excitation source, wherein a real time bi-modal periodic waveform consisting of two pulses is generated, wherein a photothermal radiometric signal is responsively emitted from said sample; wherein detecting the photothermal signal response and feeding it to a lock-in amplifier (single or dual channel), by scanning the center-to-center time delay between the two pulses.

13. A laser photothermal radiometric instrument coupled with a computational method for determining thermal and electronic parameters of industrial semiconductor (e.g. Si) wafers, from frequency domain measurements comprising:
(a) providing a sample of the semiconductor;
(b) irradiating the sample with a periodic laser source causing a radiometric photothermal signal to be responsively emitted by the sample;
(c) detecting said photothermal signal and inputting said photothermal signal to a lock-in amplifier;
(d) storing amplitude and phase of the emitted photothermal signal for each frequency scan in a computer processor;
(e) applying the multiparameter computational method to obtain the thermal and electronic properties of the semiconductor.

14. An instrumental method for producing parallel or sequentially acquired and processed laser radiometric electronic imaging of semiconductor wafer, which comprises:
(a) providing a sample of the semiconductor;
(b) irradiating the sample with a periodic optical (laser) source causing a photothermal signal at a fixed laser modulation frequency and an image for the X-Y directions.
(c) detecting said photothermal radiometric signal and inputting said photothermal signal to a lock-in amplifier
(d) storing the mapping data in a personal computer; and
(e) producing a thermoelectronic image of the semiconductor by displaying the amplitude and/or phase vs. the X-Y positions.

15. An instrumental method for producing parallel or sequentially-acquired and processed laser radiometric electronic imaging of a semiconductor wafer, which comprises:
(f) providing a sample of the semiconductor;
(g) irradiating the sample with a periodic optical (laser) source causing a photothermal signal at a fixed laser modulation frequency using the bi-modal common-mode rejection demodulation waveform and an image for the X-Y directions;
(h) detecting said photothermal radiometric signal and inputting said photothermal signal to a lock-in amplifier;
(i) storing the mapping data in a personal computer;
producing the thermoelectronic image of the semiconductor by displaying the in-phase and/or quadrature of the demodulated lock-in output vs. the X-Y positions at a fixed center-to-center time delay so as to obtain signals in the neighborhood of the zero crossing point, for maximum signal baseline suppression.

16. The method according to claim 13 wherein said sample is a patterned (scribeline) semiconductor, wherein the sample is irradiated with a periodic optical excitation source causing a laser photothermal radiometric signal at a fixed laser modulation frequency, wherein detecting said photothermal signal and inputting said photothermal signal to a lock-in amplifier, wherein storing the mapping data in a personal computer, wherein producing the thermoelectronic image of the semiconductor by displaying the amplitude and/or phase or the in-phase and quadrature versus the X-Y position coordinate scan.

17. A photothermal instrument and method for depth profilometry and roughness elimination for determining thermal diffusivity profiles of rough samples, comprising:
(a) providing a sample of the inhomogeneous material;
(b) irradiating the sample with a periodically excited source (laser)
(c) detecting the photothermal radiometric (or otherwise) frequency sweep signal with an infrared wide-bandwidth detector such as a mercury-cadmium-telluride (MCT) cryogenic detector and a lock-in amplifier
(d) storing the experimental data in a personal computer;
(e) normalizing such response with an instrumental (calibration) function obtained in conjunction with the lock-in/frequency scan technique; or amplitude-modulated with a linear frequency ramp (“chirp”), or, alternately, frequency- or phase-modulated, and cross-correlated with the received photothermal signal;
(f) processing the experimental data with a heuristic approach to roughness so as to eliminate the effects of roughness;
(g) applying to the processed data the theoretical/computational model to reconstruct the thermal diffusivity profile.

18. The method according to claim 17 wherein said sample is multi-layer structure (coating) sample, wherein the sample is irradiated with a periodic optical excitation source causing a photothermal signal. A method of roughness elimination for determining thermal diffusivity and conductivity of rough-homogeneous multilayer samples, wherein detecting the photothermal frequency sweep signal with a lock-in amplifier and
storing the experimental data in a personal computer; wherein normalizing such response with an instrumental (calibration) function obtained in conjunction with the lock-in/frequency scan technique; or amplitude-modulated with a linear frequency ramp (“chirp”), or, alternately, frequency- or phase-modulated, and cross-correlated with the received photothermal signal; wherein processing the experimental data with a heuristic approach to roughness so as to eliminate the effects of roughness; wherein applying to the processed data the theoretical/computational model to determine the thermal diffusivity and conductivity of the sample coating.

19. The method according to claim 6 wherein said excitation source is one of an optical excitation source, an electrical excitation source and an electron beam source.
